(19) United States
(12) Patent Application Publication
(10) Pub. No.: US 2026/0089921 A1
(43) Pub. Date: Mar. 26, 2026

(54) Semiconductor Device

(71) Applicant: Semiconductor Energy Laboratory Co., Ltd., Kanagawa-ken (JP)

(72) Inventors: Shunpei YAMAZAKI, Setagaya, Tokyo (JP); Hitoshi KUNITAKE, Machida-shi, Tokyo-to (JP); Takanori MATSUZAKI, Atsugi, Kanagawa (JP)

(73) Assignee: Semiconductor Energy Laboratory Co., Ltd., Kanagawa-ken (JP)

(21) Appl. No.: 19/110,932

(22) PCT Filed: Sep. 11, 2023
(86) PCT No.: PCT/IB2023/058970

§ 371 Date: Mar. 12, 2025

(30) Foreign Application Priority Data
Sep. 16, 2022 (JP) 2022-147541

(51) Int. Cl. H10B 12/00; H10B 53/20; H10B 53/30; H10D 1/68; H10D 30/67

(52) U.S. Cl. CPC H10B 12/33; H10B 12/05; H10D 1/714; H10D 1/716; H10D 30/6706; H10D 30/6728; H10D 30/6731; H10D 30/6757; H10B 12/036; H10B 12/50; H10B 53/20; H10B 53/30

(57) ABSTRACT

A semiconductor device that can be miniaturized or highly integrated is provided. The semiconductor device includes a first transistor, a connection portion, a first insulator, a second insulator, and a first wiring. The connection portion includes a first electrode and a second electrode. The first transistor includes the second electrode, a third electrode, a first semiconductor, a gate insulator, and a first gate electrode. The first insulator includes a first opening reaching the first wiring. The first electrode is in contact with a side surface of the first opening and the top surface of the first wiring. The second electrode is in contact with the first electrode in the first opening. The second insulator includes a second opening reaching the second electrode. The third electrode is provided over the second insulator. The first semiconductor is in contact with the third electrode, a side surface of the second insulator in the second opening, and the top surface of the second electrode. The gate insulator is in contact with the first semiconductor in the second opening. The first gate electrode faces the first semiconductor with the gate insulator therebetween.

### TECHNICAL FIELD

One embodiment of the present invention relates to a transistor, a semiconductor device, a memory device, and an electronic device. Another embodiment of the present invention relates to a method for manufacturing a memory device or a semiconductor device. Another embodiment of the present invention relates to a semiconductor wafer and a module.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, semiconductor devices have been developed; an LSI (Large Scale Integration), a CPU (Central Processing Unit), a memory, and the like have been mainly used for semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film applicable to the transistor, and an oxide semiconductor has been attracting attention as another material.

It is known that a transistor using an oxide semiconductor has an extremely low leakage current in a non-conduction state. For example, Patent Document 1 discloses a low-power-consumption CPU utilizing a feature of a low leakage current of the transistor using an oxide semiconductor. Furthermore, for example, Patent Document 2 discloses a memory device that can retain stored contents for a long time by utilizing a feature of a low leakage current of the transistor including an oxide semiconductor.

In recent years, demand for an integrated circuit with higher density has risen with reductions in size and weight of electronic devices. Furthermore, the productivity of a semiconductor device including an integrated circuit is required to be improved. For example, Patent Document 3 and Non-Patent Document 1 disclose a technique to achieve an integrated circuit with higher density by providing a plurality of memory cells, which include transistors with oxide semiconductor films, so as to overlap with each other.

Furthermore, by employing vertical transistors, an integrated circuit with higher density can be achieved. For example, Patent Document 4 discloses a vertical transistor in which a side surface of an oxide semiconductor is covered with a gate electrode with a gate insulator therebetween.

### REFERENCE

### Patent Document

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537
[Non-Patent Document 1] M. Oota, et al., “3D-Stacked CAAC—In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a memory device that can be miniaturized or highly integrated. Another object is to provide a memory device including a memory element and a peripheral circuit that are formed separately at a low cost. Another object is to provide a memory device that can reduce the load on a wiring. Another object is to provide a memory device with a high operation speed. Another object is to provide a memory device with favorable electrical characteristics. Another object is to provide a memory device with a small variation in electrical characteristics of transistors. Another object is to provide a highly reliable memory device. Another object is to provide a memory device with a high on-state current. Another object is to provide a memory device with low power consumption. Another object is to provide a novel memory device. Another object is to provide a method for manufacturing a novel memory device. An object of one embodiment of the present invention is to at least alleviate at least one of problems of the conventional technique.

Note that the description of these objects does not preclude the existence of other objects. One embodiment of the present invention does not necessarily achieve all these objects. Other objects can be derived from the description of the specification, the drawings, the claims, and the like.

### Means for Solving the Problems

One embodiment of the present invention is a semiconductor device that includes a first transistor, a connection portion, a first insulator, a second insulator, and a first wiring. The connection portion includes a first electrode and a second electrode. The first transistor includes the second electrode, a third electrode, a first semiconductor, a gate insulator, and a first gate electrode. The first insulator is provided over the first wiring and has a first opening reaching the first wiring. The first electrode includes a first portion in contact with a side surface of the first insulator in the first opening and a second portion in contact with the top surface of the first wiring. The second electrode is embedded in the first opening and is in contact with the second portion of the first electrode. The second insulator is provided over the first insulator and has a second opening reaching the second electrode. The third electrode is provided over the second insulator. The first semiconductor includes a third portion in contact with the third electrode, a fourth portion in contact with a side surface of the second insulator in the second opening, and a fifth portion in contact with the top surface of the second electrode. The gate insulator is positioned in the second opening and is in contact with the fourth portion and the fifth portion of the first semiconductor. The first gate electrode is positioned in the second opening and faces the third portion, the fourth portion, and the fifth portion of the first semiconductor with the gate insulator therebetween.

In the above, a capacitor and a second wiring are preferably further provided. The capacitor includes a fourth electrode, a fifth electrode, and a third insulator. The first insulator includes a third opening reaching the second wiring. The fourth electrode includes a sixth portion in contact with a sidewall of the first insulator in the third opening and a seventh portion in contact with the top surface of the second wiring. The third insulator is positioned in the third opening and is in contact with the sixth portion and the seventh portion of the fourth electrode. The fifth electrode is embedded in the third opening and faces the sixth portion and the seventh portion of the fourth electrode with the third insulator therebetween.

In the above, a second transistor is preferably further provided over the capacitor. The second transistor includes the fifth electrode, a sixth electrode, a second semiconductor, the gate insulator, and a second gate electrode. The second insulator includes a fourth opening reaching the fifth electrode. The sixth electrode is provided over the second insulator. The second semiconductor includes an eighth portion in contact with the sixth electrode, a ninth portion in contact with a sidewall of the second insulator in the fourth opening, and a tenth portion in contact with the top surface of the fifth electrode. The gate insulator is positioned in the fourth opening and is in contact with the eighth portion, the ninth portion, and the tenth portion of the second semiconductor. The second gate electrode is positioned in the fourth opening and faces the ninth portion and the tenth portion of the second semiconductor with the gate insulator therebetween.

In any of the above, the second electrode is preferably in contact with the first portion of the first electrode.

In any of the above, a fourth insulator is preferably further provided. In that case, the fourth insulator is preferably positioned in the first opening and in contact with the first portion of the first electrode. Furthermore, the second electrode is preferably in contact with the fourth insulator.

In any of the above, the second electrode preferably includes a first conductor and a second conductor over the first conductor. In that case, the first conductor is embedded in the first opening and is in contact with the second portion of the first electrode. The second conductor is in contact with the first semiconductor.

### Effect of the Invention

According to one embodiment of the present invention, a memory device that can be miniaturized or highly integrated can be provided. In a memory device, a memory element and a peripheral circuit can be formed separately at a low cost. A semiconductor device or a memory device that can reduce the load on a wiring can be provided. Alternatively, a memory device with a high operation speed can be provided. A highly reliable memory device can be provided. A memory device with a small variation in electrical characteristics of transistors can be provided. A memory device with favorable electrical characteristics can be provided. A memory device with a high on-state current can be provided. A memory device with low power consumption can be provided. A novel memory device can be provided. A method of manufacturing a novel memory device can be provided. According to one embodiment of the present invention, at least one of problems of the conventional technique can be at least alleviated.

Note that the description of these effects does not preclude the existence of other effects. One embodiment of the present invention does not necessarily have all these effects. Note that effects other than these can be derived from the description of the specification, the drawings, the claims, and the like.

### BRIEF DESCRIPTION OF THE DRAWINGS

FIG. 1A to FIG. 1D are structure examples of a memory device.

FIG. 2A to FIG. 2D are structure examples of a memory device.

FIG. 3A and FIG. 3B are structure examples of a memory device.

FIG. 4A to FIG. 4D are structure examples of a memory device.

FIG. 5A to FIG. 5D are structure examples of a memory device.

FIG. 6A and FIG. 6B are structure examples of a memory device.

FIG. 7A to FIG. 7D are structure examples of a memory device.

FIG. 8A to FIG. 8C are structure examples of a memory device.

FIG. 9A and FIG. 9B are structure examples of a memory device.

FIG. 10A to FIG. 10D are structure examples of a memory device.

FIG. 11A and FIG. 11B are structure examples of a memory device.

FIG. 12A to FIG. 12C are diagrams illustrating a method for manufacturing a memory device.

FIG. 13A to FIG. 13C are diagrams illustrating a method for manufacturing a memory device.

FIG. 14A to FIG. 14C are diagrams illustrating a method for manufacturing a memory device.

FIG. 15A to FIG. 15C are diagrams illustrating a method for manufacturing a memory device.

FIG. 16A to FIG. 16C are diagrams illustrating a method for manufacturing a memory device.

FIG. 17A to FIG. 17C are diagrams illustrating a method for manufacturing a memory device.

FIG. 18A to FIG. 18C are diagrams illustrating a method for manufacturing a memory device.

FIG. 19A to FIG. 19C are diagrams illustrating a method for manufacturing a memory device.

FIG. 20A to FIG. 20C are diagrams illustrating a method for manufacturing a memory device.

FIG. 21A to FIG. 21C are diagrams illustrating a method for manufacturing a memory device.

FIG. 22A to FIG. 22C are diagrams illustrating a method for manufacturing a memory device.

FIG. 23A to FIG. 23C are diagrams illustrating a method for manufacturing a memory device.

FIG. 24A and FIG. 24B are structure examples of a memory device.

FIG. 25A and FIG. 25B are structure examples of a memory device.

FIG. 26A and FIG. 26B are structure examples of a memory device.

FIG. 27A and FIG. 27B are structure examples of a memory device.

FIG. 28A to FIG. 28C are structure examples of a memory device.

FIG. 29A to FIG. 29C are structure examples of a memory device.

FIG. 30 is a structure example of a memory device.

FIG. 31 is a structure example of a memory device.

FIG. 32 is a block diagram illustrating an example of a memory device.

FIG. 33A and FIG. 33B are schematic diagrams illustrating an example of a memory device.

FIG. 34A to FIG. 34D are circuit diagrams illustrating examples of a memory device.

FIG. 35 is a circuit diagram illustrating an example of a memory device.

FIG. 36A and FIG. 36B are diagrams each illustrating an example of an electronic component.

FIG. 37A and FIG. 37B are diagrams each illustrating an example of an electronic device. FIG. 37C to FIG. 37E are diagrams illustrating examples of a large computer.

FIG. 38A is a diagram illustrating an example of space equipment. FIG. 38B is a diagram illustrating an example of a storage system that can be used in a data center.

### MODE FOR CARRYING OUT THE INVENTION

Embodiments will be described below with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the description of the embodiments below.

In the drawings, the size, the layer thickness, or the region is exaggerated for clarity in some cases. Therefore, the size, the layer thickness, or the region is not limited to the illustrated scale. Note that the drawings schematically illustrate ideal examples, and embodiments of the present invention are not limited to shapes or values shown in the drawings. For example, in the actual manufacturing process, a layer, a resist mask, or the like might be unintentionally reduced in size by treatment such as etching, which is not be reflected in the drawings for easy understanding in some cases. Furthermore, in the drawings, the same reference numerals are used in common for the same portions or portions having similar functions in different drawings, and repeated description thereof is omitted in some cases. The same hatching pattern is used for portions having similar functions, and the portions are not especially denoted by reference numerals in some cases.

Furthermore, especially in a plan view (also referred to as a “top view”), a perspective view, or the like, the description of some components is omitted for easy understanding of the invention in some cases. The description of some hidden lines and the like is also omitted in some cases.

The ordinal numbers such as “first” and “second” in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like do not sometimes correspond to the ordinal numbers that are used to specify one embodiment of the present invention.

In this specification and the like, terms for describing arrangement, such as “over” and “under”, are used for convenience for describing the positional relationship between components with reference to drawings. The positional relationship between components is changed as appropriate in accordance with a direction in which each component is described. Thus, without limitation to terms described in the specification, the description can be changed appropriately depending on the situation.

In this specification and the like, for example, the expression “X and Y are connected” means the case where X and Y are electrically connected. Here, the expression “X and Y are electrically connected” means connection that enables electrical signal transmission between X and Y in the case where an object (that refers to an element such as a switch, a transistor element, or a diode, a circuit including the element and a wiring, or the like) is present between X and Y. Note that the case where X and Y are electrically connected includes the case where X and Y are directly connected. Here, the expression “X and Y are directly connected” means connection that enables electrical signal transmission between X and Y through a wiring (or an electrode) or the like, not through the above object. In other words, direct connection refers to connection that can be regarded as the same circuit diagram when represented by an equivalent circuit.

In this specification and the like, a transistor is an element having at least three terminals including a gate, a drain, and a source. In addition, the transistor includes a region where a channel is formed (hereinafter also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

Functions of a “source” and a “drain” are sometimes replaced with each other when a transistor of opposite polarity is used or when the direction of current is changed in circuit operation, for example. Therefore, the terms “source” and “drain” can sometimes be interchanged with each other in this specification and the like.

Note that impurities in a semiconductor refer to, for example, elements other than the main components of the semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. Note that water also serves as an impurity in some cases. In addition, oxygen vacancies (also referred to as V_{O}) are formed in an oxide semiconductor in some cases by entry of impurities, for example.

Note that in this specification and the like, an oxynitride is a material that contains more oxygen than nitrogen in its composition. Examples of oxynitride include silicon oxynitride, aluminum oxynitride, and hafnium oxynitride. Moreover, a nitride oxide is a material that contains more nitrogen than oxygen in its composition. Examples of nitride oxide include silicon nitride oxide, aluminum nitride oxide, and hafnium nitride oxide.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, the expression “parallel” indicates a state where two straight lines are placed at an angle greater than or equal to −10° and less than or equal to 10°. Accordingly, the case where the angle is greater than or equal to −5° and less than or equal to 5° is also included. Furthermore, the expression “substantially parallel” indicates a state where two straight lines are placed at an angle greater than or equal to −30° and less than or equal to 30°. Moreover, the expression “perpendicular” indicates a state where two straight lines are placed at an angle greater than or equal to 80° and less than or equal to 100°. Accordingly, the case where the angle is greater than or equal to 85° and less than or equal to 95° is also included. Furthermore, the expression “substantially perpendicular” indicates a state where two straight lines are placed at an angle greater than or equal to 60° and less than or equal to 120°.

In this specification and the like, a “voltage” and a “potential” can be replaced with each other as appropriate. A “voltage” refers to a potential difference from a reference potential, and when the reference potential is a ground potential, for example, a “voltage” can be replaced with a “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, when a plurality of components are denoted with the same reference numeral, and in particular need to be distinguished from each other, an identification sign such as “_1”, “[n]”, or “[m,n]” is sometimes added to the reference numeral.

Note that in this specification and the like, the expression “level with” indicates components having the same level from a reference surface (e.g., a flat surface such as a substrate surface) in a cross-sectional view. For example, in a manufacturing process of a memory device, planarization treatment (typically, chemical mechanical polishing (CMP) treatment) is performed, whereby the surface(s) of a single layer or a plurality of layers are exposed in some cases. In that case, the surfaces on which the CMP treatment is performed are at the same level from a reference surface. Note that a plurality of layers may be at different levels depending on a treatment apparatus, a treatment method, or a material of the treated surfaces, used for the CMP treatment. This case is also regarded as being “level with” in this specification and the like. For example, the expression “level with” also includes the case where two layers having different levels with respect to the reference surface (here, given as a first layer and a second layer) are provided to have a difference of less than or equal to 20 nm between the top-surface level of the first layer and the top-surface level of the second layer.

Note that in this specification and the like, the expression “end portions are aligned” means that at least outlines of stacked layers partly overlap with each other in a plan view. For example, the case of processing the upper layer and the lower layer with use of the same mask pattern or mask patterns that are partly the same is included. Note that, in some cases, the outlines do not exactly overlap with each other and the outline of the upper layer is positioned inward from the outline of the lower layer or the outline of the upper layer is positioned outward from the outline of the lower layer; such a case is also represented by the expression “end portions are aligned”.

In general, it is difficult to clearly differentiate “perfectly aligned” from “substantially aligned”. Therefore, in this specification and the like, the expression “aligned” includes both “perfectly aligned” and “substantially aligned”.

Note that in this specification and the like, “normally-on characteristics” means a state where a channel exists without application of a potential to a gate and current flows through the transistor. “Normally-off characteristics” mean a state where current does not flow through a transistor when no potential or a ground potential is applied to a gate.

In this specification and the like, “leakage current” sometimes expresses the same meaning as off-state current. Furthermore, in this specification and the like, the off-state current sometimes refers to current that flows between a source and a drain of a transistor in an off state, for example.

### Embodiment 1

In this embodiment, structure examples of a memory device of one embodiment of the present invention and a method for manufacturing the memory device will be described. One embodiment of the present invention includes a memory cell and a functional element on the same plane.

The memory cell includes a capacitor and a transistor over the capacitor. The capacitor has what is called an MIM (Metal-Insulator-Metal) structure that includes a pair of conductors and a dielectric sandwiched therebetween. The functional element includes a connection portion and a transistor over the connection portion. Here, the connection portion has a structure in which part of the dielectric in the capacitor is removed. In the connection portion, a pair of conductors are brought into conduction in the portion where the dielectric is not provided. That is, the memory cell and the functional element have the same structure except for the structure of the dielectric. With such a structure, the memory cell and the functional element including the transistor can be formed separately on the same plane by adding only a step of processing the dielectric.

In the functional element, one of a source electrode and a drain electrode of the transistor included in the functional element can be electrically connected to a wiring positioned below the connection portion. The transistor can be used as a switch for controlling conduction and non-conduction between the wiring and the other of the source electrode and the drain electrode, for example. A variety of peripheral circuits can be formed by using the functional element in combination.

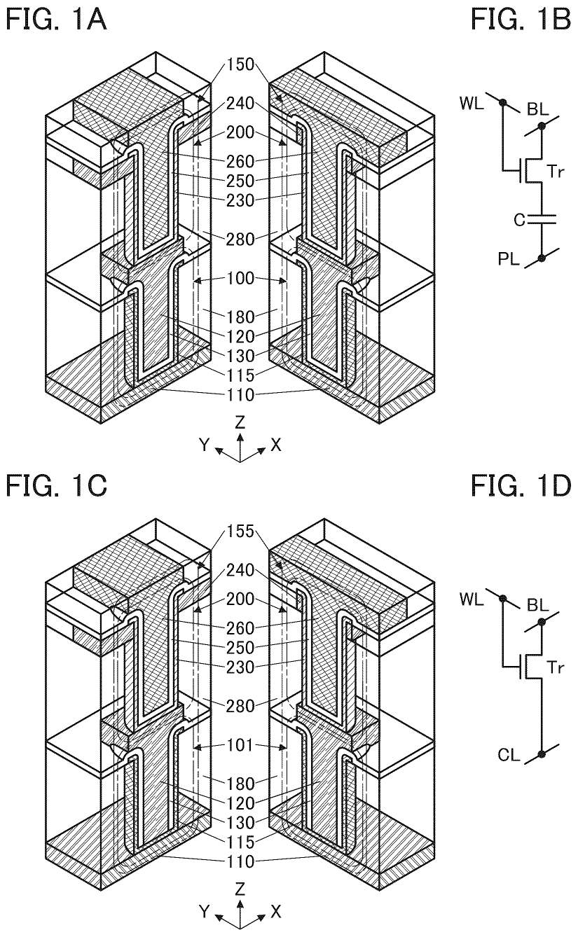

FIG. 1A is a cross-sectional perspective view of a region including a memory cell 150. A perspective view including a cut plane of the memory cell 150 cut along the X-Z plane and a perspective view including a cut plane of the memory cell 150 cut along the Y-Z plane are illustrated on the left side and the right side in FIG. 1A, respectively. In FIG. 1A, only the outlines of some components (e.g., an insulator 180 and an insulator 280) are indicated by a solid line.

Note that in the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases. The memory cell 150 includes a capacitor 100 over a conductor 110 and a transistor 200 over the capacitor 100.

The capacitor includes a conductor 115, a conductor 120, and an insulator 130 therebetween. The conductor 115, the insulator 130, and the conductor 120 are embedded inside an opening formed in the insulator 180.

The transistor 200 includes the conductor 120 functioning as one of a source electrode and a drain electrode, an oxide semiconductor 230, an insulator 250 functioning as a gate insulator, a conductor 260 functioning as a gate electrode, and a conductor 240 functioning as the other of the source electrode and the drain electrode. The conductor 240 is provided over the insulator 280. An opening reaching the conductor 120 is formed in the insulator 280. The oxide semiconductor 230 is provided along the inner wall of the opening and is in contact with the conductor 240 and the conductor 120.

In the transistor 200 having the above structure, the source electrode and the drain electrode are positioned at different heights, so that current flows in the semiconductor in the height direction. In other words, the channel length direction can be regarded as having a component of the height direction (the vertical direction); accordingly, the transistor of one embodiment of the present invention can also be referred to as a VFET (Vertical Field Effect Transistor), a vertical transistor, a vertical-channel transistor, and the like.

Since the source electrode, the semiconductor, and the drain electrode can be provided to overlap with each other in the transistor 200, the area occupied by the transistor 200 can be significantly smaller than that of what is called a planar transistor (also referred to as a lateral transistor, LFET (Lateral FET), or the like) in which a semiconductor is positioned over a flat surface.

Since the channel length of the transistor 200 can be precisely controlled by the thickness of the insulator 280 functioning as a spacer, a variation in the channel length can be extremely smaller than that of a planar transistor. Furthermore, by reducing the thickness of the insulator 280, a transistor with an extremely short channel length can be manufactured. For example, it is possible to manufacture a transistor with a channel length of less than or equal to 50 nm, less than or equal to 30 nm, or less than or equal to 20 nm and greater than or equal to 5 nm, greater than or equal to 7 nm, or greater than or equal to 10 nm. Thus, even with a conventional light-exposure apparatus for mass production, a transistor with a channel length of less than 10 nm can be obtained without using an extremely expensive light-exposure apparatus used in the latest LSI technology.

FIG. 1B is a circuit diagram corresponding to the memory cell 150. The transistor 200 and the capacitor 100 correspond to a transistor Tr and a capacitor C, respectively. The conductor 110, the conductor 240, and the conductor 260 correspond to a wiring PL, a wiring BL, and a wiring WL, respectively. The memory cell 150 includes one transistor Tr and one capacitor C and is also referred to as 1Tr1C.

FIG. 1C is a schematic perspective view of a region including a functional element 155. The functional element 155 includes a connection portion 101 and the transistor 200 over the connection portion 101. The transistor included in the functional element 155 has a structure similar to that of the transistor included in the memory cell 150; thus, the components are denoted by the same reference numeral and duplicate description is omitted.

The connection portion 101 has a structure in which part of the insulator 130 in the capacitor 100 is opened and the conductor 115 and the conductor 120 are in contact with each other in the opening. FIG. 1C illustrates an example in which a portion of the insulator 130 that is positioned at the bottom of the opening in the insulator 180 is removed and a portion along the side surface of the opening remains. Such a structure can be formed by performing anisotropic etching on the insulator 130, for example.

Since the conductor 120 and the conductor 115 are brought into conduction, the conductor 120 and the conductor 110 are brought into conduction through the conductor 115. In other words, the conductor 110 and one of the source electrode and the drain electrode of the transistor 200 are brought into conduction.

FIG. 1D is a circuit diagram corresponding to the functional element 155. The conductor 110, the conductor 240, and the conductor 260 correspond to a wiring CL, a wiring BL, and a wiring WL, respectively. In this manner, the functional element 155 can function as a switch for controlling conduction and non-conduction between the wiring BL and the wiring CL. The functional element 155 can be regarded as a single transistor.

In one embodiment of the present invention, the memory cell 150 and the functional element 155 can be separately formed on the same plane. For example, a memory cell array including a plurality of the memory cells 150 and a peripheral circuit can be formed on the same plane through the same process.

Hereinafter, a more specific example will be described.

### <Structure Example of Memory Device>

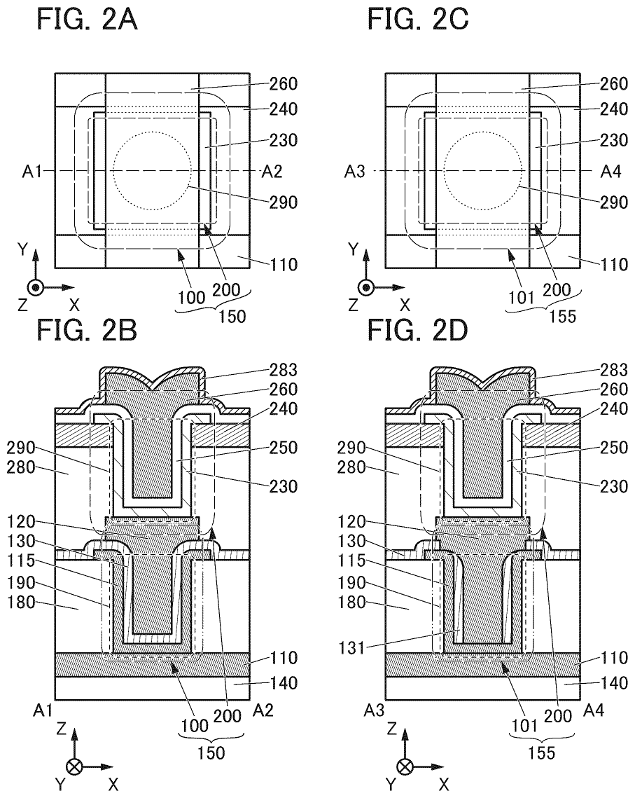

An example of a memory device including the memory cell 150 and the functional element 155 will be described below. FIG. 2A is a plan view of the memory cell 150 and FIG. 2B is a schematic cross-sectional view cut along the cutting line A1-A2 in FIG. 2A. FIG. 2C is a plan view of the functional element 155 and FIG. 2D is a schematic cross-sectional view cut along the cutting line A3-A4 in FIG. 2C. Note that some components are omitted in the plan views of FIG. 2A and FIG. 2C for clarity of the drawings.

The memory device includes an insulator 140 over a substrate (not illustrated), the conductor 110 over the insulator 140, the memory cell 150 and the functional element 155 over the conductor 110, the insulator 180 over the conductor 110, the insulator 280, and an insulator 283 over the memory cell 150 and the functional element 155. The insulator 140, the insulator 180, the insulator 280, and the insulator 283 function as interlayer films. The conductor 110 functions as a wiring. Note that the conductor 110 electrically connected to the memory cell 150 and the conductor 110 electrically connected to the functional element 155 may each function as an independent wiring or may be brought into conduction. Similarly, the conductor 240 and the conductor 260 included in the memory cell 150 and the conductive layer 240 and the conductive layer 260 included in the functional element 155 may each function as an independent wiring or two or more of them may be brought into conduction.

The memory cell 150 includes the capacitor 100 over the conductor 110 and the transistor 200 over the capacitor 100. The functional element 155 includes the connection portion 101 over the conductor 110 and the transistor 200 over the connection portion 101.

The capacitor 100 includes the conductor 115 over the conductor 110, the insulator 130 over the conductor 115, and the conductor 120 over the insulator 130. The conductor 120 functions as one of a pair of electrodes (sometimes referred to as an upper electrode), the conductor 115 functions as the other of the pair of electrodes (sometimes referred to as a lower electrode), and the insulator 130 functions as a dielectric. That is, the capacitor 100 forms a MIM (Metal-Insulator-Metal) capacitor.

As illustrated in FIG. 2B, an opening portion 190 reaching the conductor 110 is formed in the insulator 180. At least part of the conductor 115 is positioned in the opening portion 190. Note that the conductor 115 includes a region in contact with the top surface of the conductor 110 in the opening portion 190, a region in contact with a side surface of the insulator 180 in the opening portion 190, and a region in contact with at least part of the top surface of the insulator 180. The insulator 130 is provided such that at least part of the insulator 130 is positioned in the opening portion 190. The conductor 120 is provided such that at least part of the conductor 120 is positioned in the opening portion 190. Note that the conductor 120 is preferably provided to fill the opening portion 190 as illustrated in FIG. 2B.

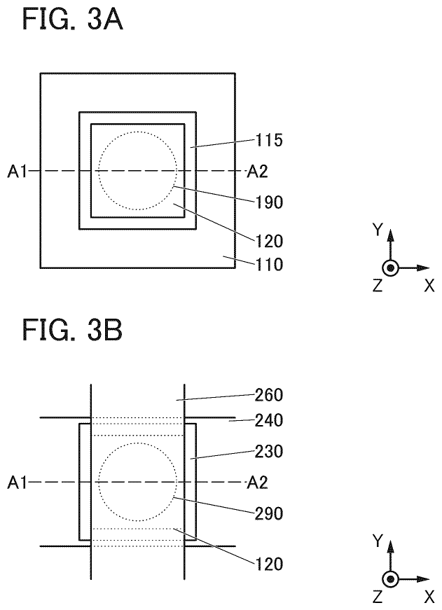

FIG. 3A is a plan view selectively illustrating the conductor 110, the conductor 115, the conductor 120, and the opening portion 190. Note that the opening portion 190 formed in the insulator 180 is indicated by dashed lines. As illustrated in FIG. 3A, the conductor 115 has the opening portion 190 in a region overlapping with the conductor 110.

The capacitor 100 has a structure in which the upper electrode and the lower electrode face each other with the dielectric therebetween on the side surface as well as the bottom surface of the opening portion 190; thus, the capacitance per unit area can be increased. Thus, the deeper the opening portion 190 is, the larger the capacitance of the capacitor 100 can be. Increasing the capacitance per unit area of the capacitor 100 in this manner enables stable reading operation of the memory device.

A sidewall of the opening portion 190 is preferably perpendicular to the top surface of the conductor 110. In that case, the opening portion 190 has a cylindrical shape. Such a structure enables the memory device to be miniaturized or highly integrated.

The conductor 115 and the insulator 130 are stacked along the sidewall of the opening portion 190 and the top surface of the conductor 110. The conductor 120 is provided over the insulator 130 to fill the opening portion 190. The capacitor 100 having such a structure may be referred to as a trench-type capacitor or a trench capacitor.

The insulator 280 is positioned over the capacitor 100. That is, the insulator 280 is positioned over the conductor 115, the insulator 130, and the conductor 120. In other words, the conductor 120 is positioned under the insulator 280.

The transistor 200 includes the conductor 120, the conductor 240 over the insulator 280, the oxide semiconductor 230, the insulator 250 over the oxide semiconductor 230, and the conductor 260 over the insulator 250. The oxide semiconductor 230 functions as a semiconductor layer, the conductor 260 functions as a gate electrode, the insulator 250 functions as a gate insulator, the conductor 120 functions as one of a source electrode and a drain electrode, and the conductor 240 functions as the other of the source electrode and the drain electrode.

As illustrated in FIG. 2B, an opening portion 290 reaching the conductor 120 is formed in the insulator 280 and the conductor 240. At least part of the oxide semiconductor 230 is positioned in the opening portion 290. Note that the oxide semiconductor 230 includes a region in contact with the top surface of the conductor 120 in the opening portion 290, a region in contact with a side surface of the conductor 240 in the opening portion 290, and a region in contact with at least part of the top surface of the conductor 240. The insulator 250 is provided such that at least part of the insulator 250 is positioned in the opening portion 290. The conductor 260 is provided such that at least part of the conductor 260 is positioned in the opening portion 290. Note that the conductor 260 is preferably provided to fill the opening portion 290 as illustrated in FIG. 2B.

FIG. 3B is a plan view selectively illustrating the conductor 120, the oxide semiconductor 230, the conductor 240, the conductor 260, and the opening portion 290. Note that the opening portion 290 formed in the insulator 280 is indicated by dashed lines. As illustrated in FIG. 3B, the conductor 240 has the opening portion 290 in a region overlapping with the conductor 120. It is preferable that the conductor 240 not be provided inside the opening portion 290. That is, it is preferable that the conductor 240 not include a region in contact with a side surface of the insulator 280 on the opening portion 290 side.

The oxide semiconductor 230 includes the region in contact with the side surface of the conductor 240 in the opening portion 290 and the region in contact with part of the top surface of the conductor 240. When the oxide semiconductor 230 is in contact with not only the side surface but also the top surface of the conductor 240 in this manner, the area where the oxide semiconductor 230 and the conductor 240 are in contact with each other can be increased.

As illustrated in FIG. 2B, the transistor 200 is provided to overlap with the capacitor 100. The opening portion 290 where some of the components of the transistor 200 are provided includes a region overlapping with the opening portion 190 where some of the components of the capacitor 100 are provided. In particular, since the conductor 120 functions as one of the source electrode and the drain electrode of the transistor 200 and as the upper electrode of the capacitor 100, the transistor 200 and the capacitor 100 share part of the structure. With such a structure, the transistor 200 and the capacitor 100 can be provided without significantly increasing the occupation area in the plan view. Thus, the occupation area of the memory cell 150 can be reduced, so that the memory cells 150 can be arranged densely and the memory capacity of the memory device can be increased. In other words, the memory device can be highly integrated.

The functional element 155 illustrated in FIG. 2C and FIG. 2D includes the transistor 200 and the connection portion 101. The transistor 200 has a structure similar to that of the memory cell 150. The functional element 155 has substantially the same structure as the memory cell 150 except that the insulator 130 has a different structure, that the insulator 131 is provided, and that the conductor 115 and the conductor 120 are in contact with each other.

In the functional element 155, an opening portion overlapping with the opening portion 190 is formed in the insulator 130. The opening portion of the insulator 130 is preferably formed to cover the opening portion 190. That is, in the plan view, the opening portion 190 is preferably positioned inside the opening portion of the insulator 130.

The insulator 131 is provided inside the opening portion 190 along a portion of the conductor 115 provided along the inner wall of the insulator 180. The insulator 131 is in contact with the conductor 115 and the conductor 120. The insulator 130 and the insulator 131 are formed by processing the same insulating film and contain the same element. The insulator 131 is formed in the following manner: part of the insulator 130 remains when a portion of the insulator 130 that is positioned in the bottom portion of the opening portion 190 is removed by anisotropic etching. The insulator 131 can also be referred to as a sidewall insulator.

Note that the insulator 131 is not formed in some cases depending on the method for processing an insulating film to be the insulator 130. In that case, the area where the conductor 120 and the conductor 115 are in contact with each other is large, which is preferable.

### [Capacitor 100]

The capacitor 100 includes the conductor 115, the insulator 130, and the conductor 120. The conductor 110 is provided below the conductor 115. The conductor 115 includes a region in contact with the conductor 110.

The conductor 110 is provided over the insulator 140. The conductor 110 functions as a wiring and can be provided in a planar shape, for example. As the conductor 110, a single layer or stacked layers of any of the conductors described in the section [Conductor] below can be used. For example, a conductive material with high conductivity such as tungsten can be used as the conductor 110.

For the conductor 115, a single layer or stacked layers of a conductive material that is less likely to be oxidized, a conductive material that is less likely to allow diffusion of oxygen, or the like is preferably used. In that case, an increase in resistance due to oxidation can be inhibited even when an oxide insulator is used as the insulator (the insulator 130 and the insulator 180) in contact with the conductor 115. For example, a nitride such as titanium nitride or tantalum nitride may be used. Alternatively, an oxide such as indium tin oxide or indium tin oxide to which silicon is added may be used. Alternatively, a stacked-layer structure such as a structure in which titanium nitride is stacked over tungsten or a structure in which tungsten is stacked over first titanium nitride and second titanium nitride is stacked over the tungsten may be employed.

The insulator 130 is provided over the conductor 115. The insulator 130 is provided to be in contact with the top and side surfaces of the conductor 115. That is, a structure in which the insulator 130 covers the side end portion of the conductor 110 is preferably employed. In that case, a short circuit between the conductor 115 and the conductor 120 can be prevented.

Alternatively, a structure may be employed in which the side end portion of the insulator 130 and the side end portion of the conductor 115 are aligned with each other. Such a structure enables the insulator 130 and the conductor 115 to be formed using the same mask, so that the manufacturing process of the memory device can be simplified.

For the insulator 130, any of the materials with high relative permittivity, that is, high-k materials, described in the section [Insulator] below is preferably used. Using the high-k material for the insulator 130 allows the insulator 130 to be thick enough to inhibit a leakage current and the capacitor 100 to have a sufficiently high capacitance.

It is preferable to use, as the insulator 130, stacked insulators formed of any of the high-k materials; it is preferable to use a stacked-layer structure of a material having high relative permittivity (high-k material) and a material having higher dielectric strength than the high-k material. As the insulator 130, an insulating film in which zirconium oxide, aluminum oxide, and zirconium oxide are stacked in this order can be used, for example. Alternatively, an insulating film in which zirconium oxide, aluminum oxide, zirconium oxide, and aluminum oxide are stacked in this order can be used, for example. Alternatively, an insulating film in which hafnium zirconium oxide, aluminum oxide, hafnium zirconium oxide, and aluminum oxide are stacked in this order can be used, for example. The use of stacked insulators with relatively high dielectric strength, such as aluminum oxide, can increase the dielectric strength and inhibit electrostatic breakdown of the capacitor 100.

Alternatively, a material that exhibits ferroelectricity may be used for the insulator 130. Examples of the material that exhibits ferroelectricity include metal oxides such as hafnium oxide, zirconium oxide, and HfZrO_{X} (X is a real number greater than 0). Examples of the material that exhibits ferroelectricity also include a material in which an element J1 (the element J1 here is one or more selected from zirconium (Zr), silicon (Si), aluminum (Al), gadolinium (Gd), yttrium (Y), lanthanum (La), strontium (Sr), and the like) is added to hafnium oxide. Here, the atomic ratio of hafnium to the element J1 can be set as appropriate; the atomic ratio of hafnium to the element J1 is, for example, 1:1 or the neighborhood thereof. Examples of the material that exhibits ferroelectricity also include a material in which an element J2 (the element 2 here is one or more selected from hafnium (Hf), silicon (Si), aluminum (Al), gadolinium (Gd), yttrium (Y), lanthanum (La), strontium (Sr), and the like) is added to zirconium oxide. The atomic ratio of zirconium to the element J2 can be set as appropriate; the atomic ratio of zirconium to the element J2 is, for example, 1:1 or the neighborhood thereof. As the material that exhibits ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that exhibits ferroelectricity also include a metal nitride containing an element M1, an element M2, and nitrogen. Here, the element M1 is one or more selected from aluminum (Al), gallium (Ga), indium (In), and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that exhibits ferroelectricity also include a material in which an element M3 is added to the above metal nitride. Note that the element M3 is one or more selected from magnesium (Mg), calcium (Ca), strontium (Sr), zinc (Zn), cadmium (Cd), and the like. Here, the atomic ratio of the element M1 to the element M2 and the element M3 can be set as appropriate.

Examples of the material that exhibits ferroelectricity also include a perovskite-type oxynitride such as SrTaO₂N or BaTaO₂N and GaFeO₃ with a k-alumina-type structure.

Note that although metal oxides and metal nitrides are given as examples in the above description, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that exhibits ferroelectricity, a mixture or compound containing a plurality of materials selected from the above-listed materials can be used, for example. Alternatively, the insulator 130 can have a stacked-layer structure of a plurality of materials selected from the above-listed materials. Note that the crystal structures (properties) of the above-listed materials and the like can be changed depending on the processes as well as the deposition conditions; thus, not only a material that exhibits ferroelectricity or a material that shows ferroelectricity but also a material that can have ferroelectricity is referred to as a ferroelectric or the like in some cases.

A metal oxide containing one or both of hafnium and zirconium is preferable because the metal oxide can exhibit ferroelectricity even when being processed into a thin film of several nanometers. Here, the thickness of the insulator 130 is less than or equal to 100 nm, preferably less than or equal to 50 nm, further preferably less than or equal to 20 nm, still further preferably less than or equal to 10 nm. When the ferroelectric layer that can be thin is used, the capacitor 100 can be combined with a miniaturized semiconductor element such as a transistor to manufacture a semiconductor device.

A metal oxide containing one or both of hafnium and zirconium is preferable because the metal oxide can exhibit ferroelectricity even with a minute area. For example, a ferroelectric layer may have ferroelectricity even with an area (occupying area) less than or equal to 100 μm², less than or equal to 10 μm², less than or equal to 1 μm², less than or equal to 0.1 μm², less than or equal to 10000 nm², or less than or equal to 1000 nm². With a small-area ferroelectric layer, the area occupied by the capacitor 100 can be reduced.

The ferroelectric is an insulator having a property of causing internal polarization by application of an electric field from the outside and maintaining the polarization even after the electric field is made zero. Thus, with the use of a capacitor that includes this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor 100, the memory device described in this embodiment functions as a ferroelectric memory.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer; in order that the insulator 130 can exhibit ferroelectricity, the insulator 130 needs to include a crystal. It is particularly preferable that the insulator 130 include a crystal having an orthorhombic crystal structure, in which case the insulator 130 exhibits ferroelectricity. A crystal included in the insulator 130 may have one or more of crystal structures selected from cubic, tetragonal, orthorhombic, monoclinic, and hexagonal crystal structures. Alternatively, the insulator 130 may have an amorphous structure. In that case, the insulator 130 may have a composite structure including an amorphous structure and a crystal structure.

The conductor 120 is provided in contact with part of the top surface of the insulator 130. As illustrated in FIG. 2B, the side end portion of the conductor 120 is preferably positioned inside the side end portion of the conductor 115 in both the X direction and the Y direction. Note that in the structure where the insulator 130 covers the side end portion of the conductor 115, the side end portion of the conductor 120 may be positioned outside the side end portion of the conductor 115.

As the conductor 120, a single layer or stacked layers of any of the conductors described in the section [Conductor] below can be used. A conductive material that is less likely to be oxidized or a conductive material that is less likely to allow diffusion of oxygen is preferably used for the conductor 120. For example, titanium nitride, tantalum nitride, or the like can be used. For example, a structure in which tantalum nitride is stacked over titanium nitride may be used. In that case, titanium nitride is in contact with the insulator 130 and tantalum nitride is in contact with the oxide semiconductor 230. Such a structure can inhibit excessive oxidation of the conductor 120 due to the oxide semiconductor 230. In the case of using an oxide insulator as the insulator 130, excessive oxidation of the conductor 120 due to the insulator 130 can be inhibited. Alternatively, the conductor 120 may have a structure in which tungsten is stacked over titanium nitride, for example.

The conductor 120 includes a region in contact with the oxide semiconductor 230 and thus is preferably formed using any of the conductive materials containing oxygen described in the section [Conductor] below. When the conductive material containing oxygen is used for the conductor 120, the conductor 120 can maintain its conductivity even when absorbing oxygen. In addition, an insulator containing oxygen such as zirconium oxide is preferably used as the insulator 130, in which case the conductor 120 can maintain its conductivity. As the conductor 120, a single layer or stacked layers of indium tin oxide (also referred to as ITO), indium tin oxide to which silicon is added (also referred to as ITSO), indium zinc oxide (IZO (registered trademark)), or the like can be used, for example.

The insulator 180 functions as an interlayer film and thus preferably has low relative permittivity. When a material with low relative permittivity is used for an interlayer film, parasitic capacitance generated between wirings can be reduced. As the insulator 180, a single layer or stacked layers of an insulator containing any of the materials with low relative permittivity described in the section [Insulator] below can be used. Silicon oxide and silicon oxynitride are preferable because they are thermally stable. In that case, the insulator 180b contains at least silicon and oxygen.

Note that although the insulator 180 has a single layer in FIG. 2B and FIG. 2D, the present invention is not limited thereto. The insulator 180 may have a stacked-layer structure.

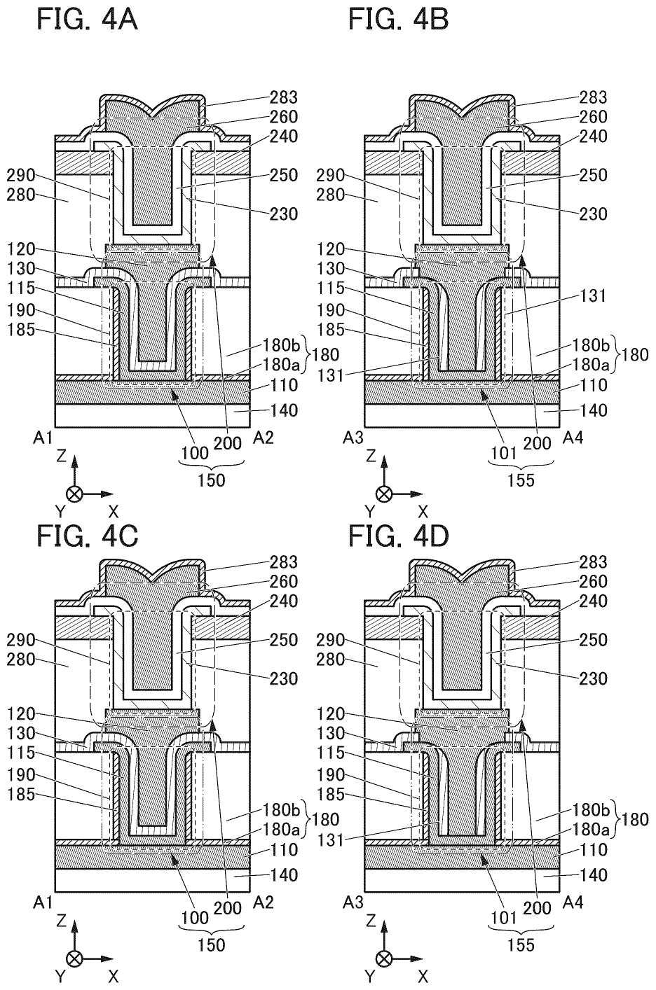

For example, as illustrated in FIG. 4A and FIG. 4B, the insulator 180 may have a stacked-layer structure of an insulator 180a and an insulator 180b over the insulator 180a.

For the insulator 180b, any of the above-described insulating materials that can be used for the insulator 180 is preferably used.

As the insulator 180a, any of the insulators having a barrier property against oxygen described in the section [Insulator] below is preferably used. When the insulator 180b and the conductor 110 are in contact with each other, the conductor 110 is oxidized by oxygen contained in the insulator 180b and has high resistance in some cases. Thus, the insulator 180a is preferably provided between the insulator 180b and the conductor 110.

When impurities such as hydrogen enter the insulator 130, leakage current generated between the upper electrode and the lower electrode is increased in some cases. In the case where a material showing ferroelectricity is used for the insulator 130, entry of impurities such as hydrogen into the material showing ferroelectricity might reduce the crystallinity of the material showing ferroelectricity. It is thus preferable to inhibit entry of impurities such as hydrogen into the insulator 130.

Thus, for the insulator 180a, any of the insulators having a barrier property against hydrogen described in the section [Insulator] below is preferably used. In that case, diffusion of hydrogen into the insulator 130 through the insulator 180b and the conductor 115 can be inhibited. Silicon nitride and silicon nitride oxide can be suitably used for the insulator 180a because they release few impurities (e.g., water and hydrogen) and are unlikely to transmit oxygen and hydrogen. In that case, the insulator 180a contains at least silicon and nitrogen.

As the insulator 180a, any of the insulators having a function of capturing or fixing hydrogen described in the section [Insulator] below is preferably used. With such a structure, hydrogen in the insulator 130 can be captured or fixed, so that the concentration of hydrogen in the insulator 130 can be reduced. For the insulator 180a, magnesium oxide, aluminum oxide, hafnium oxide, or the like can be used. Alternatively, for example, a stacked-layer film of aluminum oxide and silicon nitride over the aluminum oxide may be used as the insulator 180a.

Note that although the insulator 180 has the stacked-layer structure of two layers in FIG. 4A and FIG. 4B, one embodiment of the present invention is not limited thereto. The insulator 180 may have a stacked structure of three or more layers.

For example, in the case where the insulator 180 has a stacked-layer structure of three layers, an insulator is preferably provided between the insulator 180b and the conductor 115 and the insulator 130, in addition to the insulator 180a and the insulator 180b. As the insulator, an insulator that can be used as the insulator 180a can be used. This can inhibit diffusion of hydrogen into the insulator 130 through the insulator 180b.

As illustrated in FIG. 4A and FIG. 4B, an insulator 185 is preferably provided between the conductor 115 and the insulator 180. The insulator 185 is preferably provided in contact with a side surface of the insulator 180 in the opening portion 190. That is, the insulator 185 is preferably provided between the conductor 115 and the side surface of the insulator 180 in the opening portion 190.

As the insulator 185, any of the above-described insulators having a barrier property against hydrogen is preferably used. In that case, diffusion of hydrogen into the insulator 130 from the outside of the capacitor 100 through the insulator 180 can be inhibited. As the insulator 185, any of the above-described insulators having a function of capturing or fixing hydrogen is preferably used. In that case, hydrogen in the insulator 130 can be captured or fixed, so that the concentration of hydrogen in the insulator 130 can be reduced.

Note that although the insulator 185 is provided in contact with a side surface of the insulator 180a in the opening portion 190 and a side surface of the insulator 180b in the opening portion 190 in FIG. 4A and FIG. 4B, the present invention is not limited thereto. For example, as illustrated in FIG. 4C and FIG. 4D, the insulator 185 may be provided in contact with part of the top surface of the insulator 180a and the side surface of the insulator 180b in the opening portion 190.

Note that although the conductor 120 is positioned on the inner side of the conductor 115 with the insulator 130 therebetween in FIG. 2B and FIG. 2D, the present invention is not limited thereto. For example, the conductor 120 may be positioned on the outer side of the conductor 115 with the insulator 130 therebetween.

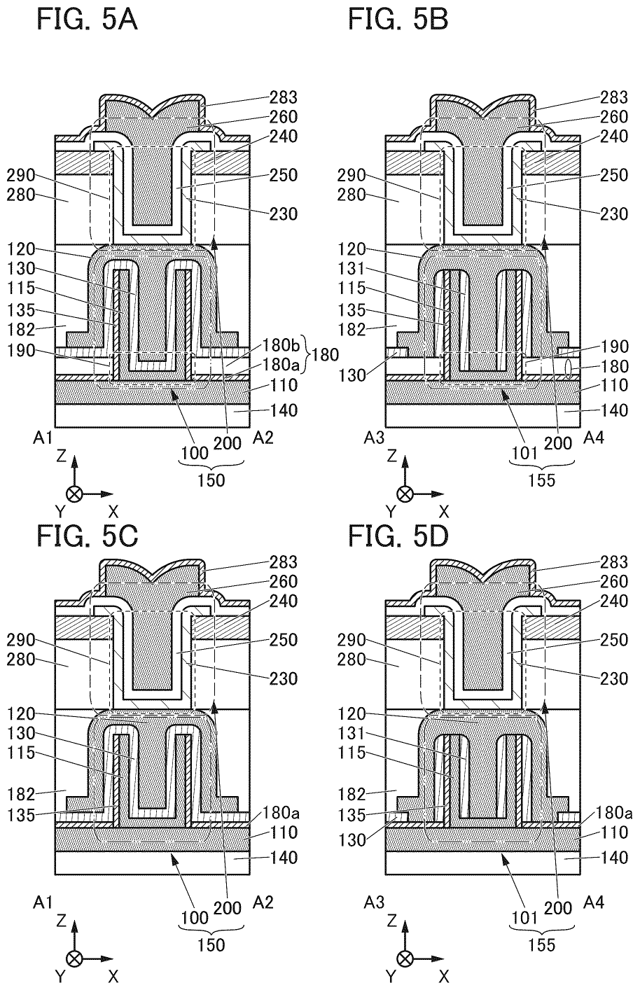

For example, as illustrated in FIG. 5A and FIG. 5B, the insulator 130 includes a region positioned on the outer side surface side of the conductor 115 in addition to a region in contact with the inner side of a depressed portion defined by the conductor 115 and a region in contact with the top surface of the conductor 115.

The conductor 120 is provided to fill the depressed portion defined by the conductor 115 with the insulator 130 therebetween. Furthermore, the conductor 120 includes a region facing the part of the outer side surface of the conductor 115 with the insulator 130 therebetween.

With the above structure, the capacitance per unit area can be further increased.

Note that as illustrated in FIG. 5A and FIG. 5B, an insulator 135 may be provided between the outer side surface of the conductor 115 and the insulator 130 and the insulator 180.

An insulator 182 may be provided over the conductor 120 and the insulator 130. The insulator 182 is preferably subjected to planarization treatment so that the top surface of the conductor 120 is exposed. The planarization treatment performed on the insulator 182 allows the transistor 200 to be suitably formed over the capacitor 100.

The insulator 182 functions as an interlayer film and thus preferably has low relative permittivity. When a material with low relative permittivity is used for an interlayer film, parasitic capacitance generated between wirings can be reduced. As the insulator 182, an insulator that can be used as the insulator 180 can be used.

Note that the insulator 180 is not necessarily provided in the case where sufficient capacitance can be ensured as a memory cell with a structure in which the conductor 120 is provided to face the inner side and the outer side of the conductor 115 as illustrated in FIG. 5A and FIG. 5B.

Memory devices illustrated in FIG. 5C and FIG. 5D are different from the memory devices illustrated in FIG. 5A and FIG. 5B in that the insulator 180b is not provided. By not providing the insulator 180b, the manufacturing process of the memory device can be simplified.

### [Transistor 200]

As illustrated in FIG. 2A to FIG. 2D, the transistor 200 can include the conductor 120; the conductor 240 over the insulator 280; the oxide semiconductor 230 provided in contact with the top surface of the conductor 120 exposed in the opening portion 290, a side surface of the insulator 280 in the opening portion 290, a side surface of the conductor 240 in the opening portion 290, and at least part of the top surface of the conductor 240; the insulator 250 provided in contact with the top surface of the oxide semiconductor 230; and the conductor 260 provided in contact with the top surface of the insulator 250.

At least some of the components of the transistor 200 are provided in the opening portion 290. Here, the bottom portion of the opening portion 290 is the top surface of the conductor 120, and a sidewall of the opening portion 290 is a side surface of the insulator 280 and a side surface of the conductor 240.

The sidewall of the opening portion 290 is preferably perpendicular to the top surface of the conductor 110. In that case, the opening portion 290 has a cylindrical shape. Such a structure enables the memory device to be miniaturized or highly integrated.

Although an example in which the opening portion 290 is circular in the plan view is described in this embodiment, the present invention is not limited thereto. For example, the opening portion 290 can have an elliptical shape or a quadrangular shape with rounded corners besides the circular shape in the plan view. Alternatively, a regular polygonal shape such as a regular triangular shape, a square shape, or a regular pentagonal shape or a polygonal shape other than the regular polygonal shape may be employed. By employing a depressed polygonal shape in which at least one interior angle is greater than 180°, such as a star polygonal shape, the channel width can be increased. Alternatively, an elliptical shape, a quadrangular shape with rounded corners, a closed curve in which a straight line and a curve are combined, or the like can be employed. In that case, the maximum width of the opening portion 290 is calculated as appropriate in accordance with the shape of the uppermost portion of the opening portion 290. For example, in the case where the opening portion is square or rectangular in the plan view, the maximum width of the opening portion 290 may be the length of a diagonal line of the uppermost portion of the opening portion 290.

Portions of the oxide semiconductor 230, the insulator 250, and the conductor 260 that are positioned in the opening portion 290 reflect the shape of the opening portion 290. Therefore, the oxide semiconductor 230 is provided so as to cover the bottom portion and the sidewall of the opening portion 290, the insulator 250 is provided so as to cover the oxide semiconductor 230, and the conductor 260 is provided so as to be embedded in a depressed portion of the insulator 250 that reflects the shape of the opening portion 290.

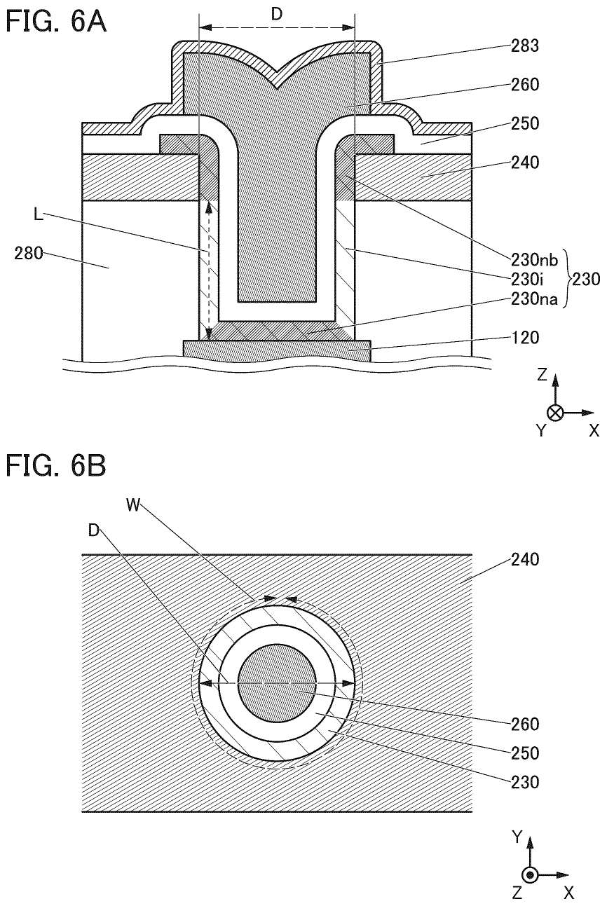

FIG. 6A is an enlarged view of the oxide semiconductor 230 and its vicinity in FIG. 2B. FIG. 6B is a cross-sectional view taken along the XY plane including the conductor 240.

As illustrated in FIG. 6A, the oxide semiconductor 230 includes a region 230i, and a region 230na and a region 230nb provided such that the region 230i is sandwiched therebetween.

The region 230na is a region in contact with the conductor 120 in the oxide semiconductor 230. At least part of the region 230na functions as one of a source region and a drain region of the transistor 200. The region 230nb is a region of the oxide semiconductor 230 that is in contact with the conductor 240. At least part of the region 230nb functions as the other of the source region and the drain region of the transistor 200. As illustrated in FIG. 6B, the conductor 240 is in contact with the entire outer circumference of the oxide semiconductor 230. Thus, the other of the source region and the drain region of the transistor 200 can be formed along the entire outer circumference of a portion of the oxide semiconductor 230 that is formed in the same layer as the conductor 240.

The region 230i is a region of the oxide semiconductor 230 that is positioned between the region 230na and the region 230nb and functions as a channel formation region. The channel formation region of the transistor 200 can be regarded as a region in contact with the insulator 280 or a region in the vicinity thereof.

The channel length of the transistor 200 is a distance between the source region and the drain region. In other words, the channel length of the transistor 200 is determined by the thickness of the insulator 280 over the conductor 120. In FIG. 6A, a channel length L of the transistor 200 is indicated by a dashed double-headed arrow. In a cross-sectional view, the channel length L is a distance between an end portion of a region where the oxide semiconductor 230 and the conductor 120 are in contact with each other and an end portion of a region where the oxide semiconductor 230 and the conductor 240 are in contact with each other. That is, the channel length L corresponds to the length of a side surface of the insulator 280 on the opening portion 290 side in the cross-sectional view.

In a planar transistor, the channel length is determined by the light exposure limit of photolithography. In the present invention, the channel length can be determined by the thickness of the insulator 280. Thus, the transistor 200 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 200 can have higher on-state current and improved frequency characteristics. Accordingly, the read speed and the write speed of the memory cell 150 can be increased, whereby a memory device with a high operation speed can be provided.

In addition, as described above, the channel formation region, the source region, and the drain region can be formed in the opening portion 290. Thus, the area occupied by the transistor 200 can be reduced as compared with a planar transistor in which the channel formation region, the source region, and the drain region are provided separately on the XY plane. This allows high integration of the memory device; therefore, the memory capacity per unit area can be increased.

Furthermore, in the XY plane including the channel formation region of the oxide semiconductor 230, as illustrated in FIG. 6B, the oxide semiconductor 230, the insulator 250, and the conductor 260 are provided concentrically. Therefore, a side surface of the conductor 260 provided at the center faces a side surface of the oxide semiconductor 230 with the insulator 250 therebetween. That is, in the plan view, all the perimeter of the oxide semiconductor 230 serves as the channel formation region. In this case, for example, the channel width of the transistor 200 is determined by the length of the outer circumference of the oxide semiconductor 230. In other words, the channel width of the transistor 200 is determined by the maximum width of the opening portion 290 (the diameter in the case where the opening portion 290 is circular in the plan view). In FIG. 6A and FIG. 6B, the maximum width D of the opening portion 290 is indicated by a dashed double-dotted double-headed arrow. In FIG. 6B, the channel width W of the transistor 200 is indicated by a dashed-dotted double-headed arrow. By increasing the maximum width D of the opening portion 290, the channel width per unit area can be increased and the on-state current can be increased.

In the case where the opening portion 290 is formed by a photolithography method, the maximum width D of the opening portion 290 is determined by the light exposure limit of photolithography. In addition, the maximum width D of the opening portion 290 is determined by the thicknesses of the oxide semiconductor 230, the insulator 250, and the conductor 260 provided in the opening portion 290. The maximum width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in the plan view, the maximum width D of the opening portion 290 corresponds to the diameter of the opening portion 290, and the channel width W can be “D×π”.

In the memory device of one embodiment of the present invention, the channel length L of the transistor 200 is preferably shorter than at least the channel width W of the transistor 200. The channel length L of the transistor 200 in one embodiment of the present invention is greater than or equal to 0.1 times and less than or equal to 0.99 times, preferably greater than or equal to 0.5 times and less than or equal to 0.8 times the channel width W of the transistor 200. This structure enables a transistor with favorable electrical characteristics and high reliability.

In the case where the opening portion 290 is formed to be circular in the plan view, the oxide semiconductor 230, the insulator 250, and the conductor 260 are formed concentrically. This makes the distance between the conductor 260 and the oxide semiconductor 230 substantially uniform, so that a gate electric field can be substantially uniformly applied to the oxide semiconductor 230.

It is preferable that the channel formation region of the transistor including an oxide semiconductor in the semiconductor layer contain less oxygen vacancies or have a lower concentration of impurities such as hydrogen, nitrogen, and a metal element than the source region and the drain region. In some cases, hydrogen in the vicinity of an oxygen vacancy forms a defect that is an oxygen vacancy into which hydrogen enters (hereinafter sometimes referred to as V_{O}H), which generates an electron serving as a carrier. Therefore, it is preferable that V_{O}H be also decreased in the channel formation region. Thus, the channel formation region of the transistor is a high-resistance region having a low carrier concentration. Thus, the channel formation region of the transistor can be regarded as being i-type (intrinsic) or substantially i-type.

The source region and the drain region of the transistor including an oxide semiconductor in the semiconductor layer are each a region that has lower resistance than the channel formation region by having an increased carrier concentration because of containing more oxygen vacancies or more V_{O}H or having a higher concentration of impurities such as hydrogen, nitrogen, and a metal element. In other words, the source region and the drain region of the transistor are each an n-type region having a higher carrier concentration and a lower resistance than the channel formation region.

Although the opening portion 290 is provided so that the sidewall of the opening portion 290 is perpendicular to the top surface of the conductor 110 in FIG. 2B and FIG. 2D, the present invention is not limited thereto. The sidewall of the opening portion 290 may have a tapered shape, for example.

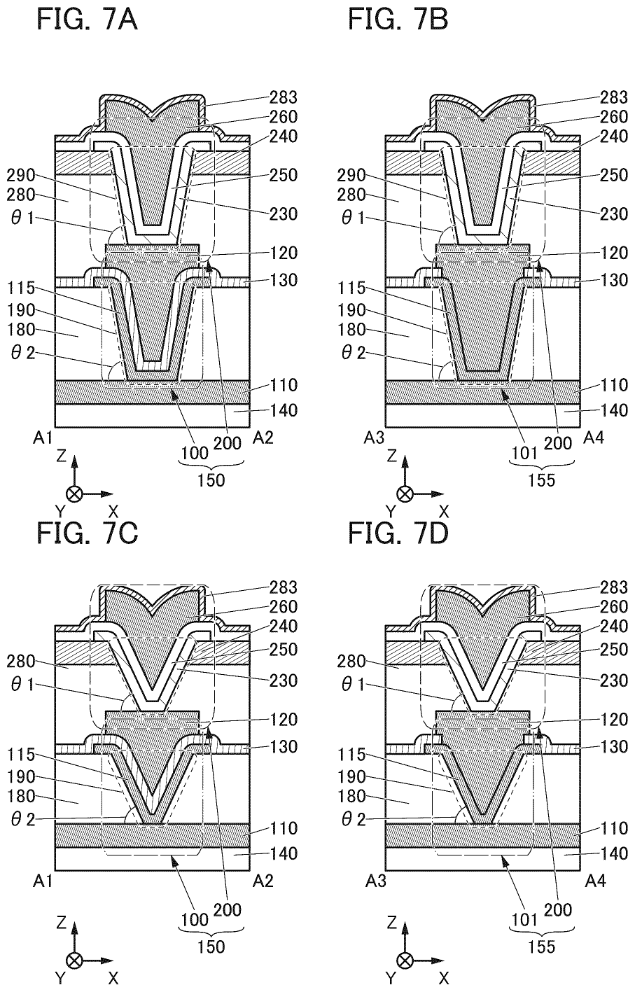

In memory devices illustrated in FIG. 7A and FIG. 7B, a sidewall of the opening portion 290 has a tapered shape. Note that FIG. 2A can be referred to for the plan view of the memory devices illustrated in FIG. 7A and FIG. 7B.

When the sidewall of the opening portion 290 has a tapered shape, the coverage with the oxide semiconductor 230, the insulator 250, or the like can be improved, so that defects such as voids can be reduced. For example, the angle formed by a side surface of the insulator 280 in the opening portion 290 and the top surface of the conductor 120 (an angle θ1 illustrated in FIG. 7A) is preferably greater than or equal to 45° and less than 90°. Alternatively, the angle is preferably greater than or equal to 45° and less than or equal to 75°. Alternatively, the angle is preferably greater than or equal to 45° and less than or equal to 65°.

Note that in this specification and the like, the tapered shape refers to a shape such that at least part of a side surface of a component is inclined to a substrate surface or a formation surface. For example, the tapered shape includes a region where the angle formed by the inclined side surface and the substrate surface (the angle is hereinafter referred to as a taper angle in some cases) is less than 90°. Note that the side surface of the component and the substrate surface are not necessarily completely flat and may be substantially flat with a slight curvature or substantially flat with slight unevenness.

The opening portion 290 illustrated in FIG. 7A and FIG. 7B has a truncated cone shape. In this case, the opening portion 290 is circular in the plan view and is trapezoidal in the cross-sectional view. The area of the upper base of the truncated cone shape (e.g., the opening portion formed in the conductor 240) is smaller than the area of the lower base of the truncated cone (the top surface of the conductor 120 exposed in the opening portion 290). In this case, the maximum diameter of the opening portion 290 is preferably calculated on the basis of the upper base of the truncated cone.

In the case where the sidewall of the opening portion 290 has a tapered shape, the channel length can be set by the thickness of the insulator 280 and the angle θ1 formed by the side surface of the insulator 280 in the opening portion 290 and the top surface of the conductor 120. The length of the outer circumference of the oxide semiconductor 230 is determined, for example, in a region facing the conductor 240 or at half of the thickness of the insulator 280. Note that the length of the circumference of the opening portion 290 in an arbitrary position may be regarded as the channel width of the transistor 200. For example, the length of the circumference at the lowest portion of the opening portion 290 may be regarded as the channel width, or the length of the circumference at the uppermost portion of the opening portion 290 may be regarded as the channel width.

Although a side surface of the conductor 240 in the opening portion 290 is aligned with the side surface of the insulator 280 in the opening portion 290 in FIG. 7A and FIG. 7B, the present invention is not limited thereto. For example, the side surface of the conductor 240 in the opening portion 290 and the side surface of the insulator 280 in the opening portion 290 may be discontinuous. The inclination of the side surface of the conductor 240 in the opening portion 290 and the inclination of the side surface of the insulator 280 in the opening portion 290 may be different from each other. For example, the angle formed by the side surface of the conductor 240 in the opening portion 290 and the top surface of the conductor 120 is preferably smaller than the angle θ1. With such a structure, the coverage of the side surface of the conductor 240 with the oxide semiconductor 230 in the opening portion 290 is improved, so that defects such as voids can be reduced.

As illustrated in FIG. 7A and FIG. 7B, the bottom portion of the conductor 260 positioned in the opening portion 290 includes a flat region. Note that the bottom portion of the conductor 260 positioned in the opening portion 290 does not include a flat region in some cases depending on the maximum width of the opening portion 290 (the diameter in the case where the opening portion 290 is circular in the plan view), the thickness of the insulator 280 (corresponding to the depth of the opening portion 290), the thickness of the oxide semiconductor 230, the thickness of the insulator 250, and the like. For example, as illustrated in FIG. 7C and FIG. 7D, the bottom portion of the conductor 260 positioned in the opening portion 290 may have a needle-like shape. Note that FIG. 2A can be referred to for the plan view of the memory devices illustrated in FIG. 7C and FIG. 7D.

The needle-like shape here refers to a shape that becomes thinner toward the tip (toward the bottom portion of the conductor 260 positioned in the opening portion 290). Note that the needle-like tip may have an acute angle or a curved shape that is convex downward. Note that a needle-like shape whose tip has an acute angle may be referred to as a V shape.

A region of the conductor 260 in the opening portion 290 that faces the oxide semiconductor 230 with the insulator 250 therebetween functions as a gate electrode. Thus, the conductor 260 that fills the opening portion 290 and has a needle-like bottom portion may be referred to as a needle-like gate. Even when the bottom portion of the conductor 260 includes a flat region as illustrated in FIG. 7A and FIG. 7B, the conductor 260 may be referred to as a needle-like gate.

Although the opening portion 190 is provided so that the sidewall of the opening portion 190 is perpendicular to the top surface of the conductor 110 in FIG. 2B and FIG. 2D, the present invention is not limited thereto. For example, like the opening portion 290, the sidewall of the opening portion 190 may have a tapered shape or an inverse tapered shape.

When the sidewall of the opening portion 190 has a tapered shape, the coverage with the conductor 115, the insulator 130, or the like can be improved, so that defects such as voids can be reduced. For example, the angle formed by a side surface of the insulator 180 in the opening portion 190 and the top surface of the conductor 110 (an angle θ2 illustrated in FIG. 7A) is preferably greater than or equal to 45° and less than 90°. Alternatively, the angle is preferably greater than or equal to 45° and less than or equal to 75°. Alternatively, the angle is preferably greater than or equal to 45° and less than or equal to 65°.

As illustrated in FIG. 7A and FIG. 7B, the bottom portion of the conductor 120 positioned in the opening portion 190 includes a flat region. Note that the bottom portion of the conductor 120 positioned in the opening portion 190 does not include a flat region in some cases depending on the maximum width of the opening portion 190 (the diameter in the case where the opening portion 190 is circular in the plan view), the thickness of the insulator 180 (corresponding to the depth of the opening portion 190), the thickness of the conductor 115, the thickness of the insulator 130, and the like. For example, as illustrated in FIG. 7C and FIG. 7D, the bottom portion of the conductor 120 positioned in the opening portion 190 may have a needle-like shape. Note that FIG. 2A can be referred to for the plan view of the memory devices illustrated in FIG. 7C and FIG. 7D.

In the case where the insulator 180 and the insulator 280 are formed using the same material, the angle θ1 and the angle θ2 are the same or substantially the same. Note that the angle θ1 and the angle θ2 may be different from each other depending on the material used for each of the insulator 180 and the insulator 280, the method for forming each of the opening portion 190 and the opening portion 290, or the like. For example, the angle θ1 may be larger than the angle θ2 or may be smaller than the angle θ2. One of the angle θ1 and the angle θ2 may be 90° or a value in the neighborhood thereof.

The sidewall of the opening portion 290 may have an inverse tapered shape, for example.

The inverse tapered shape here refers to a shape in which a side portion or an upper portion extends beyond a bottom portion in the direction parallel to a substrate. In this case, the opening portion 290 has a conical frustum shape. In this case, the opening portion 290 is circular in the plan view and the opening portion 290 is trapezoidal in the cross-sectional view. The area of the upper base of the conical frustum shape (e.g., the opening portion formed in the conductor 240) is larger than the area of the lower base of the conical frustum shape (the top surface of the conductor 120 exposed in the opening portion 290). Such a structure can increase the area where the oxide semiconductor 230 and the conductor 120 are in contact with each other.

Here, FIG. 7B and FIG. 7D illustrate an example in which the connection portion 101 included in the functional element 155 does not include the insulator 131. In the case where the sidewall of the opening portion 190 has a tapered shape as illustrated in the drawings, the insulator 131 does not remain in many cases even when anisotropic etching is performed as an etching method of the insulator 130. The insulator 131 is preferably not included, in which case the area where the conductor 120 and the conductor 115 are in contact with each other is increased and the electric resistance can be reduced. Note that the sidewall of the opening portion 190 may have a tapered shape and the insulator 131 may be provided.

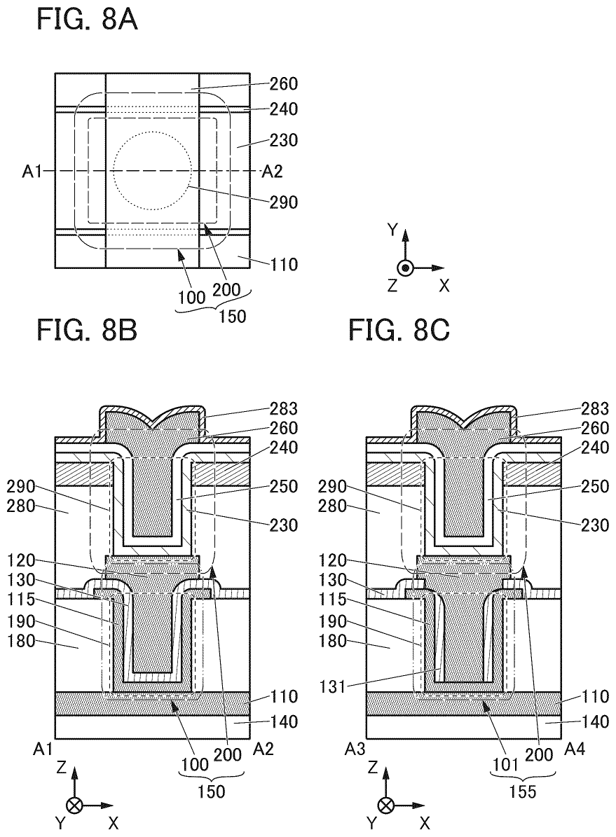

As illustrated in FIG. 2B and FIG. 2D, part of the oxide semiconductor 230 is positioned outside the opening portion 290, that is, over the conductor 240. Note that although the oxide semiconductor 230 is divided in the X direction in FIG. 2B, the present invention is not limited thereto. For example, as illustrated in FIG. 8A and FIG. 8B, the oxide semiconductor 230 may be provided to extend in the X direction. Note that also in the structures illustrated in FIG. 8A and FIG. 8B, the oxide semiconductor 230 is divided in the Y direction.

The metal oxide functioning as the oxide semiconductor 230 preferably has a band gap higher than or equal to 2 eV, further preferably higher than or equal to 2.5 eV. By using a metal oxide having a wide band gap as the oxide semiconductor 230, the off-state current of the transistor can be reduced. By using a transistor with a low off-state current in a memory cell, stored content can be retained for a long time. In other words, such a memory device does not require refresh operation or has extremely low frequency of the refresh operation, which leads to a sufficient reduction in power consumption of the memory device. The frequency of refresh operation in a general DRAM is approximately once per 60 msec, whereas the frequency of refresh operation in the memory device of one embodiment of the present invention can be approximately once per 10 sec, which is greater than or equal to 10 times or greater than or equal to 100 times that of the general DRAM. In the memory device of one embodiment of the present invention, the frequency of refresh operation can be once per period of more than or equal to 1 sec and less than or equal to 100 sec, preferably once per period of more than or equal to 5 sec and less than or equal to 50 sec.

As the oxide semiconductor 230, a single layer or stacked layers of any of the metal oxides described in the section [Metal oxide] below can be used.

As the oxide semiconductor 230, a metal oxide with a composition of In:M:Zn=1:3:2 [atomic ratio] or in the neighborhood thereof, a metal oxide with a composition of In:M:Zn=1:3:4 [atomic ratio] or in the neighborhood thereof, a metal oxide with a composition of In:M:Zn=1:1:0.5 [atomic ratio] or in the neighborhood thereof, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a metal oxide with a composition of In:M:Zn=1:1:2 [atomic ratio] or in the neighborhood thereof, or a metal oxide with a composition of In:M:Zn=4:2:3 [atomic ratio] or in the neighborhood thereof may be specifically used. Note that a composition in the neighborhood includes the range of ±30% of an intended atomic ratio. Gallium is preferably used as the element M.

When the metal oxide is deposited by a sputtering method, the above atomic ratio is not limited to the atomic ratio of the deposited metal oxide and may be the atomic ratio of a sputtering target used for depositing the metal oxide.

Analysis of the composition of the metal oxide used as the oxide semiconductor 230 can be performed by energy dispersive X-ray spectrometry (EDX), X-ray photoelectron spectrometry (XPS), inductively coupled plasma-mass spectrometry (ICP-MS), or inductively coupled plasma-atomic emission spectrometry (ICP-AES), for example. Alternatively, these methods may be combined for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an atomic layer deposition (ALD) method can be suitably used for forming a film of the metal oxide. Note that in the case where the metal oxide is formed by a sputtering method, the composition of the formed metal oxide may be different from the composition of a sputtering target. In particular, the content percentage of the zinc in the formed metal oxide may be reduced to approximately 50% of that of the sputtering target.

The oxide semiconductor 230 preferably has crystallinity. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. As the oxide semiconductor 230, the CAAC-OS or the nc-OS is preferably used, and the CAAC-OS is particularly preferably used.

CAAC-OS preferably includes a plurality of layered crystal regions and a c-axis is preferably aligned in a normal direction of a surface where the CAAC-OS is deposited. For example, the oxide semiconductor 230 preferably includes layered crystals substantially parallel to the sidewall of the opening portion 290, particularly the side surface of the insulator 280. With this structure, the layered crystals of the oxide semiconductor 230 are formed substantially parallel to the channel length direction of the transistor 200, so that the on-state current of the transistor can be increased.

The CAAC-OS is a metal oxide having a dense structure with high crystallinity and a small amount of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide semiconductor having crystallinity, such as CAAC-OS, is used as the oxide semiconductor 230, oxygen extraction from the oxide semiconductor 230 by the source electrode or the drain electrode can be inhibited. This can inhibit oxygen extraction from the oxide semiconductor 230 even when heat treatment is performed; thus, the transistor 200 is stable with respect to high temperatures in a manufacturing process (what is called thermal budget).

The crystallinity of the oxide semiconductor 230 can be analyzed with X-ray diffraction (XRD), a transmission electron microscope (TEM), or electron diffraction, for example. Alternatively, these methods may be combined for the analysis.

Note that although the oxide semiconductor 230 has a single layer in FIG. 2B and FIG. 2D, the present invention is not limited thereto. The oxide semiconductor 230 may have a stacked-layer structure of a plurality of oxide layers with different chemical compositions. For example, a structure in which a plurality of kinds of metal oxides selected from the above-described metal oxides are stacked as appropriate may be used.

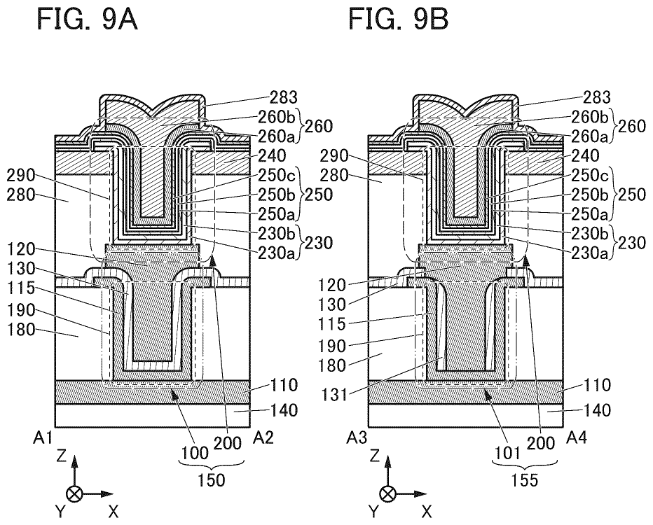

For example, as illustrated in FIG. 9A and FIG. 9B, the oxide semiconductor 230 may have a stacked-layer structure of an oxide semiconductor 230a and an oxide semiconductor 230b over the oxide semiconductor 230a.

The conductivity of a material used for the oxide semiconductor 230a is preferably different from the conductivity of a material used for the oxide semiconductor 230b.

For example, a material having higher conductivity than the oxide semiconductor 230b can be used for the oxide semiconductor 230a. The use of the material having high conductivity for the oxide semiconductor 230a, which is in contact with the conductor 120 and the conductor 240 functioning as the source electrode and the drain electrode, can reduce the contact resistance between the oxide semiconductor 230 and the conductor 120 and the contact resistance between the oxide semiconductor 230 and the conductor 240, so that the transistor can have high on-state current.

Here, in the case where a material having high conductivity is used for the oxide semiconductor 230b provided on the side of the conductor 260 functioning as the gate electrode, the threshold voltage of the transistor is shifted and drain current flowing when the gate voltage is 0 V (hereinafter also referred to as cutoff current) becomes large in some cases. Specifically, the threshold voltage might be low when the transistor 200 is an n-channel transistor. Thus, a material having lower conductivity than the oxide semiconductor 230a is preferably used for the oxide semiconductor 230b. Accordingly, in the case where the transistor 200 is an n-channel transistor, the transistor can have a high threshold voltage and a low cut-off current. Note that characteristics with a low cut-off current are sometimes referred to as normally-off characteristics.

When the oxide semiconductor 230 has a stacked-layer structure and a material having higher conductivity than the oxide semiconductor 230b is used for the oxide semiconductor 230a as described above, the transistor can have normally-off characteristics and a high on-state current. Consequently, the memory device can have both low power consumption and high performance.

Note that the carrier concentration of the oxide semiconductor 230a is preferably higher than the carrier concentration of the oxide semiconductor 230b. When the carrier concentration of the oxide semiconductor 230a is increased the conductivity is increased and the contact resistance between the oxide semiconductor 230 and the conductor 120 and the contact resistance between the oxide semiconductor 230 and the conductor 240 can be reduced, so that the transistor can have a high on-state current. When the carrier concentration of the oxide semiconductor 230b is reduced, the conductivity is reduced, so that the transistor can have normally-off characteristics.

Although an example in which a material having higher conductivity than the oxide semiconductor 230b is used for the oxide semiconductor 230a is described here, one embodiment of the present invention is not limited thereto. A material having lower conductivity than the material for the oxide semiconductor 230b may be used for the oxide semiconductor 230a. The carrier concentration of the oxide semiconductor 230a can be lower than the carrier concentration of the oxide semiconductor 230b.

A first metal oxide used for the oxide semiconductor 230a and a second metal oxide used for the oxide semiconductor 230b preferably have different band gaps. For example, a difference between the band gap of the first metal oxide and the band gap of the second metal oxide is preferably greater than or equal to 0.1 eV, further preferably greater than or equal to 0.2 eV, still further preferably greater than or equal to 0.3 eV.

The band gap of the first metal oxide used for the oxide semiconductor 230a can be smaller than that of the second metal oxide used for the oxide semiconductor 230b. Thus, the contact resistance between the oxide semiconductor 230 and the conductor 120 and the contact resistance between the oxide semiconductor 230 and the conductor 240 can be reduced, so that the transistor can have a high on-state current. In the case where the transistor 200 is an n-channel transistor, the transistor can have a high threshold voltage and normally-off characteristics.

Although an example in which the band gap of the first metal oxide is smaller than that of the second metal oxide is described here, one embodiment of the present invention is not limited thereto. The band gap of the first metal oxide can be larger than that of the second metal oxide.

As described above, the band gap of the first metal oxide used for the oxide semiconductor 230a can be smaller than the band gap of the second metal oxide used for the oxide semiconductor 230b. The composition of the first metal oxide is preferably different from that of the second metal oxide. When the compositions of the first metal oxide and the second metal oxide are different from each other, the band gap can be controlled. For example, the content percentage of the element M in the first metal oxide is preferably lower than that of the element M in the second metal oxide. Specifically, in the case where the first metal oxide and the second metal oxide are each an In-M-Zn oxide, the first metal oxide can have an atomic ratio of In:M:Zn=1:1:1 or a composition in the neighborhood thereof, and the second metal oxide can have an atomic ratio of In:M:Zn=1:3:2 or a composition in the neighborhood thereof. It is particularly preferable to use one or more of gallium, aluminum, and tin as the element M.

The first metal oxide may have a composition not including the element M. For example, the first metal oxide used for the oxide semiconductor 230a can be an In—Zn oxide, and the second metal oxide used for the oxide semiconductor 230b can be an In-M-Zn oxide. Specifically, the first metal oxide can be an In—Zn oxide, and the second metal oxide can be an In—Ga—Zn oxide. More specifically, the first metal oxide can have an atomic ratio of In:Zn=1:1 or a composition in the neighborhood thereof or an atomic ratio of In:Zn=4:1 or a composition in the neighborhood thereof, and the second metal oxide can have an atomic ratio of In:Ga:Zn=1:1:1 or a composition in the neighborhood thereof.

Although an example in which the content percentage of the element M in the first metal oxide is lower than that of the element M in the second metal oxide is described here, one embodiment of the present invention is not limited thereto. The content percentage of the element M in the first metal oxide may be higher than that of the element M in the second metal oxide. Note that as long as the compositions of the first metal oxide and the second metal oxide are different from each other, the content percentages of elements other than the element M may be different from each other.

The thickness of the oxide semiconductor 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

The thicknesses of the layers included in the oxide semiconductor 230 (here, the oxide semiconductor 230a and the oxide semiconductor 230b) are determined so that the thickness of the oxide semiconductor 230 falls within the above-described range. The thickness of the oxide semiconductor 230a can be determined so that the contact resistance between the oxide semiconductor 230a and the conductor 120 and the contact resistance between the oxide semiconductor 230a and the conductor 240 fall within the required range. The thickness of the oxide semiconductor 230b can be determined so that the threshold voltage of the transistor falls within the required range. Note that the thickness of the oxide semiconductor 230a may be the same as or different from the thickness of the oxide semiconductor 230b.

Although the oxide semiconductor 230 has the two-layer structure of the oxide semiconductor 230a and the oxide semiconductor 230b in FIG. 9A and FIG. 9B, the present invention is not limited thereto. The oxide semiconductor 230 may have a stacked-layer structure of three or more layers.

In the case where the oxide semiconductor 230 has a three-layer structure, the oxide semiconductor 230 may have a structure in which a metal oxide with a composition of In Ga:Zn=1:1:1 [atomic ratio] or in the neighborhood thereof, a metal oxide with a composition of In:Zn=1:1 [atomic ratio] or in the neighborhood thereof or with a composition of In:Zn=4:1 [atomic ratio] or in the neighborhood thereof, and a metal oxide with a composition of In:Ga:Zn=1:1:1 [atomic ratio] or in the neighborhood thereof are provided in order from the conductor 120 side. With such a structure, the on-state current of the transistor 200 can be increased, and the transistor can have high reliability with small variations.

As the insulator 250, a single layer or stacked layers of any of the insulators described in the section [Insulator] below can be used. For example, silicon oxide or silicon oxynitride can be used as the insulator 250. Silicon oxide and silicon oxynitride are preferable because they are thermally stable.

For the insulator 250, any of materials with high relative permittivity, that is, high-k materials, described in the section [Insulator] below may be used. For example, hafnium oxide, aluminum oxide, or the like may be used.

The thickness of the insulator 250 is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of the insulator 250 preferably includes a region with the above-described thickness.

The concentration of impurities such as water and hydrogen in the insulator 250 is preferably reduced. In that case, entry of impurities such as water and hydrogen into the channel formation region of the oxide semiconductor 230 can be inhibited.

As illustrated in FIG. 2B and FIG. 2D, part of the insulator 250 is positioned outside the opening portion 290, that is, over the conductor 240 and the insulator 280. In this case, the insulator 250 preferably covers the side end portion of the oxide semiconductor 230. This can prevent a short circuit between the conductor 260 and the oxide semiconductor 230. The insulator 250 preferably covers the side end portion of the conductor 240. This can prevent a short circuit between the conductor 260 and the conductor 240.

Note that although the insulator 250 has a single layer in FIG. 2B and FIG. 2D, the present invention is not limited thereto. The insulator 250 may have a stacked-layer structure.

For example, as illustrated in FIG. 9A and FIG. 9B, the insulator 250 may have a stacked-layer structure of an insulator 250a, an insulator 250b over the insulator 250a, and an insulator 250c over the insulator 250b.

For the insulator 250b, any of the above-described materials with low relative permittivity is preferably used. In particular, silicon oxide and silicon oxynitride are preferable because they are thermally stable. In that case, parasitic capacitance between the conductor 260 and the conductor 240 can be reduced. Furthermore, the concentration of impurities such as water and hydrogen in the insulator 250b is preferably reduced.

As the insulator 250a, any of the above-described insulators having a barrier property against oxygen is preferably used. When the insulator 250a, which is in contact with the oxide semiconductor 230, has a barrier property against oxygen, release of oxygen from the oxide semiconductor 230 caused by heat treatment or the like can be inhibited, so that formation of oxygen vacancies in the oxide semiconductor 230 can be inhibited. Accordingly, the electrical characteristics and reliability of the transistor 200 can be improved. As the insulator 250a, aluminum oxide is preferably used, for example. In this case, the insulator 250a contains at least oxygen and aluminum.

As the insulator 250c, any of the above-described insulators having a barrier property against hydrogen is preferably used. In that case, diffusion of impurities contained in the conductor 260 into the oxide semiconductor 230 can be inhibited. In particular, silicon nitride is suitably used as the insulator 250c because of its high hydrogen barrier property.

The insulator 250c may further have a barrier property against oxygen. The insulator 250c is provided between the insulator 250b and the conductor 260. Thus, diffusion of oxygen contained in the insulator 250b into the conductor 260 can be prevented, so that oxidation of the conductor 260 can be inhibited. In addition, a reduction in the amount of oxygen supplied to the region 230i can be inhibited.

An insulator may be provided between the insulator 250b and the insulator 250c. As the insulator, any of the above-described insulators having a function of capturing or fixing hydrogen is preferably used. In that case, hydrogen contained in the oxide semiconductor 230 is captured or fixed, so that the concentration of hydrogen in the oxide semiconductor 230 can be reduced.

To miniaturize the transistor 200, the thicknesses of the insulator 250a to the insulator 250c are preferably small and preferably fall within the above-described range. Typically, the thicknesses of the insulator 250a, the insulator 250b, the insulator having a function of capturing or fixing hydrogen, and the insulator 250c are 1 nm, 2 nm, 2 nm, and 1 nm, respectively. Such a structure enables the transistor 200 to have favorable electrical characteristics even when the transistor is miniaturized or highly integrated.

Although the insulator 250 has the three-layer structure of the insulator 250a to the insulator 250c in FIG. 9A and FIG. 9B, the present invention is not limited thereto. The insulator 250 may have a stacked-layer structure of two layers or four or more layers. In that case, the layers included in the insulator 250 are preferably selected as appropriate from the insulator 250a to the insulator 250c and the insulator having a function of capturing or fixing hydrogen.

As the conductor 260, a single layer or stacked layers of any of the conductors described in the section [Conductor] below can be used. For example, a conductive material with high conductivity such as tungsten can be used for the conductor 260.

In addition, a conductive material that is less likely to be oxidized, a conductive material that is less likely to allow diffusion of oxygen, or the like is preferably used for the conductor 260. Examples of the conductive material include a conductive material containing nitrogen (e.g., titanium nitride or tantalum nitride) and a conductive material containing oxygen (e.g., ruthenium oxide). In that case, a decrease in the conductivity of the conductor 260 can be inhibited.

Note that although the conductor 260 has a single layer in FIG. 2B and FIG. 2D, the present invention is not limited thereto. Note that the conductor 260 may have a stacked-layer structure. For example, as illustrated in FIG. 9A and FIG. 9B, the conductor 260 may have a stacked-layer structure of a conductor 260a and a conductor 260b over the conductor 260a. In that case, titanium nitride may be used as the conductor 260a and tungsten may be used as the conductor 260b, for example. When tungsten is stacked in this manner, the conductivity of the conductor 260 can be improved and can serve well as the wiring WL.

Although the conductor 260 has the two-layer structure of the conductor 260a and the conductor 260b in FIG. 9A and FIG. 9B, the present invention is not limited thereto. The conductor 260 may have a stacked-layer structure of three or more layers.

Although the conductor 260 is provided to fill the opening portion 290 in FIG. 2B and FIG. 2D, the present invention is not limited thereto. For example, a depressed portion reflecting the shape of the opening portion 290 is formed in a center portion of the conductor 260 and part of the depressed portion is positioned in the opening portion 290 in some cases. In that case, the depressed portion may be filled with an inorganic insulating material or the like.

As illustrated in FIG. 2B and FIG. 2D, part of the conductor 260 is positioned outside the opening portion 290, that is, over the conductor 240 and the insulator 280. In this case, as illustrated in FIG. 2B, a side end portion of the conductor 260 is preferably positioned inward from a side end portion of the oxide semiconductor 230. In that case, a short circuit between the conductor 260 and the oxide semiconductor 230 can be prevented. Note that the side end portion of the conductor 260 may be aligned with the side end portion of the oxide semiconductor 230 or may be positioned outward from the side end portion of the oxide semiconductor 230.

Although the top surface of the conductor 120 is flat in FIG. 2B and FIG. 2D, the present invention is not limited thereto. For example, the top surface of the conductor 120 may have a depressed portion overlapping with the opening portion 290. When at least parts of the oxide semiconductor 230, the insulator 250, and the conductor 260 are formed to fill the depressed portion, a gate electric field of the conductor 260 can be easily applied to a portion of the oxide semiconductor 230 near the conductor 120.

As the conductor 240, a single layer or stacked layers of any of the conductors described in the section [Conductor] below can be used. For example, a conductive material with high conductivity such as tungsten can be used for the conductor 240.

Like the conductor 260, the conductor 240 is preferably formed using a conductive material that is less likely to be oxidized, a conductive material that is less likely to allow diffusion of oxygen, or the like. For example, titanium nitride, tantalum nitride, or the like can be used. Such a structure can inhibit excessive oxidation of the conductor 240 due to the oxide semiconductor 230. Alternatively, a structure in which tungsten is stacked over titanium nitride may be used, for example. When tungsten is stacked in this manner, the conductivity of the conductor 240 can be improved and can serve well as the wiring BL.

In the case where the conductor 240 has a structure where a first conductor and a second conductor are stacked, the first conductor may be formed using a conductive material with high conductivity and the second conductor may be formed using a conductive material containing oxygen, for example. By using the conductive material containing oxygen as the second conductor of the conductor 240 that is in contact with the insulator 250, oxygen in the insulator 250 can be inhibited from diffusing into the first conductor of the conductor 240. For example, tungsten can be used as the first conductor of the conductor 240, and an oxide conductor can be used as the second conductor of the conductor 240. As the oxide conductor, a single layer or stacked layers of ITO, ITSO, IZO (registered trademark), or the like can be used.

When the oxide semiconductor 230 and the conductor 120 are in contact with each other, a metal compound or oxygen vacancies are formed, so that the resistance of the region 230na in the oxide semiconductor 230 is reduced. The reduction in the resistance of the oxide semiconductor 230 in contact with the conductor 120 can reduce the contact resistance between the oxide semiconductor 230 and the conductor 120. Similarly, when the oxide semiconductor 230 and the conductor 240 are in contact with each other, the resistance of the region 230nb in the oxide semiconductor 230 is reduced. Accordingly, the contact resistance between the oxide semiconductor 230 and the conductor 240 can be reduced.

The insulator 140 and the insulator 280 function as interlayer films and thus preferably have low relative permittivity. When a material with low relative permittivity is used for an interlayer film, parasitic capacitance generated between wirings can be reduced. As the insulator 140 and the insulator 280, a single layer or stacked layers of an insulator containing any of the above-described materials with low relative permittivity can be used. Silicon oxide and silicon oxynitride are preferable because they are thermally stable.

The concentration of impurities such as water and hydrogen in the insulator 140 and the insulator 280 is preferably reduced. In that case, entry of impurities such as water and hydrogen into the channel formation region of the oxide semiconductor 230 can be inhibited.

As the insulator 280 placed in the vicinity of the channel formation region, an insulator containing oxygen that is released by heating (hereinafter, sometimes referred to as excess oxygen) is preferably used. By performing heat treatment on the insulator 280 containing excess oxygen, oxygen can be supplied from the insulator 280 to the channel formation region of the oxide semiconductor 230 and oxygen vacancies and V_{O}H can be reduced. Thus, the transistor 200 can have stable electrical characteristics and improved reliability.

As the insulator 280, any of the above-described insulators having a function of capturing or fixing hydrogen may be used. With such a structure, hydrogen in the oxide semiconductor 230 can be captured or fixed, so that the concentration of hydrogen in the oxide semiconductor 230 can be reduced. For the insulator 280, magnesium oxide, aluminum oxide, or the like can be used.

Note that although the insulator 280 has a single layer in FIG. 2B and FIG. 2D, the present invention is not limited thereto. The insulator 280 may have a stacked-layer structure.

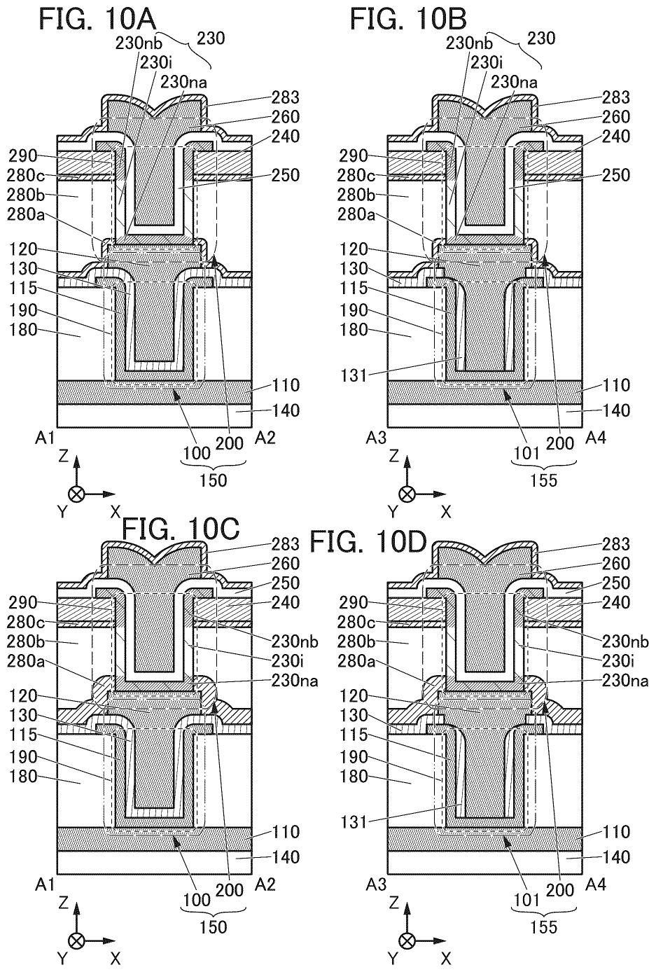

For example, as illustrated in FIG. 10A and FIG. 10B, the insulator 280 may have a stacked-layer structure of an insulator 280a, an insulator 280b over the insulator 280a, and an insulator 280c over the insulator 280b.

An insulator containing oxygen is preferably used as the insulator 280b. The insulator 280b preferably includes a region having a higher oxygen content than at least one of the insulator 280a and the insulator 280c. In particular, the insulator 280b preferably includes a region having a higher oxygen content than the insulator 280a and the insulator 280c. When the insulator 280b has a high oxygen content, an i-type region can be easily formed in a region of the oxide semiconductor 230 that is in contact with the insulator 280b and in the vicinity of the region.

It is further preferable that a film from which oxygen is released by heating be used as the insulator 280b. When the insulator 280b releases oxygen by being heated during the manufacturing process of the transistor 200, the oxygen can be supplied to the oxide semiconductor 230. The oxygen supply from the insulator 280b to the oxide semiconductor 230, particularly to the channel formation region of the oxide semiconductor 230, can reduce the amount of oxygen vacancies and V_{O}H in the oxide semiconductor 230, so that the transistor can have favorable electrical characteristics and high reliability.

For example, the insulator 280b can be supplied with oxygen when heat treatment or plasma treatment is performed in an oxygen-containing atmosphere. Alternatively, an oxide film may be formed over the top surface of the insulator 280b by a sputtering method in an oxygen atmosphere to supply oxygen. After that, the oxide film may be removed.

The insulator 280b is preferably formed by a deposition method such as a sputtering method or a plasma-enhanced chemical vapor deposition (PECVD) method. In particular, by a sputtering method using a deposition gas not containing a hydrogen gas, a film having an extremely low hydrogen content can be formed. Therefore, supply of hydrogen to the oxide semiconductor 230 is inhibited and electrical characteristics of the transistor 200 can be stabilized.

In the case where the channel length of the transistor 200 is short, the influence of oxygen vacancies and V_{O}H in the channel formation region on the electrical characteristics and reliability is particularly large. Supplying oxygen from the insulator 280b to the oxide semiconductor 230 can inhibit an increase in oxygen vacancies and V_{O}H at least in the region of the oxide semiconductor 230 that is in contact with the insulator 280b. Thus, the transistor with a short channel length can have favorable electrical characteristics and high reliability.

As each of the insulator 280a and the insulator 280c, any of the insulators having a barrier property against oxygen described in the section [Insulator] below is preferably used. In that case, oxygen contained in the insulator 280b can be inhibited from diffusing to the substrate side through the insulator 280a and to the insulator 250 side through the insulator 280c due to heating. In other words, when the insulator 280c and the insulator 280a that do not easily allow diffusion of oxygen are respectively provided above and below the insulator 280b, oxygen contained in the insulator 280b can be enclosed. Thus, oxygen can be effectively supplied to the oxide semiconductor 230.

The conductor 120 and the conductor 240 are oxidized by oxygen contained in the insulator 280b and have high resistance in some cases. Providing the insulator 280a between the insulator 280b and the conductor 120 can inhibit the conductor 120 from being oxidized and having high resistance. Furthermore, providing the insulator 280c between the insulator 280b and the conductor 240 can inhibit the conductor 240 from being oxidized and having high resistance. In addition, the amount of oxygen supplied from the insulator 280b to the oxide semiconductor 230 is increased, so that oxygen vacancies in the oxide semiconductor 230 can be reduced.

A region of the oxide semiconductor 230 that is in contact with the insulator 280a and a region of the oxide semiconductor 230 that is in contact with the insulator 280c are supplied with a smaller amount of oxygen than a region of the oxide semiconductor 23 that is in contact with the insulator 280b. Thus, the region of the oxide semiconductor 230 that is in contact with the insulator 280a and the region of the oxide semiconductor 230 that is in contact with the insulator 280c each have a low resistance in some cases. That is, by adjusting the thickness of the insulator 280a, the range of the region 230na functioning as one of the source region and the drain region can be controlled. Similarly, by adjusting the thickness of the insulator 280c, the range of the region 230nb functioning as the other of the source region and the drain region can be controlled.

As described above, the source region and the drain region can be controlled by the thicknesses of the insulator 280a and the insulator 280c; thus, the thicknesses of the insulator 280a and the insulator 280c may be set as appropriate in accordance with the characteristics required for the transistor 200.

For example, as illustrated in FIG. 10A and FIG. 10B, the thickness of the insulator 280c and the thickness of the insulator 280a may be substantially the same. Alternatively, as illustrated in FIG. 10C and FIG. 10D, the thickness of the insulator 280c may be smaller than that of the insulator 280a, for example. With the structures illustrated in FIG. 10C and FIG. 10D, the region 230na can be close to the bottom portion of the conductor 260 in the opening portion 290. In this case, the range of the region 230i can be regarded as being narrowed. This can increase the on-state current of the transistor 200.

Although the insulator 280c is provided over the planarized insulator 280b in FIG. 10C and FIG. 10D, the present invention is not limited thereto. For example, the insulator 280c may be formed without performing planarization treatment on the insulator 280b. By not performing planarization treatment, the manufacturing cost can be reduced and the production yield can be increased. Furthermore, the insulator 280a, the insulator 280b, and the insulator 280c can be successively formed without being exposed to the air. The formation without exposure to the air can prevent attachment of impurities or moisture from the atmospheric environment onto the insulator 280a to the insulator 280c, so that the vicinity of the interface between the insulator 280a and the insulator 280b and the vicinity of the interface between the insulator 280b and the insulator 280c can be kept clean.

As each of the insulator 280a and the insulator 280c, any of the above-described insulators having a barrier property against hydrogen is preferably used. In that case, diffusion of hydrogen from the outside of the transistor into the oxide semiconductor 230 through the insulator 280a or the insulator 280c can be inhibited. A silicon nitride film and a silicon nitride oxide film can be suitably used as the insulator 280a and the insulator 280c because they release few impurities (e.g., water and hydrogen) and are less likely to transmit oxygen and hydrogen. For the insulator 280a and the insulator 280c, the same material or different materials may be used.

As the insulator 280a, any of the above-described insulators having a function of capturing or fixing hydrogen is preferably used. In that case, diffusion of hydrogen from below the insulator 280a into the oxide semiconductor 230 can be inhibited, and hydrogen in the oxide semiconductor 230 can be captured or fixed, so that the concentration of hydrogen in the oxide semiconductor 230 can be reduced. In addition, diffusion of hydrogen from above the insulator 280a into the insulator 130 can be inhibited, and hydrogen in the insulator 130 can be captured or fixed, so that the concentration of hydrogen in the insulator 130 can be reduced. For the insulator 280a, magnesium oxide, aluminum oxide, hafnium oxide, or the like can be used. Alternatively, for example, a stacked-layer film of aluminum oxide and silicon nitride over the aluminum oxide may be used as the insulator 280a.

The thickness of the insulator 280a is preferably smaller than the thickness of the insulator 280b. The thickness of the insulator 280c is preferably smaller than the thickness of the insulator 280b. The thicknesses of the insulator 280a and the insulator 280c are each preferably greater than or equal to 1 nm and less than or equal to 15 nm, further preferably greater than or equal to 2 nm and less than or equal to 10 nm, still further preferably greater than or equal to 3 nm and less than or equal to 7 nm, yet still further preferably greater than or equal to 3 nm and less than or equal to 5 nm. The thickness of the insulator 280b is preferably greater than or equal to 3 nm and less than or equal to 30 nm, further preferably greater than or equal to 5 nm and less than or equal to 20 nm, still further preferably greater than or equal to 7 nm and less than or equal to 15 nm. When the thicknesses of the insulator 280a to the insulator 280c fall within the above ranges, oxygen vacancies in the oxide semiconductor 230, particularly in the channel formation region, can be reduced.

For example, silicon nitride is preferably used for the insulator 280a and the insulator 280c, and silicon oxide is preferably used for the insulator 280b. In that case, the insulator 280a and the insulator 280c each contain at least silicon and nitrogen. The insulator 280b contains at least silicon and oxygen.

Note that although the insulator 280 has the three-layer structure in FIG. 10A and FIG. 10B, one embodiment of the present invention is not limited thereto. The insulator 280 may have a stacked-layer structure of two layers or four or more layers.

As the insulator 283, any of the above-described insulators having a barrier property against hydrogen is preferably used. In that case, diffusion of hydrogen from the outside of the transistor into the oxide semiconductor 230 through the insulator 250 can be inhibited.

As the insulator 283, any of the above-described insulators having a function of capturing or fixing hydrogen is preferably used. With such a structure, diffusion of hydrogen from above the insulator 283 into the oxide semiconductor 230 can be inhibited, and hydrogen in the oxide semiconductor 230 can be captured or fixed, so that the concentration of hydrogen in the oxide semiconductor 230 can be reduced.

A region where the top surface of the conductor 120 and the bottom surface of the oxide semiconductor 230 are in contact with each other is provided in FIG. 2B and FIG. 2D; however, the present invention is not limited thereto. For example, a conductor may be provided between the conductor 120 and the oxide semiconductor 230.

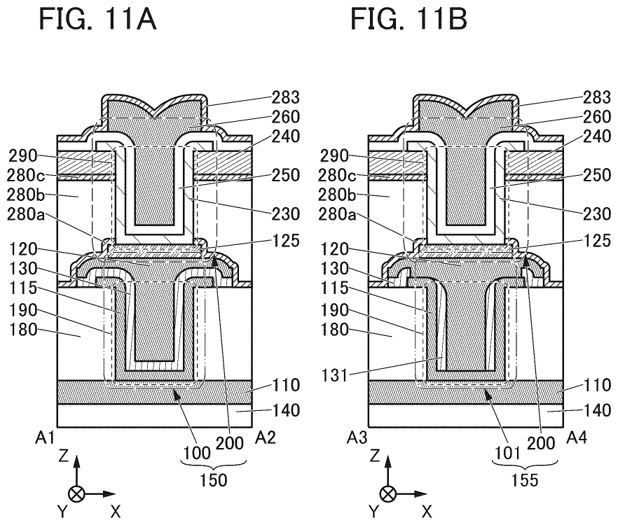

For example, as illustrated in FIG. 11A and FIG. 11B, a conductor 125 may be provided between the conductor 120 and the oxide semiconductor 230. For the conductor 125, any of the above-described conductive materials containing oxygen is preferably used. When the conductive material containing oxygen is used for the conductor 125, the conductor 125 can maintain its conductivity even when absorbing oxygen. Furthermore, oxygen in the oxide semiconductor 230 can be inhibited from diffusing into the conductor 120. As the conductor 125, a single layer or stacked layers of indium tin oxide, indium tin oxide to which silicon is added, indium zinc oxide, or the like can be used, for example.

The conductor 240 is provided over the insulator 280 in FIG. 2B and FIG. 2D. In addition, a region of the insulator 250 that does not overlap with the conductor 240 includes a region in contact with the top surface of the insulator 280. Note that the present invention is not limited thereto.

For example, the conductor 240 may be provided to be embedded in an insulator. In that case, the top surface of the conductor 240 is preferably level with or substantially level with the top surface of the insulator. With such a structure, the physical distance from the conductor 260 to the conductor 240 (particularly a side end portion of the conductor 240) can be increased, so that a short circuit between the conductor 260 and the conductor 240 can be prevented.

The insulator functions as an interlayer film and thus is preferably formed using a material with low relative permittivity. When a material with low relative permittivity is used for an interlayer film, parasitic capacitance generated between wirings can be reduced. As the insulator, a single layer or stacked layers of an insulator containing any of the above-described materials with low relative permittivity can be used.

### <Constituent Materials of Memory Device>

Constituent materials that can be used for the memory device will be described below.

### [Substrate]

As a substrate where the transistor 200 and the capacitor 100 are formed, an insulator substrate, a semiconductor substrate, or a conductor substrate may be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate in which an insulator region is included in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a memory element.

### [Insulator]

Examples of the insulator include an insulating oxide, an insulating nitride, an insulating oxynitride, an insulating nitride oxide, an insulating metal oxide, an insulating metal oxynitride, and an insulating metal nitride oxide.

With miniaturization and higher integration of transistors, for example, a problem such as leakage current may arise because of a thinner gate insulator. When a high-k material is used for the insulator functioning as a gate insulator, the voltage at the time of the operation of the transistor can be reduced while the physical thickness is maintained. In addition, the equivalent oxide thickness (EOT) of the insulator functioning as the gate insulator can be reduced. By contrast, when a material with low relative permittivity is used for the insulator functioning as an interlayer film, parasitic capacitance generated between wirings can be reduced. Thus, a material is preferably selected depending on the function of the insulator. Note that the material with low relative permittivity is a material with high dielectric strength.

Examples of a material with high relative permittivity (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of an inorganic insulating material with low relative permittivity include silicon oxide to which fluorine is added, silicon oxide to which carbon is added, and silicon oxide to which carbon and nitrogen are added. Another example is porous silicon oxide. Note that these silicon oxides may contain nitrogen.

When a transistor including a metal oxide is surrounded by an insulator having a function of inhibiting passage of impurities and oxygen, the transistor can have stable electrical characteristics. As the insulator having a function of inhibiting passage of impurities and oxygen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor or provided in the vicinity of the semiconductor layer, such as a gate insulator, preferably includes a region containing excess oxygen. For example, when an insulator including a region containing excess oxygen is in contact with a semiconductor layer or provided in the vicinity of the semiconductor layer, the number of oxygen vacancies in the semiconductor layer can be reduced. Examples of an insulator in which a region containing excess oxygen is easily formed include silicon oxide, silicon oxynitride, and porous silicon oxide.

Examples of an insulator having a barrier property against oxygen include an oxide containing one or both of aluminum and hafnium, an oxide containing hafnium and silicon (hafnium silicate), magnesium oxide, gallium oxide, gallium zinc oxide, silicon nitride, and silicon nitride oxide. Examples of an oxide containing one or both of aluminum and hafnium include aluminum oxide, hafnium oxide, and an oxide containing aluminum and hafnium (hafnium aluminate).

Examples of an insulator having a barrier property against hydrogen include aluminum oxide, magnesium oxide, hafnium oxide, gallium oxide, silicon nitride, and silicon nitride oxide.

An insulator having a barrier property against oxygen and an insulator having a barrier property against hydrogen can each be regarded as an insulator having a barrier property against one or both of oxygen and hydrogen.

Examples of an insulator having a function of capturing or fixing hydrogen include an oxide containing magnesium and an oxide containing one or both of aluminum and hafnium. These oxides preferably have an amorphous structure. In a metal oxide having an amorphous structure, an oxygen atom has a dangling bond and has a property of capturing or fixing hydrogen with the dangling bond in some cases. Note that although these metal oxides preferably have an amorphous structure, a crystal region may be partly formed.

Note that in this specification and the like, a barrier insulating film refers to an insulating film having a barrier property. A barrier property refers to a property of hardly diffusing a target substance (also referred to as a property of hardly transmitting a target substance, a low permeability of a target substance, or a function of inhibiting diffusion of a target substance). Note that a function of capturing or fixing (also referred to as gettering) a target substance can be rephrased as a barrier property. Note that hydrogen described as a target substance refers to, for example, at least one of a hydrogen atom, a hydrogen molecule, and substances bonded to hydrogen, such as a water molecule and OH⁻. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, and NO₂), and a copper atom. Oxygen described as a target substance refers to, for example, at least one of an oxygen atom, an oxygen molecule, and the like. Specifically, a barrier property against oxygen refers to a property of hardly diffusing at least one of an oxygen atom, an oxygen molecule, and the like.

### [Conductor]

It is preferable to use, as a conductor, a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements as is component; an alloy containing a combination of the above metal elements; or the like. As an alloy containing any of the above metal elements as its component, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Alternatively, a semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material that does not easily allow diffusion of oxygen, or a material maintaining its conductivity even after absorbing oxygen. Note that examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive film formed using the conductive material containing oxygen may be referred to as an oxide conductive film.

In addition, a conductive material containing tungsten, copper, or aluminum as its main component is preferable because it has high conductivity.

A plurality of conductors formed using any of the above materials may be stacked. For example, a stacked-layer structure combining a material containing any of the above metal elements and a conductive material containing oxygen may be employed. In addition, a stacked-layer structure combining a material containing any of the above metal elements and a conductive material containing nitrogen may be employed. Furthermore, a stacked-layer structure combining a material containing any of the above metal elements, a conductive material containing oxygen, and a conductive material containing nitrogen may be employed.

In the case where a metal oxide is used for the channel formation region of the transistor, the conductor functioning as the gate electrode preferably has a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing any of the above metal elements and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### [Metal Oxide]

A metal oxide has a lattice defect in some cases. Examples of a lattice defect include point defects such as an atomic vacancy and an exotic atom, a line defect such as dislocation, a plane defect such as a crystal grain boundary, and a volume defect such as a void. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects in a semiconductor layer of a transistor might lead to unstable electrical characteristics of the transistor. Hence, a metal oxide used in a semiconductor layer of a transistor preferably has a small number of lattice defects.

A transistor using a metal oxide is likely to change its electrical characteristics especially in the case where oxygen vacancies (V_{O}) and impurities exist in a channel formation region in the metal oxide, which might degrade the reliability. In some cases, hydrogen in the vicinity of an oxygen vacancy forms a defect that is an oxygen vacancy into which hydrogen enters (V_{O}H), which generates an electron serving as a carrier. Thus, when the channel formation region in the metal oxide includes oxygen vacancies, the transistor is likely to have normally-on characteristics. Therefore, oxygen vacancies and impurities are preferably reduced as much as possible in the channel formation region in the metal oxide. In other words, it is preferable that the channel formation region in the metal oxide have a reduced carrier concentration and be of an i-type (intrinsic) or substantially i-type.

The kind of a lattice defect that is likely to exist in a metal oxide and the number of lattice defects that exist vary depending on the structure of the metal oxide, a method for depositing the metal oxide, or the like.

The structure of a metal oxide is classified into a single crystal structure and other structures (non-single-crystal structures). Examples of a non-single-crystal structure include a CAAC structure, a polycrystalline structure, an nc structure, an amorphous-like (a-like) structure, and an amorphous structure. The a-like structure has a structure between the nc structure and the amorphous structure. Note that the classification of crystal structures will be described later.

A metal oxide having an a-like structure and a metal oxide having an amorphous structure each include a void or a low-density region. That is, a metal oxide having an a-like structure and a metal oxide having an amorphous structure have low crystallinity as compared with a metal oxide having an nc structure and a metal oxide having a CAAC structure. Moreover, a metal oxide having an a-like structure has higher hydrogen concentration in the metal oxide than a metal oxide having an nc structure and a metal oxide having a CAAC structure. Thus, a lattice defect is easily formed in a metal oxide having an a-like structure and a metal oxide having an amorphous structure.

Thus, a metal oxide with high crystallinity is preferably used in a semiconductor layer of a transistor. For example, a metal oxide having a CAAC structure or a metal oxide having a single crystal structure is preferably used. The use of the metal oxide for a transistor enables the transistor to have favorable electrical characteristics. In addition, a transistor with high reliability can be achieved.

For the channel formation region of a transistor, a metal oxide that increases the on-state current of the transistor is preferably used. To increase the on-state current of the transistor, the carrier mobility of the metal oxide used for the transistor is increased. To increase the carrier mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor, a CAAC-OS which is described later, and the like.

The c-axis of the above crystal is preferably aligned in the normal direction with respect to the formation surface or film surface of the metal oxide. This enables the plurality of layers to be placed parallel to or substantially parallel to the formation surface or film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal are a YbFe₂O₄ type structure, a Yb₂Fe₃O₇ type structure, their deformed structures, and the like.

Preferably, each of the first layer to the third layer is composed of one metal element or a plurality of metal elements with the same valence and oxygen. The valence of the one or plurality of metal elements included in the first layer is preferably equal to the valence of the one or plurality of metal elements included in the second layer. The first layer and the second layer may include the same metal element. The valence of the one or plurality of metal elements included in the first layer is preferably different from the valence of the one or plurality of metal elements included in the third layer.

The above structure can increase the crystallinity of the metal oxide, which leads to an increase in the carrier mobility of the metal oxide. Thus, the use of the metal oxide for the channel formation region of the transistor increases the on-state current of the transistor, leading to an improvement in the electrical characteristics of the transistor.

Examples of the metal oxide in one embodiment of the present invention include indium oxide, gallium oxide, and zinc oxide. The metal oxide in one embodiment of the present invention preferably contains at least indium (In) or zinc (Zn). The metal oxide preferably contains two or three kinds selected from indium, an element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. When the element M contained in the metal oxide is gallium, the metal oxide in one embodiment of the present invention preferably includes one or more selected from indium, gallium, and zinc. In this specification and the like, a metal element and a metalloid element may be collectively referred to as a “metal element”, and a “metal element” in this specification and the like may refer to a metalloid element.

As the metal oxide semiconductor in one embodiment of the present invention, for example, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (In—Sn—Zn oxide), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, or IAGZO) can be used. Alternatively, indium tin oxide containing silicon, gallium tin oxide (Ga—Sn oxide), aluminum tin oxide (Al—Sn oxide), or the like is given.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers in the periodic table. Alternatively, the metal oxide may contain, in addition to indium, one or more kinds of metal elements with large period numbers in the periodic table. The larger the overlap between orbits of metal elements is, the more likely it is that the metal oxide will have high carrier conductivity. Thus, a transistor containing a metal element with a larger period number in the periodic table can have high field-effect mobility in some cases. Examples of the metal element with a larger period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the proportion of the number of atoms of the element M in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

By increasing the proportion of the number of In atoms in the total number of atoms of all the metal elements contained in the metal oxide, a high on-state current and high frequency characteristics of the transistor can be achieved.

In the description of this embodiment, In—Ga—Zn oxide is sometimes taken as an example of the metal oxide.

For the formation of a metal oxide having the layered crystal structure, an atomic layer is preferably deposited one by one. Since an ALD method is employed as the deposition method of a metal oxide in one embodiment of the present invention, a metal oxide having the layered crystal structure is easily formed.

Examples of an ALD method include a thermal ALD method, in which a precursor and a reactant react with each other only by a thermal energy, and a plasma ALD (PEALD: Plasma Enhanced ALD) method, in which a reactant excited by plasma is used.

An ALD method, which enables atomic layers to be deposited one by one, has advantages such as deposition of an extremely thin film, deposition on a component with a high aspect ratio, deposition of a film with a small number of defects such as pinholes, deposition with excellent coverage, and low-temperature deposition. The use of plasma in a PEALD method is sometimes preferable because it enables deposition at a lower temperature. Note that a precursor used in an ALD method sometimes contains an element such as carbon or chlorine. Thus, in some cases, a film provided by an ALD method contains a larger amount of an element such as carbon or chlorine than a film provided by another deposition method. Note that element quantification can be performed by XPS or secondary ion mass spectrometry (SIMS). The formation method of a metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike a deposition method in which particles ejected from a target or the like are deposited, an ALD method is a deposition method in which a film is formed by reaction at a surface of an object to be processed. Thus, a CVD method and an ALD method are less likely to be influenced by the shape of an object to be processed and thus enable favorable step coverage. In particular, an ALD method allows excellent step coverage and excellent thickness uniformity and thus is suitably used to cover a surface of an opening portion with a high aspect ratio, for example. Note that an ALD method has a relatively low deposition rate and thus is sometimes preferably combined with another deposition method with a high deposition rate, such as a sputtering method or a CVD method. For example, a method in which a sputtering method is used to deposit a first metal oxide, and an ALD method is used to deposit a second metal oxide over the first metal oxide can be given. For example, in the case where the first metal oxide has a crystal part, crystal growth occurs in the second metal oxide with the use of the crystal part as a nucleus.

When an ALD method is employed, the composition of a film to be formed can be controlled with the amount of introduced source gases. For example, a film with a certain composition can be deposited by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film whose composition is continuously changed can be formed. In the case where a film is formed while the source gas is changed, as compared with the case where a film is formed using a plurality of deposition chambers, the time taken for the film formation can be shortened because the time taken for transfer and pressure adjustment is omitted. Thus, the productivity of the memory device can be increased in some cases.

### [[Transistor Including Metal Oxide]]

Next, the case where a metal oxide (oxide semiconductor) is used for a transistor will be described. Hereinafter, a transistor with a semiconductor layer of an oxide semiconductor is sometimes referred to as an OS transistor, and a transistor with a semiconductor layer of silicon is sometimes referred to as a Si transistor.

When the metal oxide (oxide semiconductor) of one embodiment of the present invention is used for a transistor, a transistor with high field-effect mobility can be achieved. In addition, a transistor with high reliability can be achieved. Furthermore, a miniaturized or highly integrated transistor can be achieved. For example, a transistor with a channel length of greater than or equal to 2 nm and less than or equal to 30 nm can be manufactured.

An oxide semiconductor having a low carrier concentration is preferably used for a channel formation region of a transistor. For example, the carrier concentration of an oxide semiconductor in the channel formation region is lower than or equal to 1×10¹⁸ cm⁻³, preferably lower than or equal to 1×10¹⁷ cm⁻³, further preferably lower than or equal to 1×10¹⁵ cm⁻³, still further preferably lower than or equal to 1×10¹³ cm⁻³, still further preferably lower than or equal to 1×10¹¹ cm⁻³, yet still further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, carbon, and nitrogen. Note that an impurity in an oxide semiconductor refers to, for example, an element other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can suppress the short-channel effect. In other words, the OS transistor is a transistor in which the short-channel effect does not appear or hardly appears.

Note that the short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes also referred to as S value), and an increase in leakage current. Here, the S value means the amount of change in gate voltage in the subthreshold region by which the drain current is changed by one order of magnitude at a constant drain voltage.

The characteristic length is widely used as an indicator of resistance to the short-channel effect. The characteristic length is an indicator of curving of potential in a channel formation region. When the characteristic length is shorter, the potential rises more sharply, which means that the resistance to the short-channel effect is high.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to the short-channel effect than the Si transistor. That is, in the case where a transistor with a short channel length is to be fabricated, the OS transistor is more suitable than the Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, a difference in energy of the conduction band minimum between the channel formation region and the source region or the drain region might decrease to higher than or equal to 0.1 eV and lower than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region become n⁺-type regions.

The above-described structure enables the OS transistor to have excellent electrical characteristics even when the OS transistors are miniaturized or highly integrated. For example, the semiconductor device can have favorable electrical characteristics even when the OS transistor has a channel length or a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Therefore, the OS transistor can be suitably used as a transistor having a short channel length as compared with the Si transistor. Note that the gate length refers to the length of a gate electrode in a direction in which carriers move inside a channel formation region during an operation of the transistor.

Miniaturization of the OS transistor can improve the high frequency characteristics of the transistor. Specifically, the cutoff frequency of the transistor can be improved. When the gate length of the OS transistor falls within any of the above ranges, the cutoff frequency of the transistor can be greater than or equal to 50 GHz, preferably greater than or equal to 100 GHz, further preferably greater than or equal to 150 GHz in a room temperature environment, for example.

As described above, the OS transistor has effects superior to those of the Si transistor, such as a low off-state current and capability of having a short channel length.

### [[Impurity in Metal Oxide]]

Here, the influence of each impurity in the metal oxide (oxide semiconductor) is described.

When silicon or carbon, which is a Group 14 element, is contained in the oxide semiconductor, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. When nitrogen is contained in the oxide semiconductor, trap states are sometimes formed. This might make the electrical characteristics of the transistor unstable. Thus, the nitrogen concentration in the channel formation region in the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the channel formation region of the oxide semiconductor, which is obtained using SIMS, is lower than or equal to 1×10¹⁸ atoms/cm³, preferably lower than or equal to 2×10¹⁶ atoms/cm³.

When an oxide semiconductor with sufficiently reduced impurity concentration is used for a channel formation region in a transistor, the transistor can have stable electrical characteristics.

### [Other Semiconductor Materials]

The oxide semiconductor 230 can be rephrased as a semiconductor layer including a channel formation region of a transistor. A semiconductor material that can be used for the semiconductor layer is not limited to the above metal oxides. The semiconductor material that has a band gap (a semiconductor material that is not a zero-gap semiconductor) may be used for the semiconductor layer. For example, a single element semiconductor, a compound semiconductor, a layered material (also referred to as an atomic layered material or a two-dimensional material), or the like is preferably used as the semiconductor material.

Here, in this specification and the like, the layered substance generally refers to a group of materials having a layered crystal structure. In the layered crystal structure, layers formed by covalent bonding or ionic bonding are stacked with bonding such as the van der Waals binding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. Examples of silicon that can be used for the semiconductor layer include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered material include graphene, silicene, boron carbonitride, and chalcogenide. Boron carbonitride serving as the layered material contains carbon, nitrogen, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For the semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a memory device with a high on-state current to be provided.

### <Method for Manufacturing Memory Device>

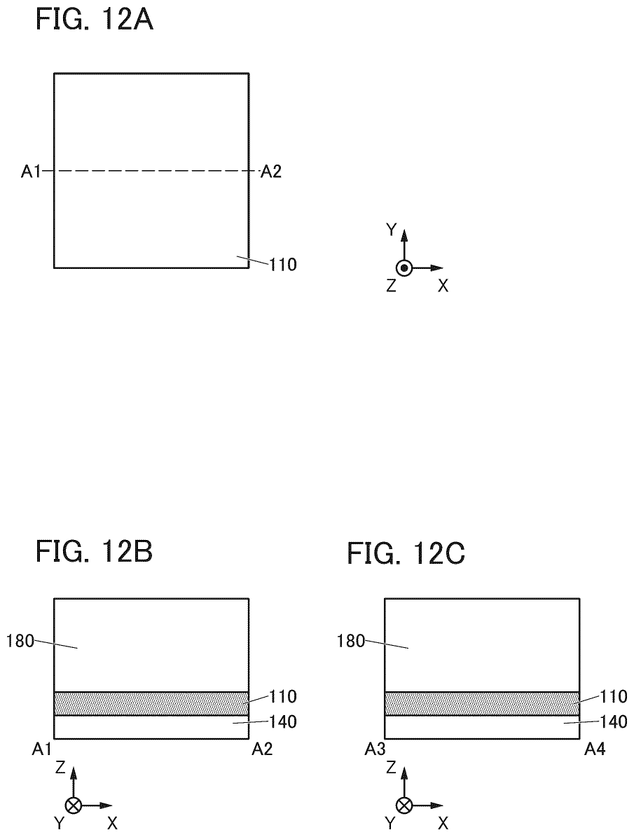

Next, a method for manufacturing the memory device of one embodiment of the present invention illustrated in FIG. 2A to FIG. 2D will be described with reference to FIG. 12A to FIG. 22C.

Note that A of each drawing is a plan view of a region including the memory cell 150. Moreover, B of each drawing corresponds to FIG. 2B and is a cross-sectional view corresponding to a portion indicated by the dashed-dotted line A1-A2 in A of each drawing. Furthermore, C of each drawing is a cross-sectional view of the functional element 155 corresponding to FIG. 2D. Note that for clarity of the drawing, some components are omitted in the plan view of A of each drawing. The plan view of the functional element 155 corresponding to FIG. 2C is omitted because it is similar to the plan view of the memory cell 150, which can be referred to.

Hereinafter, an insulating material for forming an insulator, a conductive material for forming a conductor, or a semiconductor material for forming a semiconductor can be deposited by a sputtering method, a CVD method, an MBE method, a PLD method, an ALD method, or the like as appropriate.

Examples of a sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. The RF sputtering method is mainly used in the case where an insulating film is formed, and the DC sputtering method is mainly used in the case where a metal conductive film is formed. The pulsed DC sputtering method is mainly used in the case where a compound such as an oxide, a nitride, or a carbide is deposited by a reactive sputtering method.

Note that CVD methods can be classified into a plasma CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method depending on a source gas to be used.

A high-quality film can be obtained at a relatively low temperature by the plasma CVD method. Furthermore, the thermal CVD method is a deposition method that does not use plasma and thus enables less plasma damage to an object to be processed. For example, a wiring, an electrode, an element (a transistor, a capacitor, or the like), or the like included in a memory device may be charged up by receiving charge from plasma. In that case, accumulated charge may break the wiring, the electrode, the element, or the like included in the memory device. In contrast, such plasma damage is not caused in the case of a thermal CVD method, which does not use plasma, and thus the yield of the memory device can be increased. In addition, the thermal CVD method does not cause plasma damage during deposition, so that a film with few defects can be obtained.

As an ALD method, a thermal ALD method, in which a precursor and a reactant react with each other only by a thermal energy, a PEALD method, in which a reactant excited by plasma is used, and the like can be used.

A CVD method and an ALD method are different from a sputtering method in which particles ejected from a target or the like are deposited. Thus, a CVD method and an ALD method are less likely to be influenced by the shape of an object to be processed and thus enable favorable step coverage. In particular, an ALD method allows excellent step coverage and excellent thickness uniformity and thus is suitably used to cover a surface of an opening portion with a high aspect ratio, for example. Note that an ALD method has a relatively low deposition rate and thus is sometimes preferably combined with another deposition method with a high deposition rate, such as a CVD method.

By a CVD method, a film with a certain composition can be deposited depending on the flow rate ratio of the source gases. For example, when the flow rate ratio of the source gas is changed during the deposition in a CVD method, a film whose composition is continuously changed can be formed. In the case where a film is formed while the flow rate ratio of the source gas is changed, as compared with the case where a film is formed using a plurality of deposition chambers, the time taken for the deposition can be shortened because the time taken for transfer or pressure adjustment is not required. Thus, the productivity of the memory device can be increased in some cases.

By an ALD method, a film with a certain composition can be formed by concurrently introducing different kinds of precursors. In the case where different kinds of precursors are introduced, a film with a freely selected composition can be formed by controlling the number of cycles for each of the precursors.

First, a substrate (not illustrated) is prepared, and the insulator 140 is formed over the substrate (see FIG. 12A to FIG. 12C). Any of the above-described insulating materials is used for the insulator 140 as appropriate. The insulator 140 can be formed by a sputtering method, a CVD method, an MBE method, a PLD method, an ALD method, or the like as appropriate.

Then, the conductor 110 is formed over the insulator 140. Any of the above-described conductive materials may be used for the conductor 110 as appropriate. The conductor 110 may be deposited by a sputtering method, a CVD method, an MBE method, a PLD method, an ALD method, or the like as appropriate. For example, as the conductor 110, a stacked-layer film in which tungsten and titanium nitride may be deposited in this order by a CVD method may be formed.

Note that the conductor 110 may be processed to have a shape extending in the X direction or the Y direction. Note that the conductor 110 may be processed by a lithography method. A dry etching method or a wet etching method can be used for the processing. Processing by a dry etching method is suitable for microfabrication. By the processing, a side end portion of the conductor 110 is covered with the insulator 130 to be formed later.

In the lithography method, first, a resist is exposed to light through a mask. Next, a region exposed to light is removed or left using a developing solution, so that a resist mask is formed. Then, etching treatment through the resist mask is performed, whereby a conductor, a semiconductor, an insulator, or the like can be processed into a desired shape. The resist mask may be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. Note that the resist mask can be removed by dry etching treatment such as ashing, wet etching treatment, wet etching treatment after dry etching treatment, or dry etching treatment after wet etching treatment.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example.

Next, the insulator 180 is formed over the conductor 110 (see FIG. 12A to FIG. 12C). Any of the above-described insulating materials may be used for the insulator 180 as appropriate. The insulator 180 may be formed by a sputtering method, a CVD method, an MBE method, a PLD method, an ALD method, or the like as appropriate. A silicon oxide film may be formed by a sputtering method as the insulator 180, for example. The top surface of the deposited insulator 180 is preferably planarized by CMP treatment or the like. Note that the CMP treatment is not necessarily performed in some cases. In that case, the top surface of the insulator 180 has a curved shape that is convex upward. By not performing planarization treatment, manufacturing cost can be reduced and production yield can be increased.

Here, the thickness of the insulator 180 corresponds to the capacitance of the capacitor 100 and thus is set as appropriate depending on the design value of the capacitance of the capacitor 100.

By using, for the insulator 180, a sputtering method that does not need to use a molecule containing hydrogen as a deposition gas, the concentration of hydrogen in the insulator 180 can be reduced.

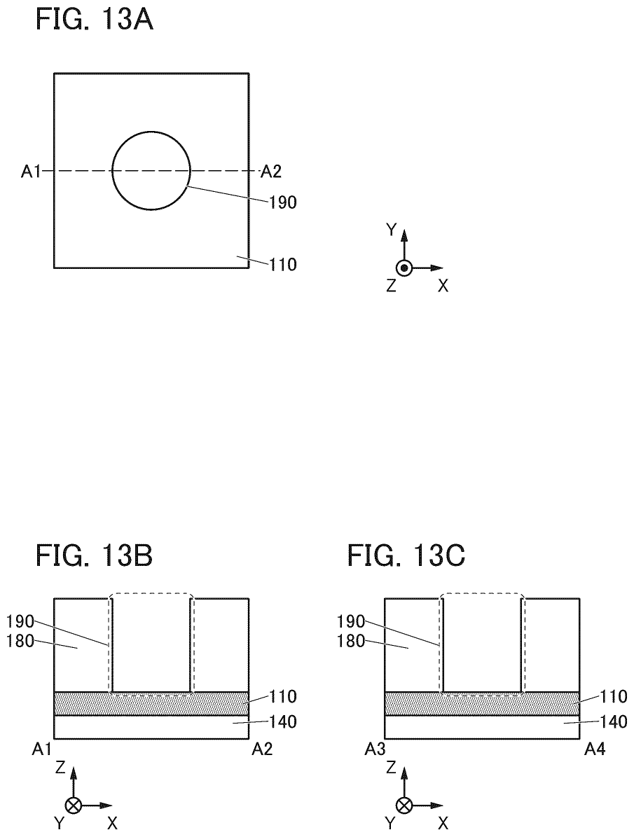

Then, part of the insulator 180 is processed to form the opening portion 190 reaching the conductor 120 (see FIG. 13A to FIG. 13C). The opening portion 190 may be formed by a lithography method. Note that although the opening portion 190 has a circular shape in the plan view, the shape of the opening portion is not limited thereto. For example, the opening portion 190 in the plan view may have an almost circular shape such as an elliptical shape, a polygonal shape such as a quadrangular shape, or a polygonal shape such as a quadrangular shape with rounded corners.

As described above, the sidewall of the opening portion 190 is preferably perpendicular to the top surface of the conductor 110. Such a structure enables the memory device to be miniaturized or highly integrated. Note that the sidewall of the opening portion 190 may have a tapered shape. When the sidewall of the opening portion 190 has a tapered shape, the coverage with a conductive film to be the conductor 115 described later can be improved, for example, so that defects such as voids can be reduced.

The maximum width of the opening portion 190 (the diameter in the case where the opening portion 190 is circular in the plan view) is preferably small. For example, the maximum width of the opening portion 190 is preferably less than or equal to 60 nm, less than or equal to 50 nm, less than or equal to 40 nm, less than or equal to 30 nm, or less than or equal to 20 nm and greater than or equal to 1 nm or greater than or equal to 5 nm. In order to process the opening portion 190 such finely, a lithography method using an electron beam or short-wavelength light such as EUV light is preferably used.

Since the opening portion 190 has a high aspect ratio, part of the insulator 280 is preferably processed by anisotropic etching. Processing by a dry etching method is particularly preferable because it is suitable for microfabrication.

Next, a conductive film to be the conductor 115 is formed in contact with the bottom portion and sidewall of the opening portion 190 and at least part of the top surface of the insulator 180. For the conductive film, any of the above-described conductors that can be used for the conductor 115 may be used as appropriate. The conductive film may be formed by a sputtering method, a CVD method, an MBE method, a PLD method, an ALD method, or the like as appropriate. Here, the conductive film is preferably formed in contact with the bottom portion and sidewall of the opening portion 190 with a high aspect ratio. Thus, the conductive film is preferably formed by a deposition method providing favorable coverage, and is further preferably formed by a CVD method, an ALD method, or the like. For example, a titanium nitride film may be formed by a CVD method as the conductive film.

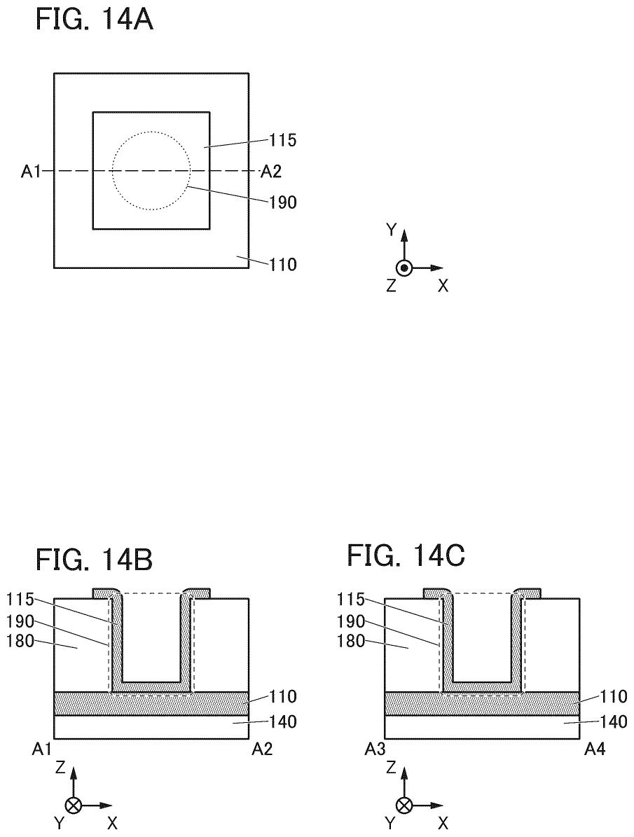

Next, the conductive film to be the conductor 115 is processed by a lithography method to form the conductor 115 (see FIG. 14A to FIG. 14C). Accordingly, part of the conductor 115 is formed in the opening portion 190. The conductor 115 is in contact with a side surface and part of the top surface of the insulator 180.

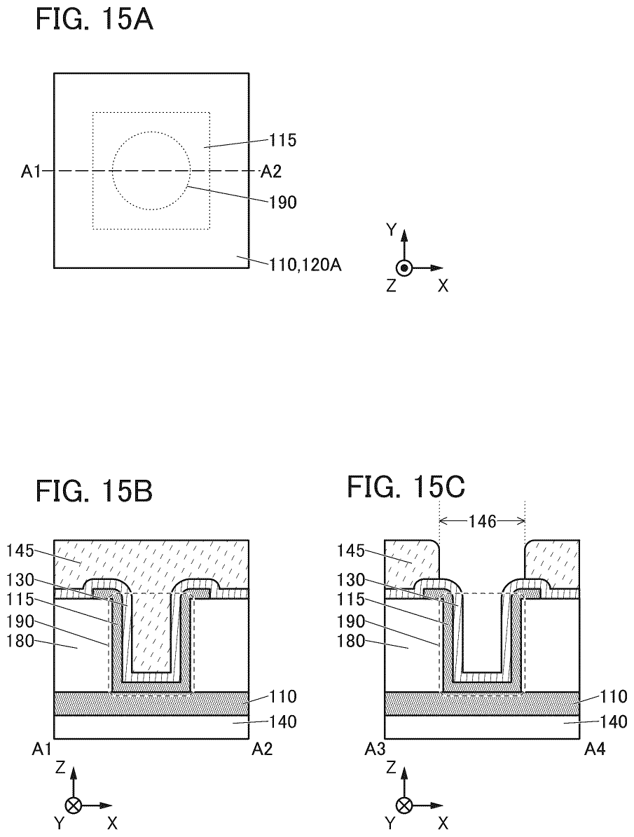

Next, the insulator 130 is formed over the conductor 115 and the insulator 180 (see FIG. 15A to FIG. 15C). Any of the above-described high-k materials or materials showing ferroelectricity may be used for the insulator 130 as appropriate. The insulator 130 may be formed by a sputtering method, a CVD method, an MBE method, a PLD method, an ALD method, or the like as appropriate. For example, as the insulator 130, a stacked-layer film in which zirconium oxide, aluminum oxide, and zirconium oxide are deposited in this order by an ALD method may be formed.

Next, a resist mask 145 is formed over the insulator 130 (see FIG. 15A to FIG. 15C). The resist mask 145 is formed so that an opening 146 is formed in a portion overlapping with the opening portion 190 in a region to be the functional element 155 (see FIG. 15C), whereas the resist mask 145 is formed so as to cover the opening portion 190 in a region to be the memory cell 150.

The opening 146 of the resist mask 145 may have any shape as long as it encompasses the opening portion 190 in the plan view. Even in the case where the opening portion 190 is circular, the opening 146 is not necessarily circular and may be rectangular, for example.

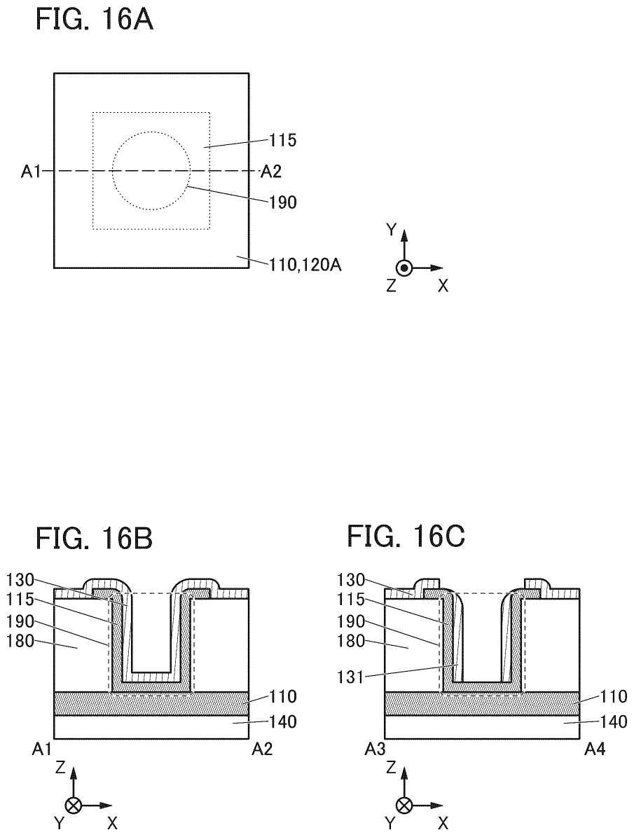

Next, a portion of the insulator 130 that is not covered with the resist mask 145 is removed by etching (see FIG. 16A to FIG. 16C). Here, an example in which anisotropic etching is used for the processing is described. The anisotropic etching allows the insulator 131 to remain in the opening portion 190. Note that isotropic etching offers a structure in which the insulator 131 does not remain.

When the insulator 130 in the opening portion 190 is removed completely in the case where the aspect ratio of the opening portion 190 is high (e.g., two or more), the insulator 130 positioned on the inner wall of the opening portion 190 takes longer time to be etched than the insulator 130 positioned in the bottom portion of the opening portion 190. Therefore, the insulator 130 disappears earlier in the bottom portion of the opening portion 190, and the conductor 115 is exposed to etching and is damaged in some cases. By contrast, in one embodiment of the present invention, etching can be performed to the extent of removing at least the insulator 130 positioned in the bottom portion of the opening portion 190, thereby mitigating damage to the conductor 115. Furthermore, when the insulator 131 remains, the adhesion of the conductor 120 formed thereover is improved in some cases.

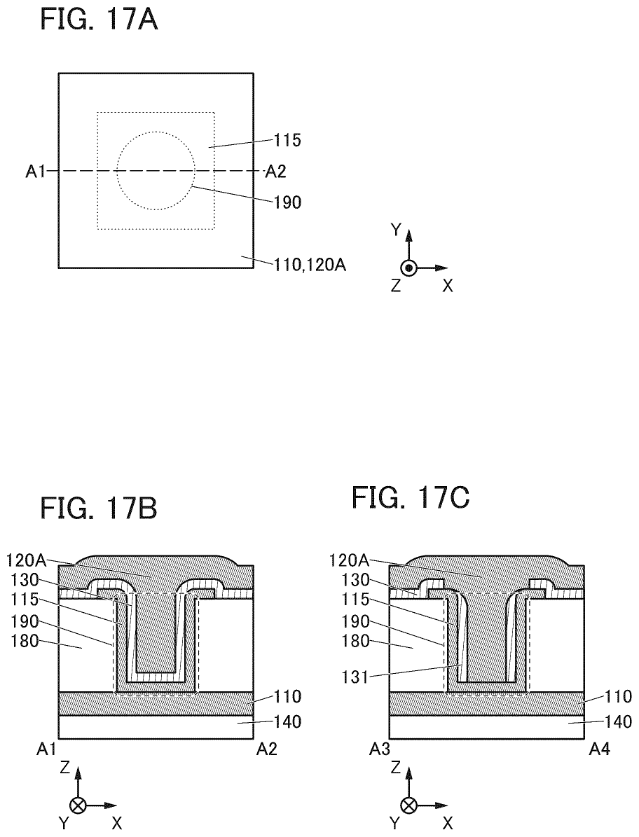

Next, a conductive film 120A is formed (see FIG. 17A to FIG. 17C). Any of the above-described conductive materials may be used for the conductive film 120A. The conductive film 120A may be formed by a sputtering method, a CVD method, an MBE method, a PLD method, an ALD method, or the like as appropriate. For example, as the conductive film 120A, a stacked-layer film in which titanium nitride and tantalum nitride are deposited in this order by a CVD method may be formed. Alternatively, for example, a stacked-layer film in which titanium nitride and tungsten are deposited in this order by a CVD method may be formed as the conductive film 120A.

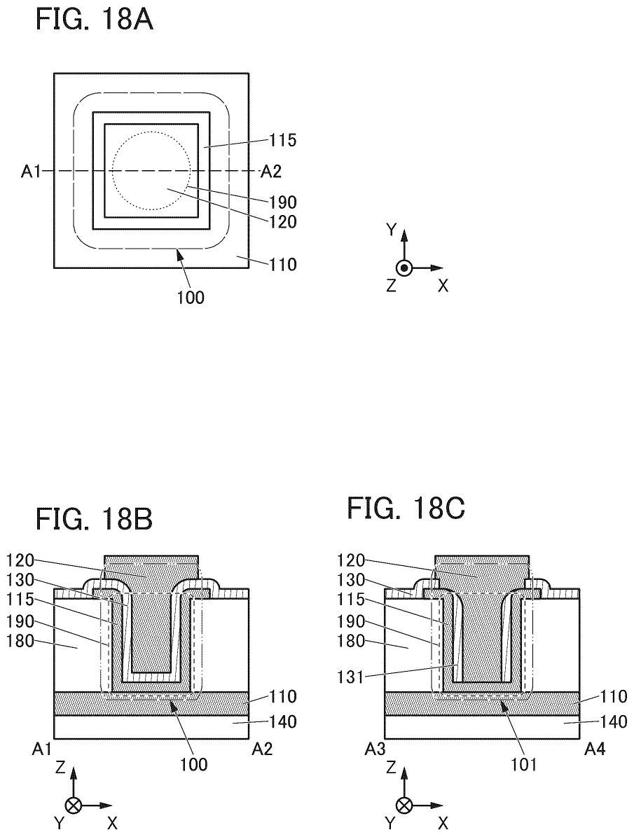

Next, the conductive film 120A is processed to form the conductor 120 (see FIG. 18A to FIG. 18C). The conductor 120 may be formed by a lithography method. A dry etching method or a wet etching method can be used to process the conductive film 120A. Processing by a dry etching method is suitable for microfabrication.

In the above manner, the connection portion 101 and the capacitor 100 including the conductor 115, the insulator 130, and the conductor 120 can be formed separately from each other.

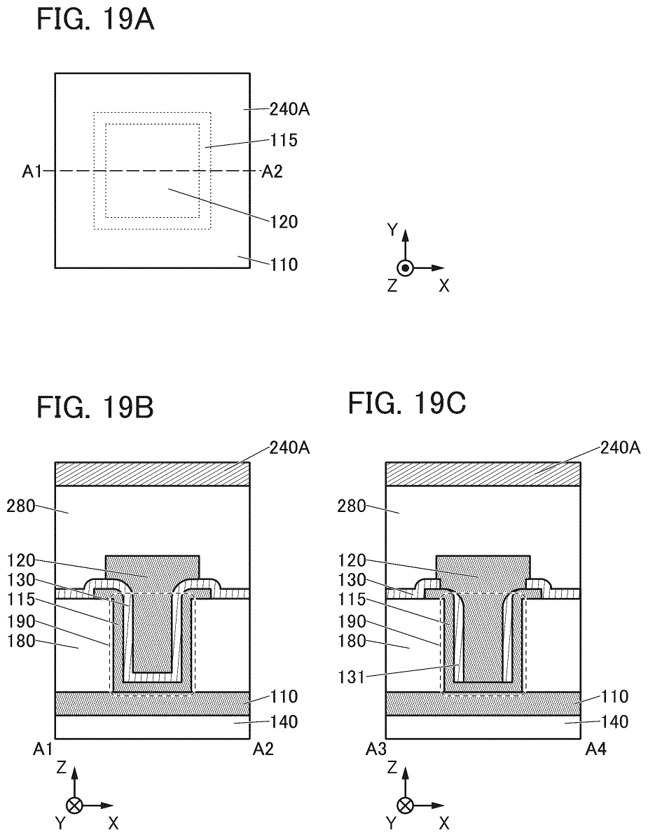

Next, the insulator 280 is formed over the insulator 130 and the conductor 120 (see FIG. 19A to FIG. 19C). Any of the above-described insulating materials may be used for the insulator 280 as appropriate. The insulator 280 may be formed by a sputtering method, a CVD method, an MBE method, a PLD method, an ALD method, or the like as appropriate. For example, a silicon oxide film may be formed by a sputtering method as the insulator 280. The top surface of the formed insulator 280 is preferably planarized by CMP (Chemical Mechanical Polishing) treatment. The planarization treatment on the insulator 280 allows the conductor 240 functioning as a wiring to be formed favorably. After aluminum oxide is deposited over the insulator 280 by, for example, a sputtering method, the aluminum oxide may be subjected to CMP treatment until the insulator 280 is reached. The CMP treatment can planarize and smooth the surface of the insulator 280. When the CMP treatment is performed on the aluminum oxide positioned over the insulator 280, it is easy to detect the endpoint of the CMP treatment.

Note that the CMP treatment is not necessarily performed in some cases. In that case, the top surface of the insulator 280 has a convex curved shape. By not performing planarization treatment, manufacturing cost can be reduced and production yield can be increased.

Note that since the thickness of the insulator 280 over the conductor 120 corresponds to the channel length of the transistor 200, the thickness of the insulator 280 may be set as appropriate depending on the design value of the channel length of the transistor 200.

When the insulator 280 is formed by a sputtering method in an oxygen-containing atmosphere, the insulator 280 containing excess oxygen can be formed. By using a sputtering method that does not need to use a molecule containing hydrogen as a deposition gas, the hydrogen concentration in the insulator 280 can be reduced. When the insulator 280 is formed in this manner, oxygen can be supplied from the insulator 280 to the channel formation region of the oxide semiconductor 230, so that oxygen vacancies and V_{O}H can be reduced.

Next, a conductive film 240A is formed over the insulator 280 (see FIG. 19A to FIG. 19C). Any of the above-described conductive materials may be used for the conductive film 240A as appropriate. The conductive film 240A may be deposited by a sputtering method, a CVD method, an MBE method, a PLD method, an ALD method, or the like as appropriate.

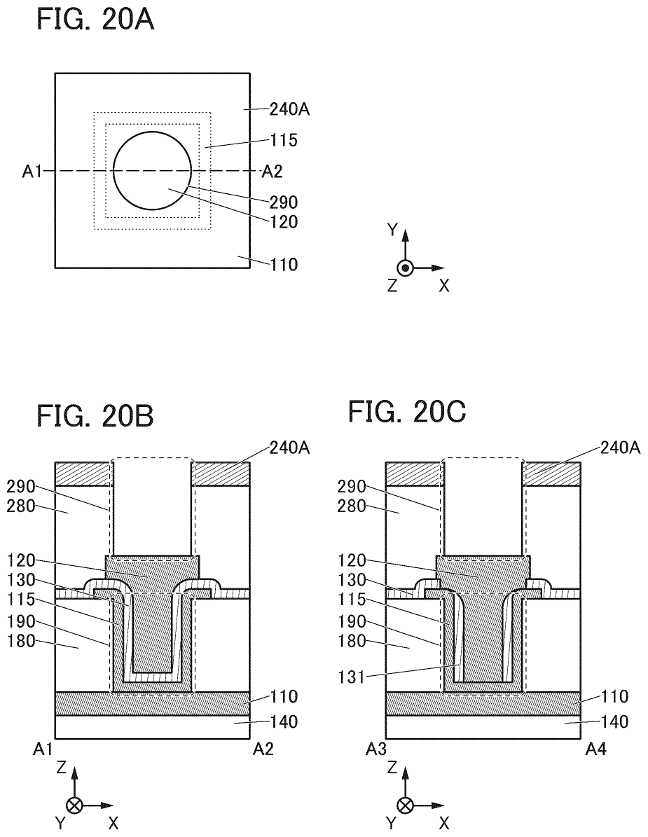

Next, part of the conductive film 240A and part of the insulator 280 are processed to form the opening portion 290 reaching the conductor 120 (see FIG. 20A to FIG. 20C). The opening portion 290 may be formed by a lithography method. Note that although the opening portion 290 has a circular shape in the plan view of FIG. 20A, the shape of the opening portion is not limited thereto. For example, the opening portion 290 in the plan view may have an almost circular shape such as an elliptical shape, a polygonal shape such as a quadrangular shape, or a polygonal shape such as a quadrangular shape with rounded corners.

As described above, the sidewall of the opening portion 290 is preferably perpendicular to the top surface of the conductor 110. Such a structure enables the memory device to be miniaturized or highly integrated. The sidewall of the opening portion 290 may have a tapered shape. When the sidewall of the opening portion 290 has a tapered shape, the coverage with an oxide semiconductor film to be the oxide semiconductor 230 or the like described later can be improved, so that defects such as voids can be reduced.

The maximum width of the opening portion 290 (the maximum diameter in the case where the opening portion 290 is circular in the plan view) is preferably small. For example, the maximum width of the opening portion 290 is preferably less than or equal to 60 nm, less than or equal to 50 nm, less than or equal to 40 nm, less than or equal to 30 nm, or less than or equal to 20 nm and greater than or equal to 1 nm or greater than or equal to 5 nm. In order to process the opening portion 290 such finely, a lithography method using an electron beam or short-wavelength light such as EUV light is preferably used.

Since the opening portion 290 has a high aspect ratio, part of the conductive film 240A and part of the insulator 280 are preferably processed by anisotropic etching. Processing by a dry etching method is particularly preferable because it is suitable for microfabrication. The processing may be performed under different conditions. Note that as described above, the inclination of a side surface of the conductor 240 in the opening portion 290 and the inclination of a side surface of the insulator 280 in the opening portion 290 may be different from each other depending on the conditions for processing part of the conductive film 240A and part of the insulator 280.

Next, heat treatment may be performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is approximately 20%. The heat treatment may be performed under reduced pressure. Alternatively, heat treatment may be performed in an atmosphere of a nitrogen gas or an inert gas, and then another heat treatment may be performed in an atmosphere containing an oxidizing gas at 10 ppm or more, 1% or more, or 10% or more in order to compensate for released oxygen. By the above-described heat treatment, impurities such as water contained in the insulator 280, for example, can be reduced before an oxide semiconductor film to be the oxide semiconductor 230 described later is formed.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment using a highly purified gas can prevent entry of moisture or the like into the insulator 280 and the like as much as possible.

Next, an oxide semiconductor film to be the oxide semiconductor 230 is formed in contact with the bottom portion and sidewall of the opening portion 290 and at least part of the top surface of the conductive film 240A. For the oxide semiconductor film, any of the above-described metal oxides that can be used for the oxide semiconductor 230 may be used as appropriate. The oxide semiconductor film may be formed by a sputtering method, a CVD method, an MBE method, a PLD method, an ALD method, or the like as appropriate. Here, the oxide semiconductor film is preferably formed in contact with the bottom portion and sidewall of the opening portion 290 with a high aspect ratio. Thus, the oxide semiconductor film is preferably formed by a deposition method providing favorable coverage, and is further preferably formed by a CVD method, an ALD method, or the like. For example, an In—Ga—Zn oxide may be deposited by an ALD method as the oxide semiconductor film. Note that a method for depositing the metal oxide by an ALD method will be described in detail in an embodiment described below.

Note that in the case where the sidewall of the opening portion 290 has a tapered shape, the method for forming the oxide semiconductor film to be the oxide semiconductor 230 is not limited to a CVD method or an ALD method. For example, a sputtering method may be employed.

During or after the formation of the oxide semiconductor film, microwave treatment is preferably performed in an oxygen-containing atmosphere so that the impurity concentration in the oxide semiconductor film can be reduced. Specific examples of the impurity include hydrogen and carbon. The microwave treatment can increase the crystallinity of the oxide semiconductor film in some cases. Here, the microwave treatment refers to, for example, treatment using an apparatus including a power source that generates high-density plasma with use of a microwave.

The microwave treatment in an oxygen-containing atmosphere converts an oxygen gas into plasma using a high-frequency wave such as a microwave or RF and activates the oxygen plasma. The oxygen that works on the oxide semiconductor has any of a variety of forms such as an oxygen atom, an oxygen molecule, an oxygen ion, and an oxygen radical (also referred to as O radical, which is an atom, a molecule, or an ion having an unpaired electron). Note that the oxygen that works on the oxide semiconductor preferably has any one or more of the above forms; an oxygen radical is particularly preferable.

The aforementioned microwave treatment in an oxygen-containing atmosphere is preferably performed while the substrate is heated, in which case the impurity concentration in the oxide semiconductor can be further reduced. The substrate may be heated at a temperature higher than or equal to 100° C. and lower than or equal to 650° C., preferably higher than or equal to 200° C. and lower than or equal to 600° C., further preferably higher than or equal to 300° C. and lower than or equal to 450° C.

When the microwave treatment in an oxygen-containing atmosphere is performed while the substrate is heated, the carbon concentration in the oxide semiconductor, which is measured by SIMS, can be lower than 1×10²⁰ atoms/cm³, preferably lower than 1×10¹⁹ atoms/cm³, further preferably lower than 1×10¹⁸ atoms/cm³.

Although the microwave treatment in an oxygen-containing atmosphere is performed on the oxide semiconductor in the above example, one embodiment of the present invention is not limited thereto. For example, the microwave treatment in an oxygen-containing atmosphere may be performed on an insulating film, more specifically a silicon oxide film, which is positioned in the vicinity of the oxide semiconductor. In that case, hydrogen contained in the silicon oxide film can be released to the outside as H₂O. Release of hydrogen from the silicon oxide film positioned in the vicinity of the oxide semiconductor enables a highly reliable memory device to be provided.

In the case where the oxide semiconductor 230 has a stacked-layer structure as illustrated in FIG. 9A and FIG. 9B, the layers included in the oxide semiconductor 230 may be formed by the same method or different methods. For example, in the case where the oxide semiconductor 230 has a stacked-layer structure of two layers, the lower oxide semiconductor film may be formed by a sputtering method and the upper oxide semiconductor film may be formed by an ALD method. An oxide semiconductor film formed by a sputtering method is likely to have crystallinity. Thus, when an oxide semiconductor film having crystallinity is provided as the lower oxide semiconductor film, the crystallinity of the upper oxide semiconductor film can be increased. Even when a pin hole, disconnection, or the like is formed in the lower oxide semiconductor film formed by a sputtering method, the upper oxide semiconductor film formed by an ALD method with favorable coverage can fill the portion.

Here, the oxide semiconductor film to be the oxide semiconductor 230 is preferably formed in contact with the top surface of the conductor 120 in the opening portion 290, the side surface of the insulator 280 in the opening portion 290, the side surface of the conductor 240 in the opening portion 290, and the top surface of the conductor 240. When the oxide semiconductor film is formed in contact with the conductor 120, the conductor 120 functions as one of a source electrode and a drain electrode of the transistor 200. When the oxide semiconductor film is formed in contact with the conductor 240, the conductor 240 functions as the other of the source electrode and the drain electrode of the transistor 200.

Next, heat treatment is preferably performed. The heat treatment is performed in a temperature range where the oxide semiconductor film does not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is approximately 20%. The heat treatment may be performed under reduced pressure. Alternatively, heat treatment may be performed in an atmosphere of a nitrogen gas or an inert gas, and then another heat treatment may be performed in an atmosphere containing an oxidizing gas at 10 ppm or more, 1% or more, or 10% or more in order to compensate for released oxygen.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment using a highly purified gas can prevent entry of moisture or the like into the oxide semiconductor film and the like as much as possible.

Here, the above-described heat treatment is preferably performed in the state where the insulator 280 containing excess oxygen is in contact with the oxide semiconductor film. When the heat treatment is performed in that manner, oxygen can be supplied from the insulator 280 to the channel formation region of the oxide semiconductor 230, so that oxygen vacancies and V_{O}H can be reduced.

Note that although the heat treatment is performed after the oxide semiconductor film is formed in the above description, the present invention is not limited thereto. Heat treatment may be further performed in a later step.

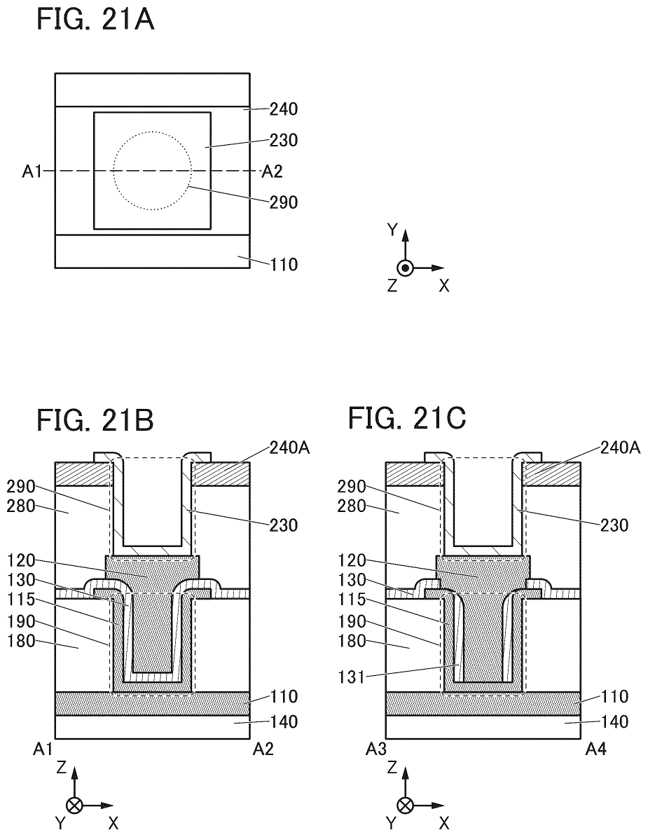

Next, the oxide semiconductor film to be the oxide semiconductor 230 is processed by a lithography method to form the oxide semiconductor 230 (see FIG. 21A to FIG. 21C). Accordingly, part of the oxide semiconductor 230 is formed in the opening portion 290. The oxide semiconductor 230 is in contact with the side surface and part of the top surface of the conductor 240. Thus, the area of a region where the oxide semiconductor 230 and the conductor 240 are in contact with each other can be increased.

Next, the conductive film 240A is processed to form the conductor 240. The conductor 240 may be formed by a lithography method. A dry etching method or a wet etching method can be used to process the conductive film 240A. Processing by a dry etching method is suitable for microfabrication.

Note that although the method in which the conductive film 240A is processed to form the conductor 240 after the oxide semiconductor 230 is processed is described here, the conductive film 240A may be processed first. That is, formation may be performed in the following order: the conductive film 240A is formed over the insulator 280; the conductive film 240A is processed to form the conductor 240; the opening portion 290 is formed in the conductor 240 and the insulator 280; and the oxide semiconductor film is formed and processed to form the oxide semiconductor 230.

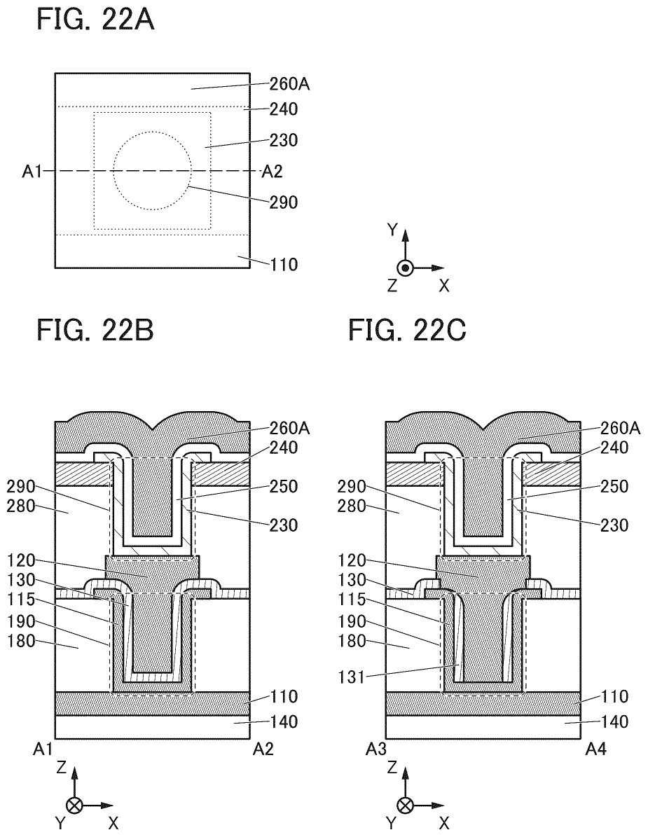

Next, the insulator 250 is formed over the oxide semiconductor 230, the conductor 240, and the insulator 280 (see FIG. 22A to FIG. 22C). For the insulator 250, any of the above-described insulating materials may be used as appropriate. The insulator 250 may be formed by a sputtering method, a CVD method, an MBE method, a PLD method, an ALD method, or the like as appropriate. Here, the insulator 250 is preferably formed in contact with the oxide semiconductor 230 provided in the opening portion 290 with a high aspect ratio. Thus, the insulator 250 is preferably formed by a deposition method providing favorable coverage, and is further preferably formed by a CVD method, an ALD method, or the like. For example, silicon oxide may be deposited by an ALD method as the insulator 250.

Note that in the case where the sidewall of the opening portion 290 has a tapered shape, the method for forming the insulator 250 is not limited to a CVD method or an ALD method. For example, a sputtering method may be employed.

When the insulator 250 is formed after the oxide semiconductor 230 is formed, a side end portion of the oxide semiconductor 230 is covered with the insulator 250. Thus, a short circuit between the oxide semiconductor 230 and the conductor 260 can be prevented. Furthermore, in the above-described structure, the side end portion of the conductor 240 is covered with the insulator 250. Thus, a short circuit between the conductor 240 and the conductor 260 can be prevented.

Next, a conductive film 260A is formed to fill a depressed portion defined by the insulator 250 (see FIG. 22A to FIG. 22C). For the conductive film 260A, any of the above-described conductive materials may be used as appropriate. The conductive film 260A may be formed by a sputtering method, a CVD method, an MBE method, a PLD method, an ALD method, or the like as appropriate. Here, the conductive film 260A is preferably formed in contact with the insulator 250 provided in the opening portion 290 with a high aspect ratio. Thus, the conductive film 260A is preferably formed by a deposition method providing favorable coverage or embeddability, and is further preferably formed by a CVD method, an ALD method, or the like. For example, titanium nitride may be deposited by a CVD method or an ALD method as the conductive film 260A.

In the case where the conductive film 260A is formed by a CVD method, the average surface roughness of the top surface of the conductive film 260A is sometimes increased. In this case, the conductive film 260A is preferably planarized by a CMP method. At this time, before the CMP treatment, a silicon oxide film or a silicon oxynitride film may be formed over the conductive film 260A and the CMP treatment may be performed until the silicon oxide film or the silicon oxynitride film is removed.

Although the conductive film 260A is provided to fill the opening portion 290 in the above description, the present invention is not limited thereto. For example, a depressed portion reflecting the shape of the opening portion 290 is formed in a center portion of the conductive film 260A in some cases. The depressed portion may be filled with an inorganic insulating material or the like.

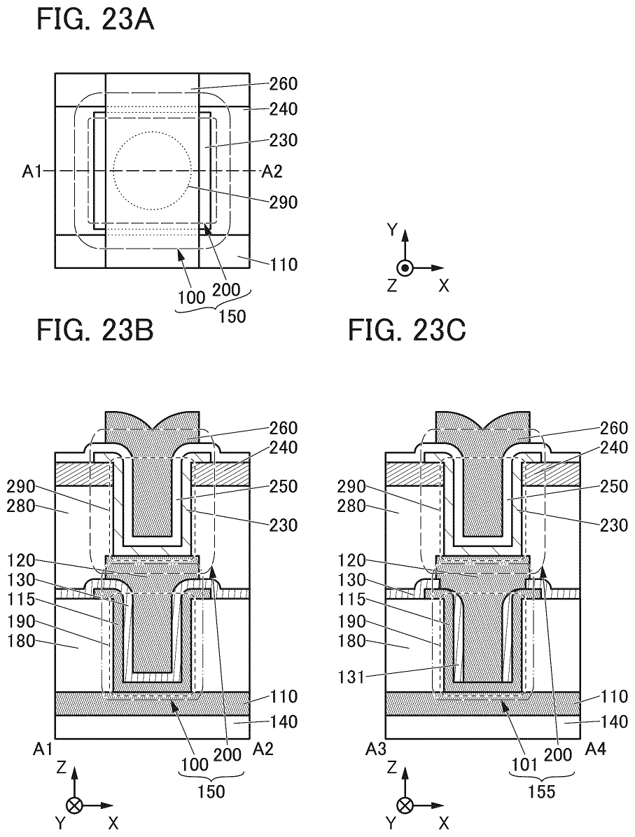

Next, the conductive film 260A is processed to form the conductor 260 (see FIG. 23A to FIG. 23C). The conductor 260 may be formed by a lithography method. A dry etching method or a wet etching method can be used for the processing. Processing by a dry etching method is suitable for microfabrication.

Here as illustrated in FIG. 2A and FIG. 2B, the side end portion of the conductor 260 is preferably positioned inward from the side end portion of the oxide semiconductor 230 in the plan view. In that case, a short circuit between the conductor 260 and the oxide semiconductor 230 can be prevented.

In the above manner, the transistor 200 including the conductor 120, the conductor 240, the oxide semiconductor 230, the insulator 250, and the conductor 260 can be formed.

Next, the insulator 283 is formed to cover the conductor 260 and the insulator 250. For the insulator 283, any of the above-described insulating materials may be used as appropriate. The insulator 283 may be formed by a sputtering method, a CVD method, an MBE method, a PLD method, an ALD method, or the like as appropriate.

Through the above steps, the memory device including the memory cell 150 and the functional element 155 illustrated in FIG. 2A to FIG. 2D can be manufactured.

According to one embodiment of the present invention, a novel transistor, a novel semiconductor device, and a novel memory device can be provided. A memory device that can be miniaturized or highly integrated can be provided. A memory device with favorable frequency characteristics can be provided. A memory device with a high operation speed can be provided. A highly reliable memory device can be provided. A memory device with low power consumption can be provided. A transistor with a high on-state current can be provided. A memory device with a small variation in transistor characteristics can be provided. A memory device with favorable electrical characteristics can be provided.

The memory cell 150 including the transistor 200 and the capacitor 100 described in this embodiment can be used as a memory cell of the memory device. The functional element including the transistor 200 and the connection portion 101 can be used as a peripheral circuit of the memory device. The transistor 200 is a transistor in which a channel is formed in a semiconductor layer including an oxide semiconductor. Since the transistor 200 has a low off-state current, a memory device that uses the transistor 200 can retain stored content for a long time. In other words, such a memory device does not require refresh operation or has extremely low frequency of the refresh operation, which leads to a sufficient reduction in power consumption of the memory device. The transistor 200 also has high frequency characteristics and thus enables high-speed reading and writing of the memory device.

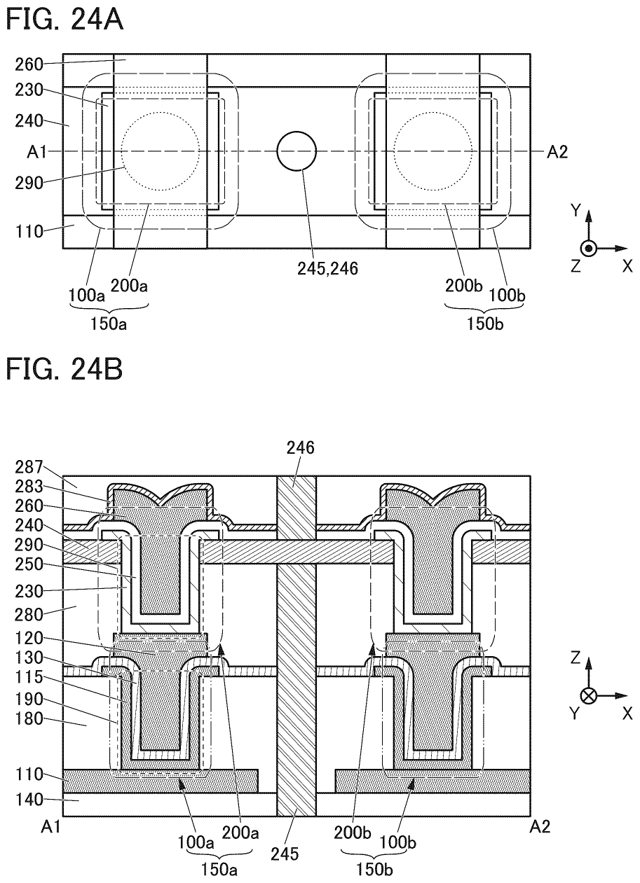

An example of a memory device in which two memory cells 150 (hereinafter referred to as a memory cell 150a and a memory cell 150b) are connected to a common wiring is described with reference to FIG. 24A and FIG. 24B. FIG. 24A is a plan view of the memory device. FIG. 24B is a cross-sectional view of a portion indicated by the dashed-dotted line A1-A2 in FIG. 24A. Note that for clarity of the drawing, some components are omitted in the plan view of FIG. 24A.

Here, the memory cell 150a and the memory cell 150b illustrated in FIG. 24A and FIG. 24B each have a structure similar to that of the memory cell 150. The memory cell 150a includes a capacitor 100a and a transistor 200a, and the memory cell 150b includes a capacitor 100b and a transistor 200b.

As illustrated in FIG. 24A and FIG. 24B, the conductor 260 functioning as the wiring WL is provided in each of the memory cell 150a and the memory cell 150b. The conductor 240 functioning as part of the wiring BL is provided in common to the memory cell 150a and the memory cell 150b. That is, the conductor 240 is in contact with the oxide semiconductor 230 of the memory cell 150a and the oxide semiconductor 230 of the memory cell 150b.

Here, the memory device illustrated in FIG. 24A and FIG. 24B includes a conductor 245 and a conductor 246 functioning as plugs (also can be referred to as connection electrodes) electrically connected to the memory cell 150a and the memory cell 150b. The conductor 245 is positioned in an opening formed in the insulator 180, the insulator 130, the insulator 280, and the insulator 140 and is in contact with the bottom surface of the conductor 240. The conductor 246 is positioned in an opening portion formed in the insulator 287, the insulator 283, and the insulator 250, and is in contact with the top surface of the conductor 240. Note that a conductive material or the like that can be used for the conductor 240 can be used for the conductor 245 and the conductor 246.

The insulator 287 functions as an interlayer film and thus preferably has low relative permittivity. When a material with low relative permittivity is used for an interlayer film, parasitic capacitance generated between wirings can be reduced. As the insulator 287, a single layer or stacked layers of an insulator containing any of the above-described materials with low relative permittivity can be used. The concentration of impurities such as water and hydrogen in the insulator 287 is preferably reduced. This can inhibit entry of impurities such as water and hydrogen into the channel formation region of the oxide semiconductor 230.

The conductor 245 can be electrically connected to a sense amplifier (not illustrated) provided below the memory device illustrated in FIG. 24B, for example, and the conductor 246 can be electrically connected to a similar memory device (not illustrated) provided above the memory device illustrated in FIG. 24B. In this case, the conductor 245 and the conductor 246 function as part of the wiring BL. When the memory device or the like is provided above or below the memory device illustrated in FIG. 24B in this manner, the memory capacity per unit area can be increased.

The memory cell 150a and the memory cell 150b are placed line-symmetrically with the conductor 245 and the conductor 246 therebetween. The transistor 200a and the transistor 200b share the conductor 245 and the conductor 246 functioning as plugs. With the above connection structure between the two transistors and the plugs, a memory device that can be miniaturized or highly integrated can be provided.

Note that the conductor 110 functioning as the wiring PL may be provided in each of the memory cell 150a and the memory cell 150b or may be provided in common to the memory cell 150a and the memory cell 150b. However, as illustrated in FIG. 24B, the conductor 110 is provided to be apart from the conductor 245 so that the conductor 110 and the conductor 245 are not short-circuited.

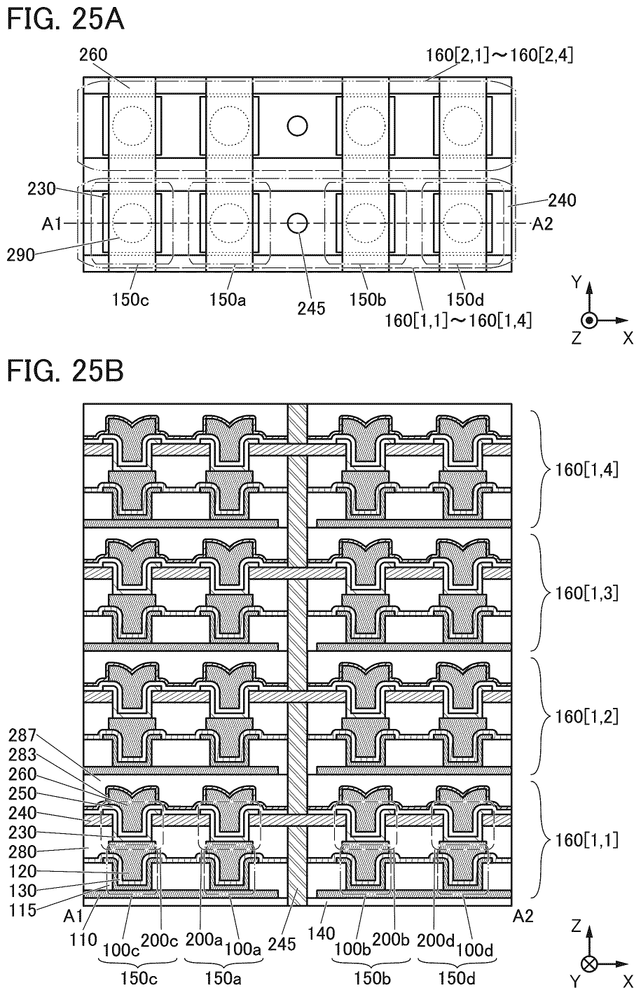

Note that a plurality of memory cells 150 can be three-dimensionally arranged in a matrix to form a memory cell array. As an example of the memory cell array, FIG. 25A and FIG. 25B illustrate an example of a memory device in which 4×2×4 memory cells 150 are arranged in the X direction, the Y direction, and the Z direction. FIG. 25A is a plan view of the memory device. FIG. 25B is a cross-sectional view of a portion indicated by the dashed-dotted line A1-A2 in FIG. 25A. Note that for clarity of the drawing, some components are omitted in the plan view of FIG. 25A.

Here, the memory cell 150a to the memory cell 150d illustrated in FIG. 25A and FIG. 25B each have a structure similar to that of the memory cell 150. The memory cell 150c includes a capacitor 100c and a transistor 200c, and the memory cell 150d includes a capacitor 100d and a transistor 200d.

Hereinafter, a memory device including the memory cell 150a to the memory cell 150d is referred to as a memory unit. FIG. 25A and FIG. 25B illustrate a memory unit 160[1,1] to a memory unit 160[2,4] among the memory units included in the memory device. Hereinafter, in the case where matters common to the memory units are described, “memory unit 160” is used to refer to the memory units in some cases. In the memory unit 160[a,b] (a and b are each a positive integer), a represents an address in the Y direction and b represents an address in the Z direction.

In the memory unit 160, with the conductor 245 as the center, the memory cell 150c is placed outside the memory cell 150a and the memory cell 150d is placed outside the memory cell 150b as illustrated in FIG. 25B. In other words, the memory unit 160 can be regarded as a memory device in which the memory cell 150c is provided adjacent to the memory cell 150a and the memory cell 150d is provided adjacent to the memory cell 150b in the memory device illustrated in FIG. 24A and FIG. 24B.

As illustrated in FIG. 25A and FIG. 25B, the conductor 260 functioning as the wiring WL is shared by the memory cells 150 adjacent to each other in the Y direction. The conductor 240 functioning as part of the wiring BL is shared in the same memory unit. That is, the conductor 240 is in contact with the oxide semiconductor 230 of each of the memory cell 150a to the memory cell 150d.

The conductor 245 is provided between the conductors 240 included in the memory units 160 adjacent to each other in the Z direction. In this manner, the conductor 240 and the conductor 245 provided in each memory unit 160 form the wiring BL. The conductor 245 is electrically connected to a sense amplifier (not illustrated) provided below the memory device illustrated in FIG. 25A and FIG. 25B. As described above, when a plurality of memory units are stacked in the memory device illustrated in FIG. 25A and FIG. 25B, the memory capacity per unit area can be increased.

The memory cells 150a and 150c and the memory cells 150b and 150d are placed line-symmetrically with the conductor 245 therebetween. With the above connection structure between the four transistors and the plug, a memory device that can be miniaturized or highly integrated can be provided.

When a plurality of memory cells are stacked as illustrated in FIG. 25B, cells can be integrally placed without increasing the area occupied by the memory cell array. In other words, a 3D memory cell array can be formed. Note that although four layers each including two memory units are stacked in FIG. 25B, the present invention is not limited thereto. The memory device may include one layer including at least one memory cell 150 or may include two or more stacked layers.

In FIG. 25B, the conductor 245 functioning as a plug is placed between the memory cells 150. In other words, the conductor 245 functioning as a plug is placed inside the memory unit 160. Note that the present invention is not limited thereto. The conductor 245 may be placed outside the memory unit.

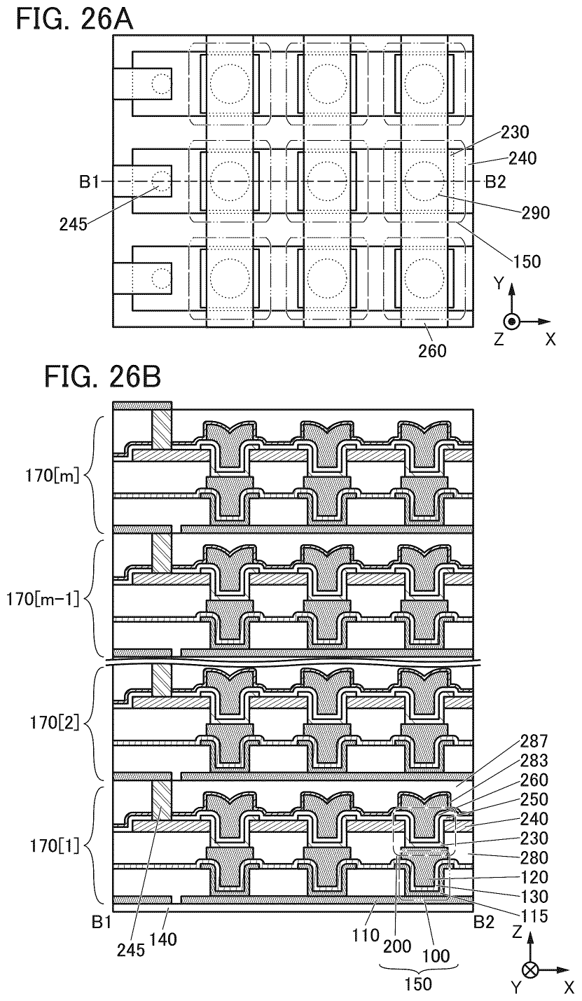

As an example of the memory cell array, FIG. 26A and FIG. 26B illustrate an example of a memory device in which 3×3×4 memory cells 150 are arranged in the X direction, the Y direction, and the Z direction. FIG. 26A is a plan view of the memory device. FIG. 26B is a cross-sectional view of a portion indicated by the dashed-dotted line A1-A2 in FIG. 26A. Note that for clarity of the drawing, some components are omitted in the plan view of FIG. 26A.

The memory device illustrated in FIG. 26A and FIG. 26B has a structure in which m (m is an integer greater than or equal to 2) layers including the memory cells 150 are stacked. Here, FIG. 26B illustrates a layer 170[1] as the first layer (the lowermost layer) and a layer 170[m] as the m-th layer (the uppermost layer). In other words, the memory device of one embodiment of the present invention may include a plurality of layers including memory cells 150 and have a structure in which the plurality of layers are stacked.

As illustrated in FIG. 26A and FIG. 26B, the conductor 245 may be provided outside the memory unit. The conductor 245 may be electrically connected to a wiring provided over the layer including the conductor 245. For example, the conductor 245 provided in the layer 170[1] is electrically connected to a wiring provided in the layer 170[2]. Note that the wiring provided in the layer 170[2] is provided in the same layer as the lower electrode (the conductor 110) of the memory cell 150 included in the layer 170[2]. That is, the wiring can be formed in the same step as the conductor 110.

Note that although the conductor 245 is electrically connected to a wiring provided over the layer including the conductor 245 in FIG. 26B, the present invention is not limited thereto. For example, the conductor 245 may be electrically connected to a wiring provided in the layer including the conductor 245. For example, the conductor 245 provided in the layer 170[1] may be electrically connected to a wiring provided in the layer 170[1]. Note that the wiring provided in the layer 170[1] is provided in the same layer as the lower electrode (the conductor 110) of the memory cell 150 included in the layer 170[1]. That is, the wiring can be formed in the same step as the conductor 110.

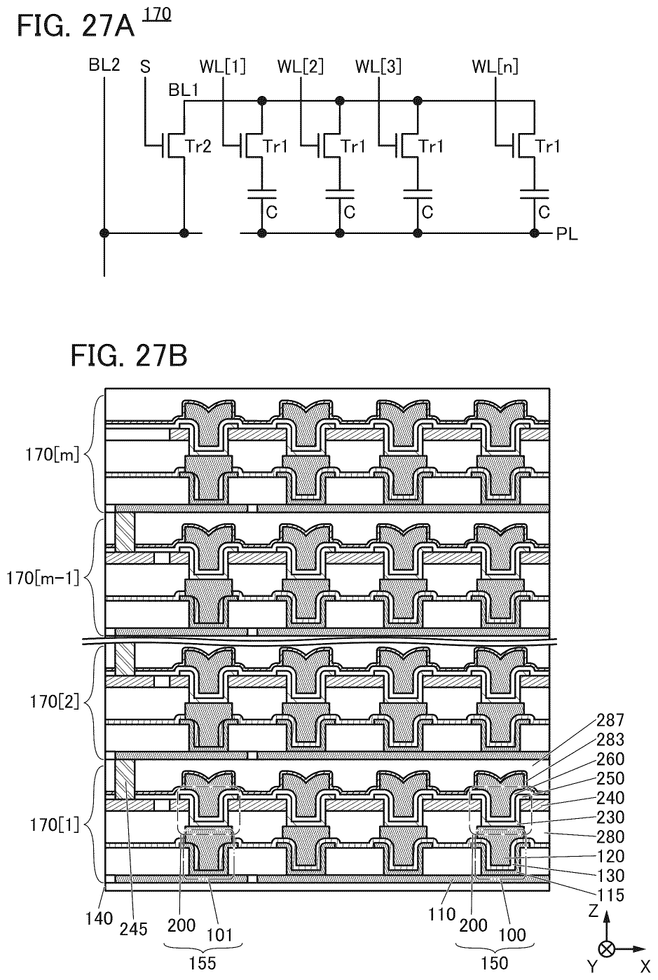

FIG. 27A and FIG. 27B each illustrate an example of the case where the functional element 155 functioning as a selector circuit, which is a peripheral circuit, is provided. Here, one functional element 155 is provided in each layer 170. FIG. 27A is a circuit diagram corresponding to one layer 170.

A transistor Tr1 corresponds to the transistor 200 included in the memory cell 150, and a capacitor C corresponds to the capacitor 100. The transistor Tr2 corresponds to the functional element 155 and the transistor 200 included in the functional element 155.

Wirings WL functioning as word lines are connected to the respective gates of the transistors Tr1. Here, an example in which any one of WL[1] to WL[n] (n is a positive integer) is connected to the transistor Tr1 is illustrated. One of a source electrode and a drain electrode of the transistor Tr1 is connected to the capacitor C, and the other is connected to a wiring BL1. The wiring BL1 functions as a first bit line and corresponds to the conductor 240.

A gate of the transistor Tr2 is connected to a wiring S functioning as a selection signal line, one of a source electrode and a drain electrode of the transistor Tr2 is connected to the wiring BL1, and the other is connected to a wiring BL2. The wiring BL2 functions as a second bit line and is electrically connected to a sense amplifier (not illustrated) provided below the memory device in FIG. 27B, for example.

The transistor Tr2 is controlled by a signal supplied to the wiring S and functions as a switch for controlling conduction and non-conduction between the first bit line and the second bit line. The second bit line is electrically connected to the first bit lines included in all the stacked layers 170 through the transistors Tr2.

With such a structure, in the case where access (reading, writing, or refresh) is made to one of the layers 170, the first bit line in the one layer 170 and the second bit line are brought into conduction and the first bit lines in the other layers 170 and the second bit line are brought into non-conduction, whereby the load on the second bit line can be significantly reduced. Thus, the time required for access can be significantly shortened.

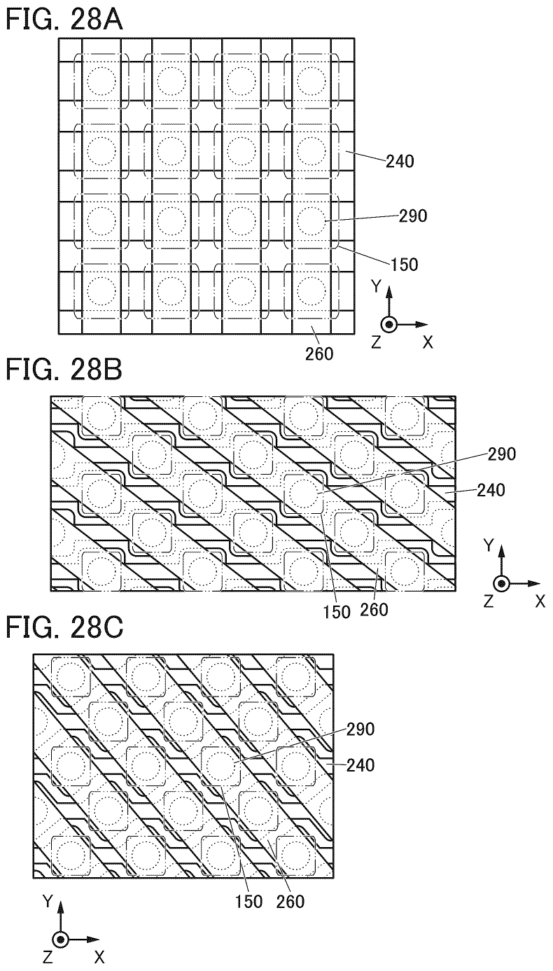

Next, another example of a planar layout is described. First, FIG. 28A illustrates a planar layout of the memory device corresponding to FIG. 26A. FIG. 28A illustrates a region including 4×4 memory cells 150. The conductor 260 functioning as the wiring WL, the conductor 240 functioning as the wiring BL, and the opening portion 290 are also illustrated. The memory cell 150 is provided in a region where the conductor 260, the conductor 240, and the opening portion 290 overlap (intersect) with each other.

In FIG. 28A, the memory cells 150 are arranged at intersection points of orthogonal lattices. The conductor 260 extends in the Y direction and the conductor 240 extends in the X direction. The distance between two adjacent memory cells 150 is equal in the X direction and in the Y direction. In addition, the width of the conductor 260 in the X direction is uniform, and the width of the conductor 240 in the Y direction is uniform. Note that the present invention is not limited thereto.

FIG. 28B is another example of a planar layout of the memory device. In the planar layout of FIG. 28B, the conductor 260, the conductor 240, the memory cell 150, and the opening portion 290 are illustrated as in FIG. 28A. The memory device illustrated in FIG. 28B is different from the memory device illustrated in FIG. 28A mainly in the arrangement of the memory cells 150 (the opening portions 290), the shape of the conductor 240, and the direction in which the conductor 260 extends.

As illustrated in FIG. 28B, the memory cells 150 (the opening portions 290) may be arranged in a zigzag pattern in the Y direction. In FIG. 28B, a memory cell adjacent to a first memory cell in the X direction is referred to as a second memory cell, and a memory cell adjacent to the first memory cell and the second memory cell in the Y direction is referred to as a third memory cell. For example, it is preferable that the center of the third memory cell be located on a straight line that passes midway between the first memory cell and the second memory cell and is parallel to the Y direction. In that case, the third memory cell can be regarded as being located at a position shifted by half in the X direction from the first memory cell and the second memory cell.

As illustrated in FIG. 28B, the conductor 240 includes a first region with a large width in the X direction and a second region with a small width in the X direction. The first region is the opening portion 290 and a region in the vicinity thereof. In the plan view, the first region can be regarded as having a quadrangular shape with rounded corners. The second region is a region between the opening portions 290 adjacent to each other in one conductor 240. Such a structure enables the physical distance between the conductors 240 to be reduced in the case where the memory cells 150 (the opening portions 290) are arranged in a zigzag pattern in the Y direction. Accordingly, miniaturization and higher integration of the memory device can be achieved.

In FIG. 28B, the extending direction of the conductor 260 is inclined with respect to the Y direction. That is, the extending direction of the conductor 260 is not orthogonal to the extending direction of the conductor 240 depending on the arrangement of the memory cells 150 (the opening portions 290).

FIG. 28C is another example of a planar layout of the memory device. The memory device illustrated in FIG. 28C is different from the memory device illustrated in FIG. 28B mainly in the shape of the first region of the conductor 240.

The first region of the conductor 240 illustrated in FIG. 28B has a quadrangular shape with rounded corners in the plan view, and one side of the quadrangle is parallel to the X direction or the Y direction. By contrast, the first region of the conductor 240 illustrated in FIG. 28C has a quadrangular shape with rounded corners in the plan view, and the diagonal of the quadrangle is parallel to the X direction or the Y direction. Such a structure enables the physical distance between the conductors 240 to be reduced in the case where the memory cells 150 (the opening portions 290) are arranged in a zigzag pattern in the Y direction. Accordingly, miniaturization and higher integration of the memory device can be achieved.

Although FIG. 28B and FIG. 28C each illustrate the example in which the first region of the conductor 240 has a quadrangular shape with rounded corners in the plan view, the present invention is not limited thereto.

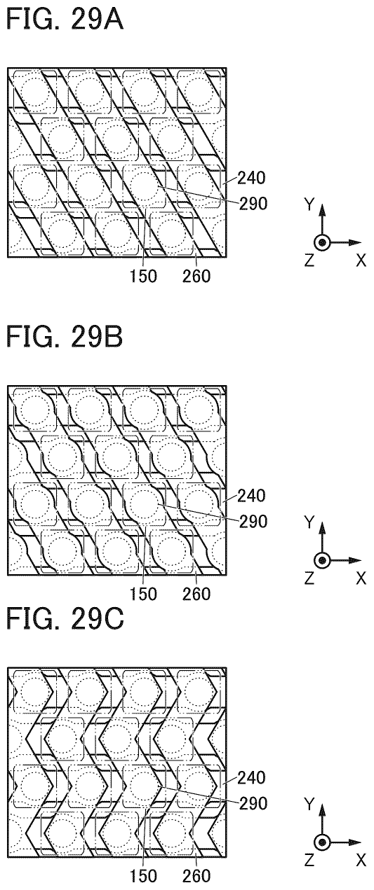

FIG. 29A is another example of a planar layout of the memory device. The memory device illustrated in FIG. 29A is different from the memory devices illustrated in FIG. 28B and FIG. 28C mainly in the shape of the first region of the conductor 240.

The first region of the conductor 240 illustrated in FIG. 29B has a circular shape in the plan view. Such a structure enables the physical distance between the conductors 240 to be reduced in the case where the memory cells 150 (the opening portions 290) are arranged in a zigzag pattern in the Y direction. Accordingly, miniaturization and higher integration of the memory device can be achieved.

Note that the shape of the first region of the conductor 240 in the plan view is not limited to the above-described shapes. For example, the first region of the conductor 240 in the plan view may have an almost circular shape such as an ellipse, a polygonal shape such as a quadrangle, or a polygonal shape, such as a quadrangle, with rounded corners.

Although the width of the conductor 260 is uniform in the direction perpendicular to the extending direction of the conductor 260 in FIG. 28A, the present invention is not limited thereto.

FIG. 29B is another example of a planar layout of the memory device. The memory device illustrated in FIG. 29B is different from the memory device illustrated in FIG. 29A mainly in the shape of the conductor 260.

Like the conductor 240, the conductor 260 illustrated in FIG. 29B includes a first region and a second region. The first region has a circular shape in the plan view. Note that the first region of the conductor 260 overlaps with the first region of the conductor 240. Such a structure enables the physical distance between the conductors 240 to be reduced in the case where the memory cells 150 (the opening portions 290) are arranged in a zigzag pattern in the Y direction. Accordingly, miniaturization and higher integration of the memory device can be achieved.

FIG. 29C is another example of a planar layout of the memory device. The memory device illustrated in FIG. 29C is different from the memory device illustrated in FIG. 29A mainly in the shape and extending direction of the conductor 260.

The conductor 260 illustrated in FIG. 29C has a meandering shape like a triangle wave in the plan view and is provided to extend in the Y direction. Such a structure enables the physical distance between the conductors 240 to be reduced in the case where the memory cells 150 (the opening portions 290) are arranged in a zigzag pattern in the Y direction. Accordingly, miniaturization and higher integration of the memory device can be achieved. Note that the shape of the conductor 260 in the plan view is not limited to the above shape and may have a meander shape or the like.

With the above-described structures, one or both of the physical distance between the conductors 260 and the physical distance between the conductors 240 can be reduced, so that miniaturization and higher integration of the memory device can be achieved.

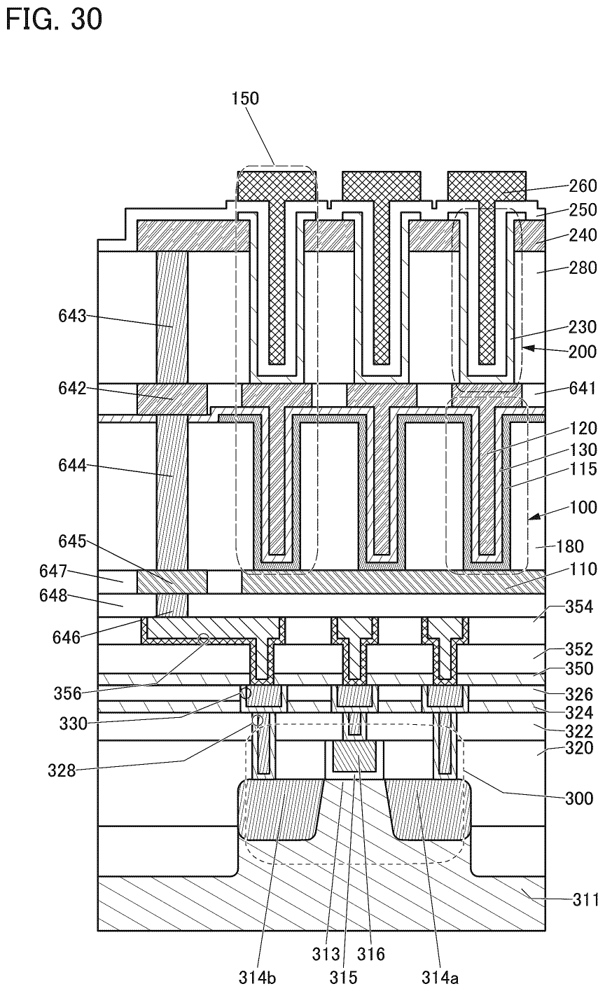

FIG. 30 illustrates a cross-sectional structure example of a memory device in which a layer including a memory cell is stacked over a layer including a driver circuit provided with a sense amplifier.

In FIG. 30, the capacitor 100 is provided above a transistor 300, and the transistor 200 is provided above the transistor 300 and the capacitor 100. The transistor 300 is one of the transistors included in the sense amplifier.

The structure of the memory cell 150 (the transistor 200 and the capacitor 100) illustrated in FIG. 30 is as described above.

When the sense amplifier is provided to overlap with the memory cell 150 as illustrated in FIG. 30, the bit line can be shortened. This reduces bit line capacitance, which can reduce the storage capacitance of the memory cell.

When the transistor 200 is provided above the capacitor 100, the transistor 200 is not affected by thermal budget in manufacturing the capacitor 100. Thus, in the transistor 200, degradation of the electrical characteristics such as variation in threshold voltage and an increase in parasitic resistance, and an increase in variation in electrical characteristics due to the degradation of the electrical characteristics can be inhibited.

The memory device illustrated in FIG. 30 can correspond to a memory device 80 to be described later. Specifically, the transistor 300 corresponds to a transistor included in a sense amplifier 46 in the memory device 80. The memory cell 150 corresponds to a memory cell 32, the transistor 200 corresponds to a transistor 37, and the capacitor 100 corresponds to a capacitor 38.

The transistor 300 is provided on a substrate 311 and includes a conductor 316 functioning as a gate, an insulator 315 functioning as a gate insulator, a semiconductor region 313 formed of part of the substrate 311, and a low-resistance region 314a and a low-resistance region 314b functioning as a source region and a drain region. The transistor 300 may be either a p-channel transistor or an n-channel transistor.

Here, in the transistor 300 illustrated in FIG. 30, the semiconductor region 313 (part of the substrate 311) in which a channel is formed has a protruding shape. Furthermore, the conductor 316 is provided to cover the side and top surfaces of the semiconductor region 313 with the insulator 315 therebetween. Note that the conductor 316 may be formed using a material for adjusting the work function. The transistor 300 having such a structure is also referred to as a FIN-type transistor because it utilizes the protruding portion of the semiconductor substrate. Note that an insulator functioning as a mask for forming the protruding portion may be provided in contact with the upper portion of the protruding portion. Although the case where the protruding portion is formed by processing part of the semiconductor substrate is described here, a semiconductor film having a protruding shape may be formed by processing an SOI substrate.

Note that the transistor 300 illustrated in FIG. 30 is an example and is not limited to the structure; an appropriate transistor can be used in accordance with a circuit structure or a driving method.

A wiring layer provided with an interlayer film, a wiring, a plug, and the like may be provided between the components. A plurality of wiring layers can be provided in accordance with the design. Here, a plurality of conductors functioning as a plug or a wiring are collectively denoted by the same reference numeral in some cases. Furthermore, in this specification and the like, a wiring and a plug electrically connected to the wiring may be a single component. That is, in some cases, part of a conductor serves as a wiring or part of a conductor functions as a plug.

For example, an insulator 320, an insulator 322, an insulator 324, and an insulator 326 are stacked in this order over the transistor 300 as an interlayer film. A conductor 328 is embedded in the insulator 320 and the insulator 322, and a conductor 330 is embedded in the insulator 324 and the insulator 326. Note that the conductor 328 and the conductor 330 function as a plug or a wiring.

The insulator functioning as an interlayer film may function as a planarization film that covers an uneven shape thereunder. For example, the top surface of the insulator 322 may be planarized through planarization treatment using a CMP method or the like to increase the level of planarity.

A wiring layer may be provided over the insulator 326 and the conductor 330. For example, in FIG. 30, an insulator 350, an insulator 352, and an insulator 354 are stacked in this order. Furthermore, a conductor 356 is formed in the insulator 350, the insulator 352, and the insulator 354. The conductor 356 functions as a plug or a wiring.

As the insulator 352, the insulator 354, and the like functioning as interlayer films, the above-described insulator that can be used in the memory device can be used.

As the conductor functioning as a plug or a wiring, such as the conductor 328, the conductor 330, and the conductor 356, any of the above-described conductors can be used. It is preferable to use a high-melting-point material that has both heat resistance and conductivity, such as tungsten or molybdenum, and it is preferable to use tungsten. Alternatively, it is preferable to form the conductors with a low-resistance conductive material such as aluminum or copper. The use of a low-resistance conductive material can reduce wiring resistance.

The conductor 240 included in the transistor 200 is electrically connected to the low-resistance region 314b functioning as the source region or the drain region of the transistor 300 through a conductor 643, a conductor 642, a conductor 644, a conductor 645, a conductor 646, the conductor 356, the conductor 330, and the conductor 328.

The conductor 643 is embedded in the insulator 280. The conductor 642 is provided over the insulator 130 and is embedded in an insulator 641. The conductor 642 can be formed using the same material in the same step as the conductor 120. The conductor 644 is embedded in the insulator 180 and the insulator 130. The conductor 645 is embedded in an insulator 647. The conductor 645 can be formed using the same material in the same step as the conductor 110. The conductor 646 is embedded in an insulator 648. The transistor 300 and the conductor 110 are electrically insulated from each other by the insulator 648.

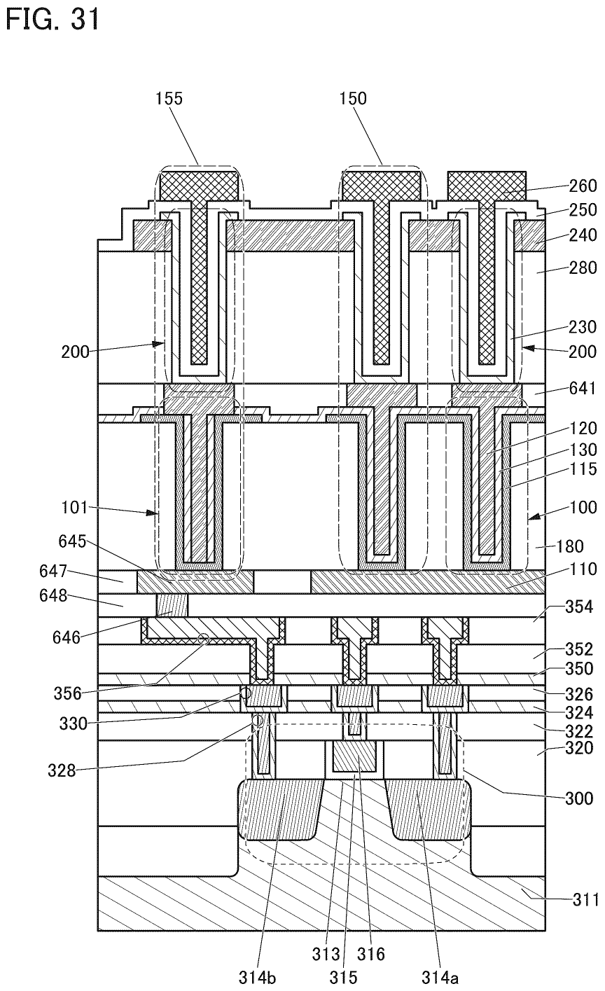

FIG. 31 illustrates an example of the case where the functional element 155 functioning as a peripheral circuit is provided instead of the conductor 642, the conductor 643, and the conductor 644 in FIG. 30. Specifically, the transistor 200 included in the functional element 155 functions as a switch for controlling conduction and non-conduction between the conductor 240 functioning as a bit line and the conductor 645 electrically connected to one of the source and the drain of the transistor 300.

According to one embodiment of the present invention, a novel transistor, a novel semiconductor device, and a novel memory device can be provided. Alternatively, a transistor, a semiconductor device, and a memory device that can be miniaturized or highly integrated can be provided. Alternatively, a transistor, a semiconductor device, and a memory device that are highly reliable can be provided. Alternatively, a transistor that has a high on-state current and a semiconductor device and a memory device that include the transistor can be provided. Alternatively, a semiconductor device and a memory device with a small variation in transistor characteristics can be provided. Alternatively, a transistor with favorable electrical characteristics and a semiconductor device and a memory device including the transistor can be provided. Alternatively, a semiconductor device and a memory device with low power consumption can be provided. Alternatively, a memory device with favorable frequency characteristics can be provided. Alternatively, a memory device with a high operation speed can be provided.

At least part of this embodiment can be implemented in combination with the other embodiments described in this specification as appropriate.

### Embodiment 2

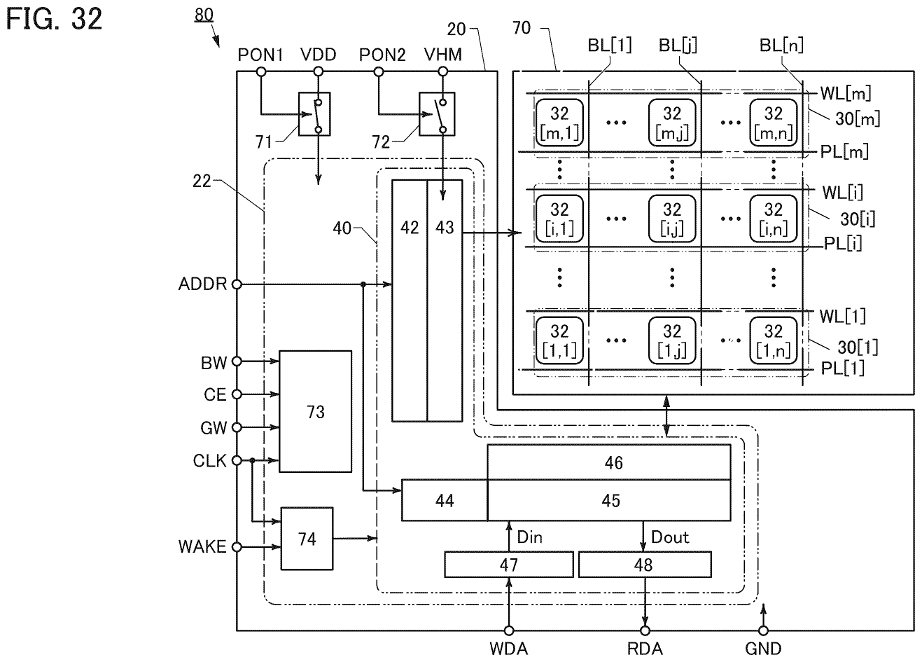

In this embodiment, a memory device of one embodiment of the present invention will be described with reference to FIG. 32 to FIG. 35. In this embodiment, a structure example of a memory device in which a layer including a memory cell is stacked over a layer including a driver circuit provided with a sense amplifier will be described.

### <Structure Example of Memory Device>

FIG. 32 is a block diagram illustrating a structure example of the memory device 80 of one embodiment of the present invention. The memory device 80 illustrated in FIG. 32 includes a layer 20 and a layer 70 stacked thereover.

The layer 20 is a layer including a Si transistor. In the stacked layer 70, element layers 30[1] to 30[m] (m is an integer greater than or equal to 2) are stacked. The element layers 30[1] to 30[m] each include an OS transistor. The layer 70 provided with the stacked layers including the OS transistors can be stacked over the layer 20.

Elements such as OS transistors and capacitors included in the element layers 30[1] to 30[m] form memory cells. FIG. 32 illustrates an example in which the element layers 30[1] to 30[m] include a plurality of the memory cells 32 arranged in a matrix of m rows and n columns (n is an integer greater than or equal to 2).

In FIG. 32, the memory cell 32 in the first row and the first column is denoted as a memory cell 32[1,1], and the memory cell 32 in the m-th row and the n-th column is denoted as a memory cell 32[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 32 in the i-th row and the j-th column is denoted as a memory cell 32[i,j]. Note that in this embodiment and the like, “i+a” (a is a positive or negative integer) is not below 1 and does not exceed m. Similarly, “j+a” is not below 1 and does not exceed n.

FIG. 32 illustrates, as an example, m wirings WL extending in the row direction, m wirings PL extending in the row direction, and n wirings BL extending in the column direction. In this embodiment and the like, a first wiring WL (provided in the first row) is denoted as a wiring WL[1], and an m-th wiring WL (provided in the m-th row) is denoted as a wiring WL[m]. Similarly, a first wiring PL (provided in the first row) is denoted as a wiring PL[1], and an m-th wiring PL (provided in the m-th row) is denoted as a wiring PL[m]. Similarly, a first wiring BL (provided in the first column) is denoted as a wiring BL[1], and an n-th wiring BL (provided in the n-th column) is denoted as a wiring BL[n]. Note that the number of the element layers 30[1] to 30[m] is not necessarily the same as the number of the wirings WL (and the wirings PL).

The plurality of memory cells 32 provided in the i-th row are electrically connected to the wiring WL in the i-th row (wiring WL[i]) and the wiring PL in the i-th row (wiring PL[i]). The plurality of memory cells 32 provided in the j-th column are electrically connected to the wiring BL in the j-th column (wiring BL[j]).

The wiring BL functions as a bit line for writing and reading data. The wiring WL functions as a word line for controlling the on and off states (conduction and non-conduction states) of the access transistor serving as a switch. The wiring PL has a function of a constant potential line connected to a capacitor. Note that a wiring CL (not illustrated) can be separately provided as a wiring for transmitting the back gate potential.

The memory cells 32 included in each of the element layers 30[1] to 30[m] are connected to the sense amplifier 46 through the wiring BL. The wiring BL can be provided horizontally and perpendicularly to the surface of the substrate where the layer 20 is provided. When the wiring BL extending from the memory cells 32 included in the element layers 30[1] to 30[m] is formed using a wiring provided perpendicularly to the substrate surface as well as a wiring provided horizontally to the substrate surface, the length of the wiring between the element layers 30 and the sense amplifier 46 can be shortened. The signal transmission distance between the memory cell and the sense amplifier can be shortened and the resistance and parasitic capacitance of the bit line can be significantly reduced, so that power consumption and signal delays can be reduced. Thus, power consumption and signal delay of the memory device 80 can be reduced. Moreover, operation is possible even when the capacitance of the capacitors included in the memory cells 32 is reduced. Thus, the memory device 80 can be downsized.

The layer 20 includes a PSW 71 (power switch), a PSW 72, and a peripheral circuit 22. The peripheral circuit 22 includes a driver circuit 40, a control circuit 73, and a voltage generation circuit 74. Note that each circuit included in the layer 20 is a circuit including a Si transistor.

In the memory device 80, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 73.

The control circuit 73 is a logic circuit having a function of controlling the entire operation of the memory device 80. For example, the control circuit performs a logical operation on the signal CE, the signal GW, and the signal BW to determine an operation mode (e.g., a writing operation or a reading operation) of the memory device 80. Alternatively, the control circuit 73 generates a control signal for the driver circuit 40 so that the operation mode is executed.

The voltage generation circuit 74 has a function of generating a negative voltage. The signal WAKE has a function of controlling the input of the signal CLK to the voltage generation circuit 74. For example, when an H-level signal is supplied as the signal WAKE, the signal CLK is input to the voltage generation circuit 74, and the voltage generation circuit 74 generates a negative voltage.

The driver circuit 40 is a circuit for writing and reading data to/from the memory cells 32. The driver circuit 40 includes the above-described sense amplifier 46 in addition to a row decoder 42, a column decoder 44, a row driver 43, a column driver 45, an input circuit 47, and an output circuit 48.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring WL specified by the row decoder 42. The column driver 45 has a function of writing data to the memory cells 32, a function of reading data from the memory cells 32, a function of retaining the read data, and the like.

The input circuit 47 has a function of retaining the signal WDA. Data retained by the input circuit 47 is output to the column driver 45. Data output from the input circuit 47 is data (Din) to be written to the memory cells 32. Data (Dout) read from the memory cells 32 by the column driver 45 is output to the output circuit 48. The output circuit 48 has a function of retaining Dout. In addition, the output circuit 48 has a function of outputting Dout to the outside of the memory device 80. Data output from the output circuit 48 is the signal RDA.

The PSW 71 has a function of controlling the supply of VDD to the peripheral circuit 22. The PSW 72 has a function of controlling the supply of VHM to the row driver 43. Here, in the memory device 80, a high power supply voltage is VDD and a low power supply voltage is GND (a ground potential). In addition, VHM is a high power supply voltage used to set the word line at high level and is higher than VDD. The on/off state of the PSW 71 is controlled by the signal PON1, and the on/off state of the PSW 72 is controlled by the signal PON2. The number of power domains to which VDD is supplied is one in the peripheral circuit 22 in FIG. 32 but can be more than one. In such a case, a power switch is provided for each power domain.

Note that the selector circuit described as an example in Embodiment 1 can be provided in the layer 70. Accordingly, the load on the bit line can be reduced, so that a memory device with extremely high operation speed (writing speed and reading speed) can be achieved.

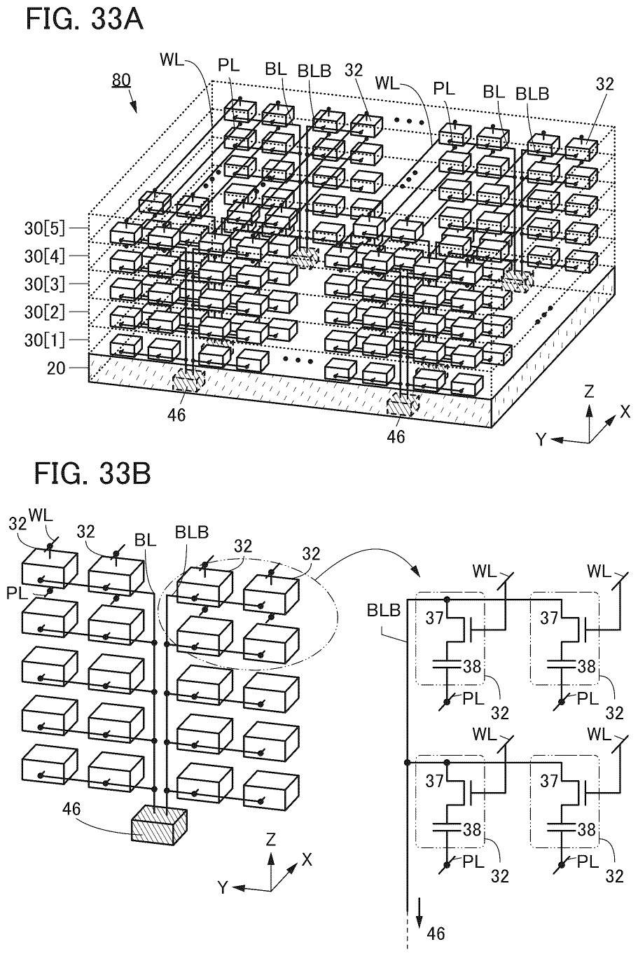

The element layers 30[1] to 30[m] can be provided over the layer 20 to overlap therewith. FIG. 33A is a perspective view of the memory device 80 in which five (m=5) element layers 30[1] to 30[5] are provided over the layer 20 to overlap therewith.

In FIG. 33A, the element layer 30 provided in the first layer is denoted as the element layer 30[1], the element layer 30 provided in the second layer is denoted as the element layer 30[2], and the element layer 30 provided in the fifth layer is denoted as the element layer 30[5]. FIG. 33A also illustrates the wiring WL and the wiring PL extending in the X direction and the wiring BL and the wiring BLB extending in the Y direction and the Z direction (the direction perpendicular to the surface of the substrate where the driver circuit is provided). The wiring BLB is an inverted bit line. For easy viewing of the drawing, some of the wirings WL and the wirings PL included in the element layers 30 are not illustrated.

FIG. 33B is a schematic view illustrating a structure example of the sense amplifier 46, which is connected to the wiring BL and the wiring BLB, and the memory cells 32 included in the element layers 30[1] to 30[5], which are connected to the wiring BL and the wiring BLB, illustrated in FIG. 33A. Note that a structure in which a plurality of memory cells (memory cells 32) are electrically connected to one wiring BL and one wiring BLB is also referred to as “memory string”.

FIG. 33B illustrates an example of a circuit structure of the memory cell 32 connected to the wiring BLB. The memory cell 32 includes the transistor 37 and the capacitor 38. As for the transistor 37, the capacitor 38, and the wirings (e.g., BL and WL), for example, the wiring BL[1] and the wiring WL[1] are referred to as the wiring BL and the wiring WL in some cases. The memory cell 150 described as an example in the above embodiment can be used as the memory cell 32, for example. In other words, the transistor 200 can be used as the transistor 37, and the capacitor 100 can be used as the capacitor 38. As the transistor included in the sense amplifier 46, the transistor 300 (see FIG. 30) can be used.

In the memory cell 32, one of the source and the drain of the transistor 37 is connected to the wiring BL. The other of the source and the drain of the transistor 37 is connected to one electrode of the capacitor 38. The other electrode of the capacitor 38 is connected to the wiring PL. The gate of the transistor 37 is connected to the wiring WL.

Note that in the case where the selector circuit described as an example in Embodiment 1 is used, the above-described functional element 155 may be connected between the wiring BL and the memory cell 32.

The wiring PL is a wiring for supplying a fixed potential for retaining the potential of the capacitor 38. A plurality of the wirings PL are provided to be connected as one wiring, whereby the number of wirings can be reduced.

In one embodiment of the present invention, the OS transistors are stacked, and the wiring functioning as the bit line is placed in the direction perpendicular to the surface of the substrate where the element layer 20 is provided. In addition, the transistor 37 and the capacitor 38 included in the memory cell 32 are arranged in the direction perpendicular to the surface of the substrate where the layer 20 is provided. When the elements and the wirings are provided in the direction perpendicular to the substrate surface, the length of the wiring between the element layers can be shortened and the density of the elements per unit area can be increased. Thus, the memory device can have high memory capacity and low power consumption.

### [Structure Examples of Memory Cell 32 and Sense Amplifier 46]

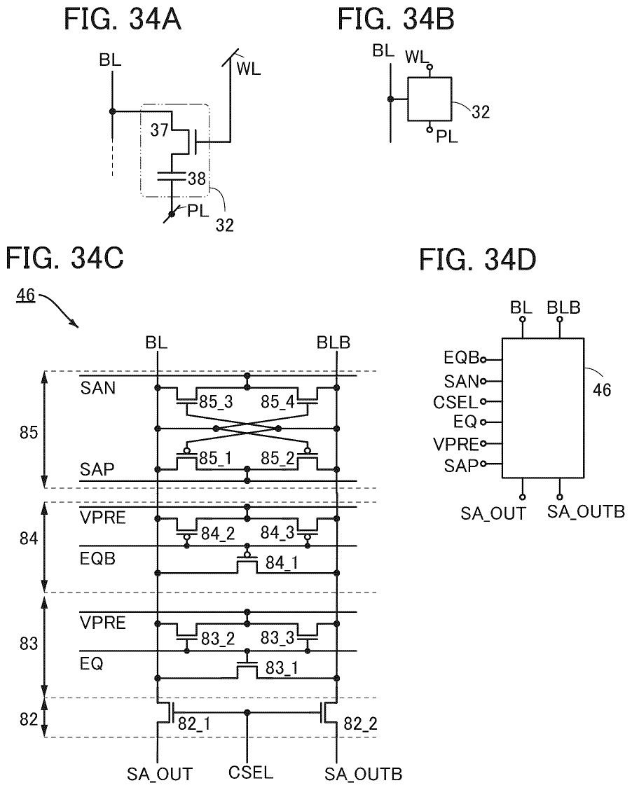

FIG. 34A and FIG. 34B are a circuit diagram corresponding to the above-described memory cell 32 and a diagram illustrating a circuit block corresponding to the circuit diagram. As illustrated in FIG. 34A and FIG. 34B, the memory cell 32 is illustrated as a block in the drawing and the like in some cases. Note that the same can be applied to the case where the wiring BL illustrated in FIG. 34A and FIG. 34B is replaced with the wiring BLB.

FIG. 34C and FIG. 34D are a circuit diagram corresponding to the above-described sense amplifier 46 and a diagram illustrating a circuit block corresponding to the circuit diagram. The sense amplifier 46 includes a switch circuit 82, a precharge circuit 83, a precharge circuit 84, and an amplifier circuit 85. In addition to the wiring BL and the wiring BLB, a wiring SA_OUT and a wiring SA_OUTB that output a read signal are illustrated.

The switch circuit 82 includes, for example, n-channel transistors 82_1 and 82_2, as illustrated in FIG. 34C. The transistors 82_1 and 82_2 switch conduction and non-conduction between the wiring SA_OUT and the wiring BL and between the wiring SA_OUTB and the wiring BLB in response to a signal CSEL; the wiring SA_OUT and the wiring SA_OUTB form a wiring pair and the wiring BL and the wiring BLB form a wiring pair.

The precharge circuit 83 is composed of n-channel transistors 83_1 to 83_3 as illustrated in FIG. 34C. The precharge circuit 83 is a circuit for precharging the wiring BL and the wiring BLB to an intermediate potential VPRE, which corresponds to half of the potential VDD, in response to a signal EQ.

The precharge circuit 84 is composed of p-channel transistors 84_1 to 84_3 as illustrated in FIG. 34C. The precharge circuit 84 is a circuit for precharging the wiring BL and the wiring BLB to the intermediate potential VPRE, which corresponds to half of the potential VDD, in response to a signal EQB.

The amplifier circuit 85 is composed of p-channel transistors 85_1 and 85_2 and n-channel transistors 85_3 and 85_4 that are connected to a wiring SAP or a wiring SAN, as illustrated in FIG. 34C. The wiring SAP or the wiring SAN is a wiring having a function of supplying VDD or VSS. The transistors 85_1 to 85_4 are transistors that form an inverter loop.

FIG. 34D illustrates a circuit block corresponding to the sense amplifier 46 described with reference to FIG. 34C or the like. As illustrated in FIG. 34D, the sense amplifier 46 is illustrated as a block in the drawing and the like in some cases.

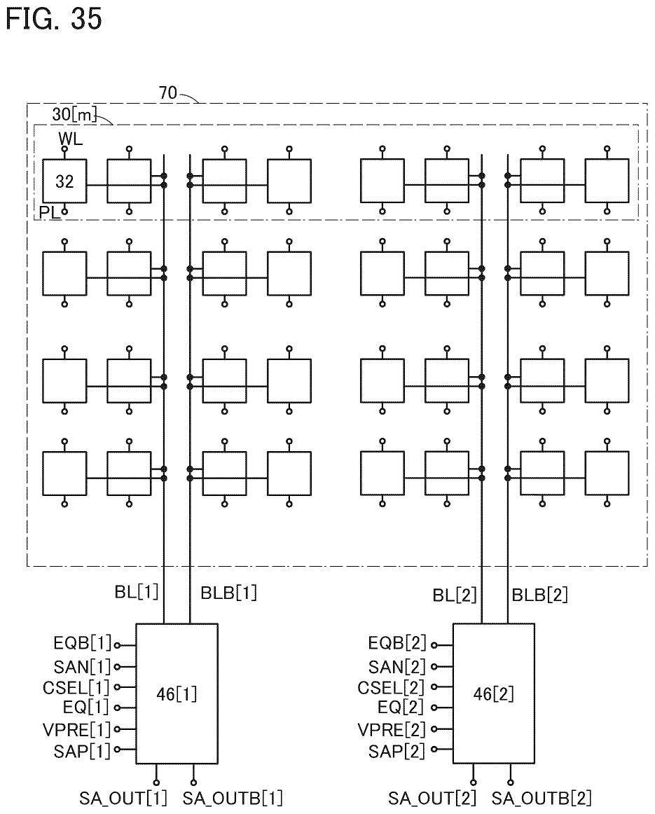

FIG. 35 is a circuit diagram of the memory device 80 in FIG. 32. In FIG. 35, the circuit block illustrated in FIG. 34A to FIG. 34D is used.

As illustrated in FIG. 35, the layer 70 including the element layer 30[m] includes the memory cells 32. The memory cells 32 illustrated in FIG. 35 are connected to a pair of wirings BL[1] and BLB[1] or a pair of wirings BL[2] and BLB[2], for example. The memory cells 32 connected to the wiring BL are memory cells to/from which data is written or read.

The wiring BL[1] and the wiring BLB[1] are connected to a sense amplifier 46[1], and the wiring BL[2] and the wiring BLB[2] are connected to a sense amplifier 46[2]. The sense amplifier 46[1] and the sense amplifier 46[2] can perform data reading in accordance with the various signals described with reference to FIG. 34C.

At least part of this embodiment can be implemented in combination with the other embodiments described in this specification as appropriate.

### Embodiment 3

In this embodiment, application examples of the semiconductor device of one embodiment of the present invention will be described. The semiconductor device of one embodiment of the present invention can be used for an electronic component, an electronic device, a large computer, space equipment, and a data center (also referred to as DC), for example. An electronic component, an electronic device, a large computer, space equipment, and a data center each using the semiconductor device according to one embodiment of the present invention are effective in achieving high performance, e.g., reducing power consumption.

### [Electronic Component]

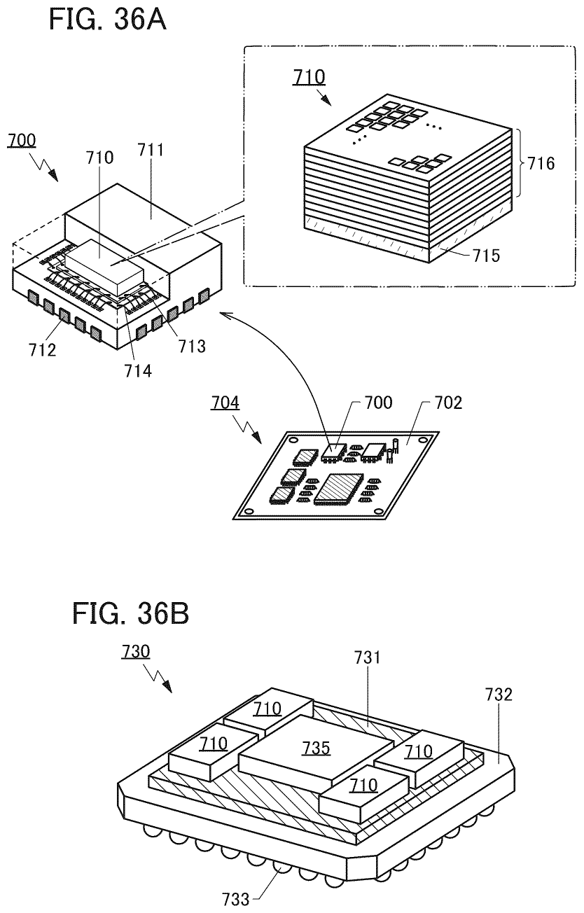

FIG. 36A is a perspective view of a substrate (a mounting board 704) on which an electronic component 700 is mounted. The electronic component 700 illustrated in FIG. 36A includes a semiconductor device 710 in a mold 711. FIG. 36A omits some components to show the inside of the electronic component 700. The electronic component 700 includes a land 712 outside the mold 711. The land 712 is electrically connected to an electrode pad 713, and the electrode pad 713 is electrically connected to the semiconductor device 710 via a wire 714. The electronic component 700 is mounted on a printed circuit board 702, for example. A plurality of such electronic components are combined and electrically connected to each other on the printed circuit board 702, whereby the mounting board 704 is completed.

The semiconductor device 710 includes a driver circuit layer 715 and a memory layer 716. Note that the memory layer 716 has a structure in which a plurality of memory cell arrays are stacked. A stacked-layer structure of the driver circuit layer 715 and the storage layer 716 can be a monolithic stacked-layer structure. In the monolithic stacked-layer structure, layers can be connected to each other without using a through electrode technique such as a TSV (Through Silicon Via) and a bonding technique such as Cu—Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. Note that in the case where the memory layer 716 is formed using Si transistors, the monolithic stacked-layer structure is difficult to form compared with the case where the memory layer 716 is formed using OS transistors. Thus, the OS transistor is superior to the Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Note that examples of semiconductor materials that can be used for the die include silicon (Si), silicon carbide (SiC), and gallium nitride (GaN). A die obtained from a silicon substrate (also referred to as a silicon wafer) may be referred to as a silicon die, for example.

Next, FIG. 36B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings have a single-layer structure or a layered structure. In addition, the interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer, a TSV, and the like, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using a TSV and monolithically stacked memory cell arrays may be employed.

A heat sink (a radiator plate) may be provided to overlap with the electronic component 730. In the case of providing a heat sink, the heights of integrated circuits provided on the interposer 731 are preferably equal to each other. In the electronic component 730 of this embodiment, the heights of the semiconductor device 710 and the semiconductor device 735 are preferably equal to each other, for example.

An electrode 733 may be provided on the bottom portion of the package substrate 732 to mount the electronic component 730 on another substrate. FIG. 36B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### [Electronic Device]

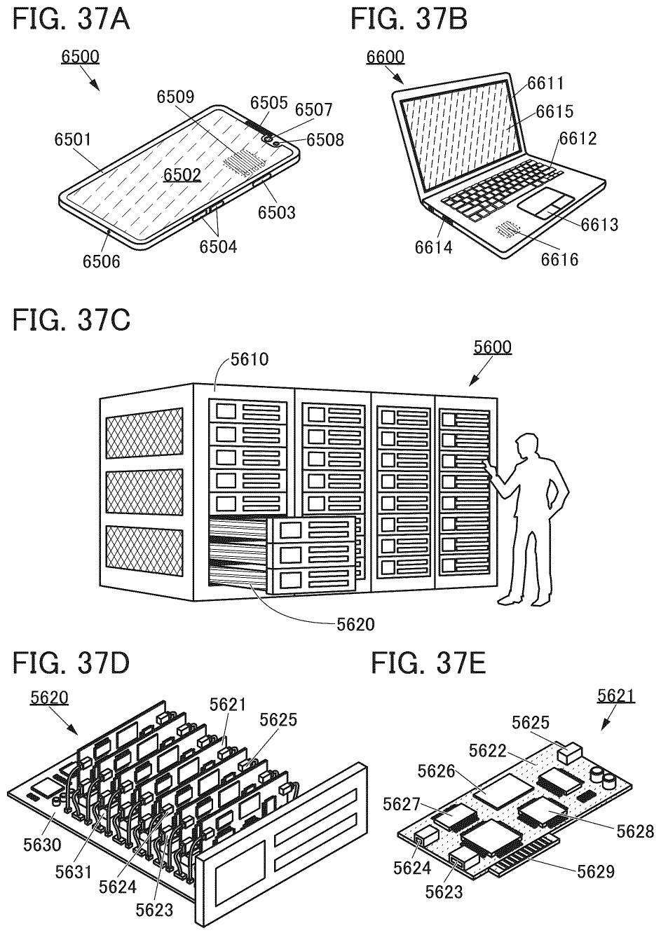

Next, FIG. 37A is a perspective view of an electronic device 6500. The electronic device 6500 illustrated in FIG. 37A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that as the control device 6509, for example, one or more selected from a CPU, a GPU, and a memory device are included. The semiconductor device of one embodiment of the present invention can be used for the display portion 6502, the control device 6509, and the like.

An electronic device 6600 illustrated in FIG. 37B is an information terminal that can be used as a notebook personal computer. The electronic device 6600 includes a housing 6611, a keyboard 6612, a pointing device 6613, an external connection port 6614, a display portion 6615, a control device 6616, and the like. Note that as the control device 6616, for example, one or more selected from a CPU, a GPU, and a memory device are included. The semiconductor device of one embodiment of the present invention can be used for the display portion 6615, the control device 6616, and the like. Note that the semiconductor device of one embodiment of the present invention is preferably used for the above-described control device 6509 and control device 6616, in which case power consumption can be reduced.

### [Large Computer]

Next, FIG. 37C is a perspective view of a large computer 5600. In the large computer 5600 illustrated in FIG. 37C, a plurality of rack mount computers 5620 are stored in a rack 5610. Note that the large computer 5600 may be referred to as a supercomputer. Note that the large computer 5600 may be referred to as a supercomputer.

The computer 5620 can have a structure in a perspective view of FIG. 37D, for example. In FIG. 37D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 37E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 37E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark) or the like.

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device or the like. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment.

The semiconductor device of one embodiment of the present invention includes an OS transistor. A change in electrical characteristics of the OS transistor due to exposure to radiation is small. That is, the OS transistor is highly resistant to radiation, and thus can be suitably used in an environment where radiation can enter. For example, the OS transistor can be suitably used in outer space. Specifically, the OS transistor can be used as a transistor included in a semiconductor device provided in a space shuttle, an artificial satellite, or a space probe. Examples of radiation include X-rays and a neutron beam. Note that outer space refers to, for example, space at an altitude greater than or equal to 100 km, and outer space in this specification may also include one or more of the thermosphere, mesosphere, and stratosphere.

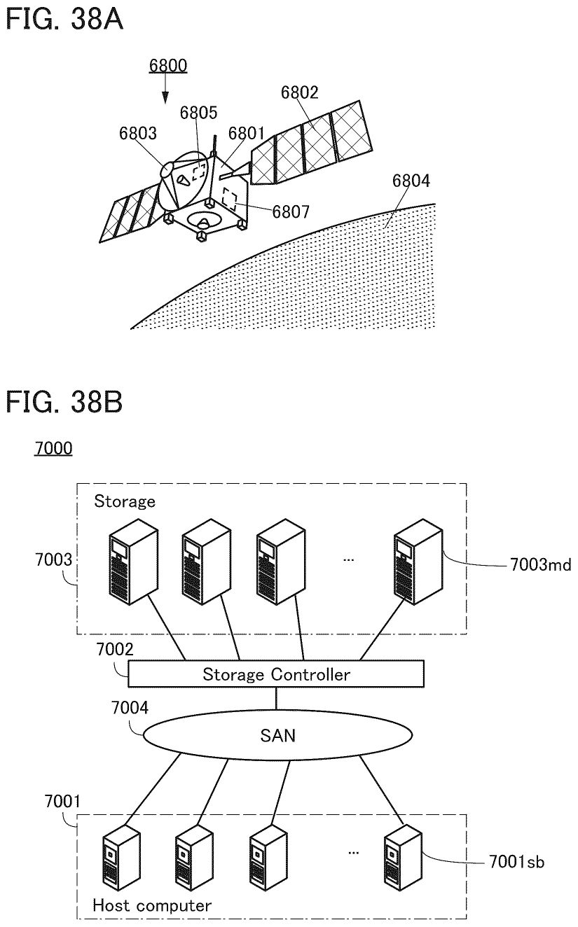

FIG. 38A illustrates an artificial satellite 6800 as an example of space equipment. The artificial satellite 6800 includes a body 6801, a solar panel 6802, an antenna 6803, a secondary battery 6805, and a control device 6807. FIG. 38A illustrates a planet 6804 in outer space as an example.

Although not illustrated in FIG. 38A, a battery management system (also referred to as BMS) or a battery control circuit may be provided in the secondary battery 6805. The battery management system or the battery control circuit preferably includes an OS transistor, in which case low power consumption and high reliability are achieved even in outer space.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used in the control device 6807. A change in electrical characteristics due to exposure to radiation is smaller in the OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for, for example, a storage system in a data center or the like. The data center is required to perform long-term management of data such as guarantee of data immutability. The long-term management of data needs an increase in building size for, for example, setting a storage and a server for storing an enormous amount of data, ensuring stable power supply for data retention, and ensuring cooling equipment for data retention.

With use of the semiconductor device of one embodiment of the present invention for a storage system in a data center, electric power used for retaining data can be reduced and a semiconductor device for retaining data can be reduced in size. Accordingly, reductions in sizes of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention can achieve a data center that operates stably even in a high temperature environment. Thus, the reliability of the data center can be improved.

FIG. 38B illustrates a storage system that can be used in a data center. A storage system 7000 illustrated in FIG. 38B includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated mode, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the time required for a DRAM that can be used as a cache memory in the storage. In the storage system, in order to solve the problem of low access speed of the storage 7003, a cache memory is normally provided in the storage to shorten the time taken for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downscaling is possible by stacking memory cell arrays.

The use of the semiconductor device of one embodiment of the present invention for one or more selected from an electronic component, an electronic device, a large computer, space equipment, and a data center can be expected to produce an effect of reducing power consumption. Although demand for energy will increase with increasing performance and integration degree of semiconductor devices, the use of the semiconductor device of one embodiment of the present invention can thus reduce the emission amount of greenhouse gas typified by carbon dioxide (CO₂). Furthermore, the semiconductor device of one embodiment of the present invention has low power consumption and thus is effective as a global warming countermeasure.

At least part of this embodiment can be implemented in combination with the other embodiments described in this specification as appropriate.

### REFERENCE NUMERALS

100: capacitor, 101: connection portion, 110: conductor, 115: conductor, 120A: conductive film, 120: conductor, 125: conductor, 130: insulator, 131: insulator, 135: insulator, 140: insulator, 145: resist mask, 146: opening, 150a: memory cell, 150b: memory cell, 150c: memory cell, 150d: memory cell, 150: memory cell, 155: functional element, 160: memory unit, 170: layer, 180a: insulator, 180b: insulator, 180: insulator, 182: insulator, 185: insulator, 190: opening portion, 200a: transistor, 200b: transistor, 200: transistor, 230a: oxide semiconductor, 230b: oxide semiconductor, 230i: region, 230na: region, 230nb: region, 230: oxide semiconductor, 240A: conductive film, 240: conductor, 245: conductor, 246: conductor, 250a: insulator, 250b: insulator, 250c: insulator, 250: insulator, 260a: conductor, 260A: conductive film, 260b: conductor, 260: conductor, 280a: insulator, 280b: insulator, 280c: insulator, 280: insulator, 283: insulator, 287: insulator, 290: opening portion

1. A semiconductor device comprising:
a first transistor, a connection portion, a first insulator, a second insulator, and a first wiring,
wherein the connection portion comprises a first electrode and a second electrode,
wherein the first transistor comprises the second electrode, a third electrode, a first semiconductor, a gate insulator, and a first gate electrode,
wherein the first insulator is positioned over the first wiring and comprises a first opening reaching the first wiring,
wherein the first electrode comprises a first portion in contact with a side surface of the first insulator in the first opening and a second portion in contact with a top surface of the first wiring,
wherein the second electrode comprises a portion positioned in the first opening and is in contact with the second portion of the first electrode,
wherein the second insulator is positioned over the first insulator and comprises a second opening reaching the second electrode,
wherein the third electrode is positioned over the second insulator,
wherein the first semiconductor comprises a third portion in contact with the third electrode, a fourth portion in contact with a side surface of the second insulator in the second opening, and a fifth portion in contact with a top surface of the second electrode,
wherein the gate insulator comprises a portion positioned in the second opening and is in contact with the fourth portion and the fifth portion of the first semiconductor, and
wherein the first gate electrode comprises a portion positioned in the second opening and faces the third portion, the fourth portion, and the fifth portion of the first semiconductor with the gate insulator therebetween.

2. The semiconductor device according to claim 1, further comprising:
a capacitor and a second wiring,
wherein the capacitor comprises a fourth electrode, a fifth electrode, and a third insulator,
wherein the first insulator comprises a third opening reaching the second wiring,
wherein the fourth electrode comprises a sixth portion in contact with a side surface of the first insulator in the third opening and a seventh portion in contact with a top surface of the second wiring,
wherein the third insulator comprises a portion positioned in the third opening and is in contact with the sixth portion and the seventh portion of the fourth electrode, and
wherein the fifth electrode comprises a portion positioned in the third opening and faces the sixth portion and the seventh portion of the fourth electrode with the third insulator therebetween.

3. The semiconductor device according to claim 2, further comprising:
a second transistor over the capacitor,
wherein the second transistor comprises the fifth electrode, a sixth electrode, a second semiconductor, the gate insulator, and a second gate electrode,
wherein the second insulator comprises a fourth opening reaching the fifth electrode,
wherein the sixth electrode is positioned over the second insulator,
wherein the second semiconductor comprises an eighth portion in contact with the sixth electrode, a ninth portion in contact with a side surface of the second insulator in the fourth opening, and a tenth portion in contact with a top surface of the fifth electrode,
wherein the gate insulator comprises a portion positioned in the fourth opening and is in contact with the ninth portion and the tenth portion of the second semiconductor, and
wherein the second gate electrode comprises a portion positioned in the fourth opening and faces the eighth portion, the ninth portion, and the tenth portion of the second semiconductor with the gate insulator therebetween.

4. The semiconductor device according to claim 1,
wherein the second electrode is in contact with the first portion of the first electrode.

5. The semiconductor device according to claim 1, further comprising:
a fourth insulator,
wherein the fourth insulator comprises a portion positioned in the first opening and is in contact with the first portion of the first electrode, and
wherein the second electrode is in contact with the fourth insulator.

6. The semiconductor device according to claim 1,
wherein the second electrode comprises a first conductor and a second conductor over the first conductor,
wherein the first conductor comprises a portion in the first opening and is in contact with the second portion of the first electrode, and
wherein the second conductor is in contact with the first semiconductor.
